(19) United States
(12) Patent Application Publication
(10) Pub. No.: US 2026/0081113 A1
(43) Pub. Date: Mar. 19, 2026

(54) GAS DISTRIBUTION PORT INSERT AND APPARATUS INCLUDING THE SAME

(71) Applicant: Lam Research Corporation, Fremont, CA (US)

(72) Inventors: Joshua Nathaniel Eric Mak, Sherwood, OR (US); Daniel Boatright, Estacada, OR (US); Yanhui Huang, Sherwood, OR (US); Chad Adrien Beaudette, Wilsonville, OR (US); Nick Ray Linebarger, Jr., Tualatin, OR (US); Fayaz A. Shaikh, Lake Oswego, OR (US); Bin Luo, Beaverton, OR (US); Callan Patrick Leonard, Portland, OR (US); Ruisong Wang, Tigard, OR (US); James Forest Lee, Casper, WY (US)

(21) Appl. No.: 19/110,771

(22) PCT Filed: Sep. 22, 2023
(86) PCT No.: PCT/US2023/033446

§ 371 Date: Mar. 11, 2025

Related U.S. Application Data
(60) Provisional application No. 63/376,944, filed on Sep. 23, 2022.
(60) Provisional application No. 63/384,379, filed on Nov. 18, 2022.
(60) Provisional application No. 63/511,454, filed on Jun. 30, 2023.

(51) Int. Cl. H01J 37/32; C23C 16/455

(52) U.S. Cl. CPC H01J 37/3244; C23C 16/45565

(57) ABSTRACT

A gas distribution port insert, and equipment for use therewith, capable of suppressing or at least reducing process gas interaction with and/or back diffusion into a gas distribution body including the gas distribution port insert in association with a semiconductor processing tool.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Semiconductor processing tools may be used to perform various semiconductor processing operations, including depositing and etching operations. Some of these operations may be performed relative to a frontside or a backside of a wafer. For example, a deposition or an etching operation may be performed relative to a backside of the wafer in a manner that one or more process gases are flowed from gas distribution ports of a showerhead pedestal towards the backside of the wafer and one or more purge gases, e.g., inert gases, are flowed from gas distribution ports of a showerhead towards a frontside of the wafer. As such, the process gas(es) may flow under the wafer in a wafer processing area to perform the deposition or etching operation and the purge gas(es) may flow over the wafer to prevent or at least reduce the potential for the process gas(es) from affecting the frontside of the wafer and/or the structures thereon (or therein). During processing, plasma may be generated by applying radio frequency (RF) power to the showerhead pedestal, which may act as a first electrode and supports the wafer during processing. A faceplate or another part of the showerhead may act as a second electrode (e.g., ground) so as to cause the plasma to come into existence between the backside of the wafer and a gas distribution surface of the showerhead pedestal. In some implementations, the role of anode and cathode may be reversed such that RF power is applied to the showerhead or a component thereof. In other cases, the RF power may be applied to both the showerhead pedestal and the showerhead (or a component thereof) such that both are used as electrodes and, for instance, the walls of a semiconductor processing chamber are used as a ground. It is noted, however, that the process gas(es) may sometimes still flow over the wafer and interact with the showerhead and/or back diffuse into the gas distribution ports of the showerhead.

The background provided herein is for the purposes of generally presenting the context of the disclosure. Work of the presently named inventors, to the extent that it is described in this background, as well as aspects of the description that may not otherwise qualify as prior art at the time of filing, are neither expressly nor impliedly admitted as prior art against the disclosure.

### SUMMARY

Details of one or more implementations of the subject matter described in this specification are set forth in the accompanying drawings and the description below. Other features, aspects, and advantages will become apparent from the description, the drawings, and the claims. The following, non-limiting implementations are considered part of the disclosure; other implementations will be evident from the entirety of this disclosure and the accompanying drawings as well.

Some embodiments provide various gas distribution port inserts (or “inserts”) capable of preventing or at least reducing process gas interaction with a gas distribution body (such as a showerhead, a showerhead pedestal, etc.) and/or back diffusion into gas distribution ports (or “ports”) of the gas distribution body that include at least one of the inserts in association with a semiconductor processing operation relative to a first surface of a wafer. Accordingly, one or more embodiments seek to provide inserts configured to achieve at least one of: 1) increasing clearance between an outer surface of the insert and an inner surface of an associated port to potential abrasion therebetween that may occur as a result of thermally induced movement of the insert relative to the port, and, thereby, reducing the potential for particulate generation and/or shedding that might otherwise occur as a result of such abrasion; 2) injecting gas into a gap between the outer surface of the insert and the inner surface of the associated port, thereby discouraging process gas(es) from flowing into the gap and potentially depositing material in the gap that may later detach and form particulates; and 3) causing, at least in part, directional gas flow configured to propel gas radially outwards from an axis, e.g., center axis, of the gas distribution body, and thereby discourage process gas(es) from flowing into the gap between the gas distribution body and a second surface of the wafer facing the gas distribution body and/or reaching at least one of the ports, the inserts, and the second surface of the wafer or features formed thereon or therein.

Some embodiments provide an apparatus including one or more of inserts capable of preventing or at least reducing process gas interaction with the apparatus (or a gas distribution body of the apparatus) and/or back diffusion into gas distribution ports of the apparatus (or a gas distribution body of the apparatus) that include at least one of the inserts.

Additional aspects will be set forth in the detailed description which follows, and, in part, will be apparent from the disclosure, or may be learned by practice of the disclosed embodiments and/or the claimed subject matter.

According to some embodiments, a gas distribution port insert (“insert”) includes a head portion a head portion, a body portion, a bore, and a plurality of gas outlet orifices. The head portion includes a gas inlet surface, an intermediate surface opposing the gas inlet surface in a first direction, and at least one first lateral surface connecting the gas inlet surface to the intermediate surface. The body portion extends from the head portion and includes a proximal end adjacent to the intermediate surface, a distal end spaced apart from the proximal end in the first direction, and at least one second lateral surface connecting the distal end to the proximal end. The distal end terminates at a first distal surface. The bore extends along a reference axis from the gas inlet surface through the head portion and partially through the body portion. The bore terminates at a second distal surface interior to the body portion. The plurality of gas outlet orifices is fluidically connected to the bore within the interior of the body portion and are circumferentially arranged about the reference axis. A width of the head portion in a second direction transverse to the first direction is greater than a width of the body portion in the second direction.

In some embodiments, proximal ends of the gas outlet orifices may be formed in the second distal surface.

In some embodiments, distal ends of the gas outlet orifices may be formed in the first distal surface.

In some embodiments, the body portion may further include at least one third lateral surface connecting the first distal surface to the at least one second lateral surface. The at least one third lateral surface may be inclined with respect to the first distal surface, and distal ends of the gas outlet orifices may be formed in the at least one third lateral surface.

In some embodiments, an angle of inclination of the at least one third lateral surface may be greater than 0° and less than 80°.

In some embodiments, the angle of inclination of the at least one third lateral surface may be about 45°.

In some embodiments, the gas outlet orifices may longitudinally extend in the first direction.

In some embodiments, respective axes of longitudinal extension of the gas outlet orifices may extend outward from the reference axis and may form corresponding angles of inclination with the reference axis.

In some embodiments, the respective axes of longitudinal extension of the gas outlet orifices may extend substantially perpendicular to the at least one third lateral surface.

In some embodiments, the insert may further include an additional gas outlet orifice in the first distal end surface. The gas outlet orifices may be circumferentially arranged about the additional gas outlet orifice.

In some embodiments, the additional gas outlet orifice may longitudinally extend in the first direction.

In some embodiments, the reference axis and a central axis of longitudinal extension of the additional gas outlet orifice may be substantially coincident.

In some embodiments, an axis of longitudinal extension of the additional gas outlet orifice may extend outwards from the reference axis and may form an angle of inclination with the reference axis.

In some embodiments, respective lengths of the gas outlet orifices may be between about 0.04 mm and about 0.6 mm.

In some embodiments, respective lengths of the gas outlet orifices may be between about 0.2 mm and about 0.3 mm.

In some embodiments, each gas outlet orifice among the gas outlet orifices may have a central axis of longitudinal extension and a maximum dimension in a plane perpendicular to the central axis. The corresponding maximum dimensions of the gas outlet orifices may be substantially equivalent. A diameter of a reference circle may extend through the corresponding central axes of the gas outlet orifices and may be greater than twice the maximum dimension and less than three times the maximum dimension.

In some embodiments, the diameter of the reference circle may be greater than about 0.08 mm and less than about 0.12 mm.

In some embodiments, each gas outlet orifice among the gas outlet orifices may have a central axis of longitudinal extension. A diameter of a reference circle may extend through the corresponding central axes of the gas outlet orifices and may be greater than about 0.1 mm and less than about 0.3 mm.

In some embodiments, a total number of the gas outlet orifices may be “n,” “n” may be an integer greater than or equal to two, and an angular pitch between adjacent gas outlet orifices among the gas outlet orifices may be approximately 360°/n.

In some embodiments, “n” may be 6.

According to some embodiments, a gas distribution port insert (“insert”) includes a head portion, a body portion, a bore, and a plurality of gas outlet orifices. The head portion includes a gas inlet surface, an intermediate surface opposing the gas inlet surface in a first direction, and at least one first lateral surface connecting the gas inlet surface to the intermediate surface. The body portion extends from the head portion and includes a proximal end adjacent to the intermediate surface, a distal end spaced apart from the proximal end in the first direction, and at least one second lateral surface connecting the distal end to the proximal end. The distal end terminates at a first distal surface. The bore extends along a reference axis from the gas inlet surface through the head portion and partially through the body portion. The bore terminates at a second distal surface interior to the body portion. The plurality of gas outlet orifices is in the at least one second lateral surface and are fluidically connected to the bore within the interior of the body portion. The first gas outlet orifices are circumferentially arranged about the reference axis. A width of the head portion in a second direction transverse to the first direction is greater than a width of the body portion in the second direction.

In some embodiments, the plurality of gas outlet orifices may include a set of first gas outlet orifices and a set of second gas outlet orifices offset from the first gas outlet orifices in the first direction such that the first gas outlet orifices are arranged closer to the proximal end of the body portion than the second gas outlet orifices.

In some embodiments, respective axes of longitudinal extension of the gas outlet orifices may extend outwards from the reference axis.

In some embodiments, the respective axes of longitudinal extension of the gas outlet orifices may extend radially outwards from the reference axis.

In some embodiments, the respective axes of longitudinal extension may form corresponding angles of inclination with a first reference plane perpendicular to the reference axis.

In some embodiments, the second distal surface may be tangent to some of the gas outlet orifices.

In some embodiments, the intermediate surface may extend in a second reference plane, the some of the gas outlet orifices tangent to the second distal surface may form the set of second gas outlet orifices, and the first gas outlet orifices may be spaced apart from the second reference plane in the first direction.

In some embodiments, the intermediate surface may extend in a second reference plane, and the second reference plane may be tangent to some of the gas outlet orifices.

In some embodiments, the some of the gas outlet orifices tangent to the second distal surface may form the set of second gas outlet orifices, and the some of the gas outlet orifices tangent to the second reference plane may form the set of first gas outlet orifices.

In some embodiments, respective first openings of the set of first gas outlet orifices may have corresponding first central axes tangent to the at least one second lateral surface, respective second openings of the set of second gas outlet orifices may have corresponding second central axes tangent to the at least one second lateral surface, and the first central axes may be circumferentially offset from the second central axes in a manner that the first central axes are incongruent with the second central axes.

In some embodiments, a total number of the gas outlet orifices may be “n,” “n” may be an integer greater than or equal to four, and an angular pitch between respective ones of the first central axes and correspondingly adjacent ones of the second central axes may be approximately 360°/n.

In some embodiments, “n” may be 12.

In some embodiments, “n” may be 14.

In some embodiments, respective openings of the set of first gas outlet orifices may have corresponding first central axes tangent to the at least one second lateral surface, respective openings of the set of second gas outlet orifices may have corresponding second central axes tangent to the at least one second lateral surface, and the first central axes may be substantially aligned with corresponding ones of the second central axes.

In some embodiments, a total number of the first gas outlet orifices may be “k,” “k” may be an integer greater than or equal to two, and an angular pitch between adjacent first central axes among the first central axes may be approximately 360°/k.

In some embodiments, “k” may be 6.

In some embodiments, “k” may be 7.

In some embodiments, a total number of the second gas outlet orifices may be equivalent to the total number of first gas outlet orifices.

In some embodiments, the second distal surface may be a generally conical surface having an apex protruding towards the first gas inlet surface in a direction opposite the first direction.

In some embodiments, a central axis of the bore may extend through the apex of the second distal surface.

In some embodiments, one or more of the gas outlet orifices may have circular cross-sections in planes perpendicular to their axes of longitudinal extension.

In some embodiments, the bore and the gas outlet orifices may be configured such that, in response to a flow of gas through the insert, a pressure drop between an inlet of the bore and respective outlets of the gas outlet orifices may be less than or equal to 850×10⁻⁴ Torr, and a Knudsen number of the flow of gas may be greater than 0.01 and less than 0.1.

In some embodiments, the pressure drop between the inlet of the bore and the respective outlets of the gas outlet orifices may be less than or equal to 500×10⁻⁴ Torr.

According to some embodiments, a gas distribution port insert (“insert”) includes a head portion, a body portion, a bore, and a gas outlet orifice. The head portion includes a gas inlet surface, an intermediate surface opposing the gas inlet surface in a first direction, and at least one first lateral surface connecting the gas inlet surface to the intermediate surface. The body portion extends from the head portion and includes a proximal end adjacent to the intermediate surface, a distal end spaced apart from the proximal end in the first direction, and at least one second lateral surface connecting the distal end to the proximal end. The distal end terminates at a first distal surface. The bore extends along a reference axis from the gas inlet surface through the head portion and partially through the body portion. The bore terminates at a second distal surface interior to the body portion. The gas outlet orifice includes a proximal end opening fluidically connected to the bore within an interior of the body portion and a distal end opening formed in the at least one second lateral surface. A width of the head portion in a second direction transverse to the first direction is greater than a width of the body portion in the second direction.

In some embodiments, the insert may further include a recessed portion in the gas inlet surface. The recessed portion may longitudinally extend from the at least one first lateral surface to the first bore in a third direction. The third direction may be transverse to the first direction. A depth of the recessed portion in the first direction may be less than a height of the head portion in the first direction.

In some embodiments, a width of the recessed portion in the second direction may be between about 0.02 mm and about 0.06 mm, and a height of the recessed portion in the first direction may be between about 0.005 mm and about 0.02 mm.

In some embodiments, the distal end opening may be formed in and may span between the first distal surface and the at least one second lateral surface.

In some embodiments, a central axis of longitudinal extension of the gas outlet orifice may extend in a fourth direction transverse to the first direction.

In some embodiments, a first reference plane may be perpendicular to the first direction, and an angle between the first reference plane and the fourth direction may be about 10° to about 30°.

In some embodiments, the third direction and the fourth direction may be substantially equivalent.

In some embodiments, a height of the gas outlet orifice may be between about 0.02 mm and about 0.05 mm.

In some embodiments, the height of the gas outlet orifice may extend in a fifth direction perpendicular to the fourth direction.

In some embodiments, a width of the gas outlet orifice in the second direction may be between about 0.1 mm and about 0.2 mm.

In some embodiments, the fourth direction may be substantially perpendicular to the first direction.

In some embodiments, the gas outlet orifice may include a first sidewall extending in a sixth direction oblique to the central axis of the gas outlet orifice, and a second sidewall extending in a seventh direction oblique to the central axis of the gas outlet orifice. The seventh direction may be different from the sixth direction.

In some embodiments, a first angle between the central axis of the gas outlet orifice and the sixth direction may be about 45° to about 75°, and a second angle between the central axis of the gas outlet orifice and the seventh direction may be about-45° to about-75°.

In some embodiments, magnitudes of the first and second angles may be substantially equivalent.

In some embodiments, the insert may further include an additional bore extending partially through the body portion and fluidically connecting the bore and the gas outlet orifice.

In some embodiments, the additional bore may extend along the reference axis.

In some embodiments, a central axis of the additional bore may be offset from a central axis of the bore.

In some embodiments, the central axis of the additional bore may be offset from the central axis of the bore in the third direction.

In some embodiments, the offset may be between 0.01 mm and 0.03 mm.

In some embodiments, a width of the additional bore in the second direction may be less than or equal to a minimum width of the gas outlet orifice in the second direction.

In some embodiments, a height of the gas outlet orifice in the first direction may be smaller than a height of the additional bore in the first direction.

In some embodiments, the bore and the gas outlet orifice may be configured such that, in response to a flow of gas through the insert, a pressure drop between an inlet of the bore and an outlet of the gas outlet orifice may be less than or equal to 850×10⁻⁴ Torr, and a Knudsen number of the flow of gas may be greater than 0.01 and less than 0.1.

In some embodiments, the pressure drop between the inlet of the bore and the outlet of the gas outlet orifice may be less than or equal to 500×10⁻⁴ Torr.

According to some embodiments, a gas distribution port insert (“insert”) includes a gas inlet, a body portion, a flange portion, a bore, and a plurality of gas outlet orifices. The gas inlet is configured to receive a flow of gas. The body portion includes a proximal end. a distal end spaced apart from the proximal end in a first direction, and a first section including first threads and being disposed between the proximal end and the distal end. The flange portion extends from the distal end of the body portion. The flange portion includes a mating surface adjacent to the distal end and a first distal surface spaced apart from the mating surface in the first direction. The bore extends along a reference axis from the proximal end towards the distal end. The bore is fluidically connected to the gas inlet and terminates at a second distal surface interior to the body portion. The plurality of gas outlet orifices is in the first distal surface. The gas outlet orifices are fluidically connected to the bore within the interior of the body portion and are circumferentially arranged about the reference axis.

In some embodiments, the head portion may include a first surface, a second surface spaced apart from the first surface in the first direction, and an opening extending in the first direction from the first surface through the second surface. The opening may include second threads configured to interface with the first threads. The head portion may be detachably coupled to the body portion by way of a threaded engagement between the first and second threads that causes, at least in part, a portion of the first section to be received in the opening. An extent of the threaded engagement may be configured to change a distance, in the first direction, between the second surface and the mating surface.

In some embodiments, the gas inlet may be defined by an inlet of the bore at the proximal end of the body portion.

In some embodiments, the gas inlet may be defined by an inlet of the opening in the first surface of the head portion.

In some embodiments, respective axes of longitudinal extension of the gas outlet orifices may form corresponding angles of inclination with the reference axis.

In some embodiments, each of the corresponding angles of inclination may be about 45°.

In some embodiments, a total number of the gas outlet orifices may be “n,” “n” may be an integer greater than or equal to two, and an angular pitch between respective ones of the axes of longitudinal extension may be approximately 360°/n.

In some embodiments, “n” may be 7.

In some embodiments, the body portion may further include a main section. The first section of the body portion may protrude from the main section in a direction opposite the axial direction. A width of the head portion in a second direction transverse to the first direction may be greater than a width of the main section of the body portion in the second direction.

In some embodiments, the body portion may further include a main section. The first section of the body portion may protrude from the main section in a direction opposite the axial direction. A width of the flange portion in a second direction transverse to the first direction may be greater than a width of the main section of the body portion in the second direction.

In some embodiments, a difference between the width of the flange and the width of the main section of the body portion may be greater than 0 mm and less than or equal to about 2 mm.

In some embodiments, the width of the main section in the second direction may be greater than the width of the first section in the second direction, and the width of the flange portion in the second direction may be greater than a width of the head portion in the second direction.

In some embodiments, the head portion may further include at least one lateral surface connecting the second surface to the first surface. The first surface may include at least one recessed portion. The at least one recessed portion may longitudinally extend from the at least one lateral surface to the opening in a third direction. The third direction may be transverse to the first direction. A depth of the at least one recessed portion in the first direction may be less than a height of the head portion in the first direction.

In some embodiments, the flange portion may form a generally cylindrical prism.

In some embodiments, the reference axis may form a central axis of the insert.

In some embodiments, the reference axis may extend in the first direction.

In some embodiments, respective lengths of the gas outlet orifices may be smaller than a length of the bore.

In some embodiments, a depth of the bore along the reference axis may be between about 0.3 mm and about 0.6 mm.

In some embodiments, a width of the bore in the second direction may be between about 0.1 mm and about 0.2 mm.

In some embodiments, a width of the head portion in the second direction may be between about 0.1 mm and about 0.4 mm, and a width of the body portion in the second direction may be between about 0.1 mm and about 0.2 mm.

In some embodiments, a length of the head portion in the first direction may be between about 0.05 mm and about 0.1 mm, and a length of the body portion in the first direction may be between about 0.4 mm and about 0.6 mm.

In some embodiments, a length of the insert may be between about 0.5 mm and about 0.7 mm.

In some embodiments, the head portion may form a generally cylindrical prism.

In some embodiments, the body portion may form a generally cylindrical prism.

In some embodiments, the body portion may form a generally conical frustum decreasing in size with increasing distance from the head portion.

In some embodiments, a cavity of the bore may form a generally cylindrical prism in the head portion.

In some embodiments, a cavity of the bore may form a generally conical frustum in the head portion.

In some embodiments, a cavity of the bore may form a generally cylindrical prism in the body portion.

In some embodiments, a cavity of the bore may form a generally conical frustum in the body portion.

In some embodiments, the insert may include a metal oxide.

In some embodiments, the insert may be formed of an aluminum oxide.

According to some embodiments, an apparatus includes a gas distribution body. The gas distribution body includes one or more plenums formed between a first surface and a second surface opposing the first surface. The second surface includes a plurality of gas distribution ports fluidically connected to at least one of the one or more plenums. One or more of the gas distribution ports includes a gas distribution port insert (“insert”) according to any one of the aforementioned embodiments at least partially supported therein.

In some embodiments, each of the one or more gas distribution ports may include a first port part configured to support the head portion of the insert at least partially therein, and a second port part fluidically connected to the first port part. The second port part may be configured to enable the body portion of insert to extend at least partially therethrough.

In some embodiments, the first port part may be configured to form a clearance fit with the head portion of the insert.

In some embodiments, a maximum dimension of the first port part in the second direction may be between about 1% and about 5% greater than the width of the head portion of the insert.

In some embodiments, the second port part may have at least one inner side wall adjacent to the at least one second lateral surface of the body portion, and a first gap between the at least one inner side wall and the at least one second lateral surface may be greater than 0 and less than or equal to about 1 mm.

In some embodiments, the first gap may be substantially constant along a length of the second port part.

In some embodiments, the first gap may be greater than 0 and less than or equal to about 0.5 mm.

In some embodiments, the first gap may increase with increasing distance from the first port part.

In some embodiments, the first gap may be greater than 0 and less than or equal to about 0.8 mm.

In some embodiments, a gas distribution port of the one or more gas distribution ports may include a first port part including second threads interfacing with the first threads, and a second port part fluidically connected to the first port part. The second port part may include at least some of the body portion supported therein.

In some embodiments, a gas distribution port of the one or more gas distribution ports may include a first port part including the head portion of the insert at least partially supported therein, and a second port part fluidically connected to the first port part. The second port part may include at least some of the body portion of the insert at least partially supported therein.

In some embodiments, the mating surface of the flange portion may abut against the second surface of the gas distribution body.

In some embodiments, the second surface of the head portion may abut against a support surface in the gas distribution port, and the support surface may define a transition between the first port part and the second port part.

In some embodiments, the apparatus may further include a process chamber and a pedestal. The pedestal may be configured to support a wafer within the process chamber in relation to the gas distribution body such that a distance, in the first direction, between the second surface and a surface of the wafer facing the second surface is about 1 mm.

In some embodiments, the first distal surface may extend beyond the second surface of the gas distribution body such that a distance, in the first direction, between the first distal surface and the surface of the wafer is between about 0.10 mm and about 0.5 mm.

In some embodiments, the gas distribution body may form a portion of a showerhead, and the pedestal may be a showerhead pedestal.

In some embodiments, the gas distribution body may further include one or more thermal control elements thermally coupled thereto, and the one or more thermal control elements may include a heating element, a cooling conduit, or both a heating element and a cooling conduit.

In some embodiments, one or more portions of the thermal control elements may be disposed in a reference plane extending between the first surface and the second surface in a manner that the reference plane is disposed, in the first direction, between the gas inlet or gas inlet surface and the first distal surface.

In some embodiments, the apparatus may further include a process chamber, a component, and a directional flow structure. The process chamber may include a cleaning gas inlet. The component may include a third surface facing the second surface of the gas distribution body within an interior of the process chamber. The directional flow structure may be supported within the interior of the process chamber and may be configured to direct a portion of a flow of cleaning gas from the cleaning gas inlet to an area between the second surface and the third surface.

In some embodiments, the gas distribution body may form a portion of a showerhead and the component may form a portion of a showerhead pedestal.

In some embodiments, the apparatus may further include a remote-plasma clean (“RPC”) source fluidically connected to the cleaning gas inlet. The one or more cleaning gases may include dissociated species from plasma generated by the RPC source.

In some embodiments, the semiconductor processing chamber may be a multi-station processing chamber.

According to an embodiment, a method includes causing, at least in part, one or more cleaning gases to flow between a first surface of a gas distribution body and a second surface of a component facing the gas distribution body within an interior region of a semiconductor processing chamber, the first surface including a plurality of gas distribution ports configured to support corresponding gas distribution port insets at least partially therein. The method also includes causing, at least in part, one or more purge gases to flow from the gas distribution port inserts as the one or more cleaning gases flow between the first surface and the second surface. The one or more cleaning gases are caused, at least in part, to flow in a first general direction. The second surface faces the first surface in a second direction transverse to the first general direction. The gas distribution port inserts include corresponding gas outlet orifices having respective axes of longitudinal extension angled away from the second direction.

In some embodiments, the second direction may be perpendicular to the first general direction.

In some embodiments, the gas distribution port inserts may be configured according to any one of the aforementioned embodiments at least partially supported therein.

In some embodiments, the respective axes of longitudinal extension may extend in the first general direction.

In some embodiments, the gas distribution body may form a portion of a showerhead and the third surface may form a portion of a showerhead pedestal.

In some embodiments, the one or more cleaning gases may include dissociated species from plasma generated outside the semiconductor processing chamber.

In some embodiments, the semiconductor processing chamber may be a multi-station processing chamber.

The foregoing general description and the following detailed description are illustrative and explanatory and are intended to provide further explanation of the claimed subject matter.

### BRIEF DESCRIPTION OF THE DRAWINGS

Various embodiments disclosed herein are illustrated by way of example, and not by way of limitation, in the figures of the accompanying drawings, in which like reference numerals refer to similar elements.

FIG. 1 schematically illustrates a substrate processing system, which may not only be used to process a wafer, but may also be capable of suppressing (or reducing) process gas interaction with a gas distributor and/or back abrasion into gas distribution ports of the gas distributor according to some embodiments.

FIG. 2 schematically illustrates a partial cross-sectional view of a gas distributor and a wafer of the substrate processing system of FIG. 1 according to some embodiments.

FIGS. 3-5 schematically depict various views of a gas distribution port insert that may be incorporated as part of the showerhead of FIG. 2 according to some embodiments.

FIG. 6 schematically illustrates a partial cross-sectional view of the showerhead of FIG. 2 including the gas distribution port insert of FIGS. 3-5 according to some embodiments.

FIGS. 7-9 schematically depict various views of a gas distribution port insert that may be incorporated as part of the showerhead of FIG. 2 according to some embodiments.

FIG. 10 schematically illustrates a partial cross-sectional view of the showerhead of FIG. 2 including the gas distribution port insert of FIGS. 7-9 according to some embodiments.

FIGS. 11-13 schematically depict various views of a gas distribution port insert that may be incorporated as part of the showerhead of FIG. 2 according to some embodiments.

FIG. 14 schematically illustrates a partial cross-sectional view of the showerhead of FIG. 2 including the gas distribution port insert of FIGS. 11-13 according to some embodiments.

FIGS. 15-18 schematically depict various views of a gas distribution port insert that may be incorporated as part of the showerhead of FIG. 2 according to some embodiments.

FIG. 19 schematically illustrates a partial cross-sectional view of the showerhead of FIG. 2 including the gas distribution port insert of FIGS. 15-18 according to some embodiments.

FIGS. 20-23 schematically depict various views of a gas distribution port insert that may be incorporated as part of the showerhead of FIG. 2 according to some embodiments.

FIG. 24 schematically illustrates a partial cross-sectional view of the showerhead of FIG. 2 including the gas distribution port insert of FIGS. 20-23 according to some embodiments.

FIGS. 25-28 schematically depict various views of a gas distribution port insert that may be incorporated as part of the showerhead of FIG. 2 according to some embodiments.

FIG. 29 schematically illustrates a partial cross-sectional view of the showerhead of FIG. 2 including the gas distribution port insert of FIGS. 25-28 according to some embodiments.

FIGS. 30-33 schematically depict various views of a gas distribution port insert that may be incorporated as part of the showerhead of FIG. 2 according to some embodiments.

FIG. 35 schematically illustrates a partial cross-sectional view of the showerhead of FIG. 2 including the gas distribution port insert of FIGS. 30-33 according to some embodiments.

FIGS. 36-40 schematically depict various views of a gas distribution port insert that may be incorporated as part of the showerhead of FIG. 2 according to some embodiments.

FIG. 41 schematically illustrates a partial cross-sectional view of the showerhead of FIG. 2 including the gas distribution port insert of FIGS. 36-40 according to some embodiments.

FIGS. 42-45 schematically depict various views of a gas distribution port insert that may be incorporated as part of the showerhead of FIG. 2 according to some embodiments.

FIGS. 46 and 47 schematically illustrate partial cross-sectional views of the showerhead of FIG. 2 including the gas distribution port insert of FIGS. 42-45 according to some embodiments.

FIGS. 48-53 schematically depict various views of a gas distribution port insert that may be incorporated as part of the showerhead of FIG. 2 according to some embodiments.

FIG. 54 schematically illustrates a partial cross-sectional view of the showerhead of FIG. 2 including the gas distribution port insert of FIGS. 48-53 according to some embodiments.

FIG. 55 schematically illustrates a partial cross-sectional view of the showerhead of FIG. 2 including a modified version of the gas distribution port insert of FIGS. 48-53 according to some embodiments.

FIG. 56 schematically illustrates a partial cross-sectional view of a modified version of the showerhead of FIG. 2 including a modified version of the gas distribution port insert of FIG. 55 according to some embodiments.

FIG. 57 schematically illustrates a multi-station processing tool according to some embodiments.

FIG. 58 schematically illustrates a cross-sectional view of the multi-station processing tool of FIG. 57 implementing a remote plasma clean (RPC) process utilizing instances of the gas distributor of FIG. 2 and the gas distribution port insert of FIG. 7 according to some embodiments.

FIG. 59 schematically depicts a simulated mean velocity profile of purge gas output from the gas distribution port insert of FIG. 7 in association with the RPC process of FIG. 58 according to some embodiments.

FIGS. 60 and 61 schematically illustrate a plan view of a support pedestal after the RPC process of FIG. 58 and a backside view of a semiconductor wafer after being processed using the support pedestal of FIG. 60 according to some embodiments.

FIG. 62 schematically illustrates a cross-sectional view of the multi-station processing tool of FIG. 57 implementing an RPC process utilizing the gas distributor of FIG. 2 and the gas distribution port insert of FIG. 15 according to some embodiments.

FIG. 63 schematically depicts a simulated mean velocity profile of purge gas output from the gas distribution port insert of FIG. 15 in association with the RPC process of FIG. 62 according to some embodiments.

FIGS. 64 and 65 schematically illustrate a plan view of a support pedestal after the RPC process of FIG. 62 and a backside view of a semiconductor wafer after being processed using the support pedestal of FIG. 64 according to some embodiments.

### DETAILED DESCRIPTION OF SOME EMBODIMENTS

In the following description, numerous specific details are set forth in order to provide a thorough understanding of various embodiments. The disclosed embodiments may be practiced without some or all of these specific details. In other instances, well-known process operations have not been described in detail to not unnecessarily obscure the disclosed embodiments. While the disclosed embodiments will be described in conjunction with specific embodiments, it will be understood that it is not intended to limit the disclosed embodiments.

In this application, the terms “semiconductor wafer,” “wafer,” “substrate,” “wafer substrate” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. In addition to semiconductor wafers, other work pieces that may take advantage of the disclosed embodiments include various articles, such as printed circuit boards, magnetic recording media, magnetic recording sensors, mirrors, optical elements, micro-mechanical devices, and the like.

### Context

As previously mentioned, semiconductor processing tools may be used to perform various semiconductor processing operations, including depositing and etching operations relative to a frontside or a backside of a wafer. For example, a deposition or an etching operation may be performed relative to a backside of the wafer in a manner that one or more process gases are flowed from gas distribution ports of a showerhead pedestal towards the backside of the wafer and one or more purge gases, e.g., inert gases, are flowed from gas distribution ports of a showerhead towards a frontside of the wafer. As used herein, inert gases include gases that are effectively non-reactive with process chemistry of an associated semiconductor processing operation such as, for instance, noble gases, and, in some cases, gases such as nitrogen. In this manner, the process gas(es) may flow under the backside of the wafer in a wafer processing area to perform the deposition or etching operation and the purge gas(es) may flow over the frontside of the wafer to prevent or at least reduce the potential for the process gas(es) from affecting the frontside of the wafer and/or structures thereon (or therein). It, however, has been discovered that the process gas(es) may sometimes still flow over the frontside of the wafer and potentially interact with the showerhead and/or back diffuse into the gas distribution ports of the showerhead. This may also be true with respect to cleaning gas(es) and/or remote plasma clean (RPC) gas(es) that may be flowed within a process chamber to remove, for instance, deposited material from exposed surfaces of components interior to a process chamber, such as exposed surfaces of the chamber walls, a support pedestal, a showerhead pedestal, and/or the like. Unwanted gas interaction with the showerhead and/or back diffusion into the gas distribution ports of the showerhead may degrade the service life of the showerhead and/or its components, decrease time between maintenance cycles (e.g., cleaning, repairs, etc.), increase equipment downtime, negatively affect product yield, and/or the like. In some instances, unwanted gas (e.g., process gas, cleaning gas, RPC gas, etc.) interaction with the showerhead may etch the showerhead, cause corrosion and/or particulate growth thereon or therein, and/or increase the likelihood of material shedding, which may result in defect causing contaminates being deposited onto the frontside of the wafer and/or structures formed thereon/therein. As such, there is a need for an approach that efficiently and effectively prevents or at least reduces the likelihood of process gas interaction with a gas distribution body and/or back diffusion into gas distribution ports of the gas distribution body.

According to one or more embodiments, the likelihood of process gas interaction with a gas distribution body and/or back diffusion into gas distribution ports of the gas distribution body may be reduced via utilization of one or more gas distribution port inserts (or “inserts”) having one or more features such as described herein in combination with a gas distribution body to tailor a flow of one or more purge gases over a first surface (e.g., a frontside) of a wafer in association with a semiconductor processing operation relative to a second surface (e.g., a backside) of the wafer. As such, one or more embodiments may seek to provide an insert(s) configured to achieve at least one of: 1) increasing clearance between an outer surface of the insert and an inner surface of an associated port to reduce potential abrasion therebetween that may occur as a result of thermally induced movement of the insert relative to the port, and, thereby, reducing the potential for particulate generation and/or shedding that might otherwise occur as a result of such abrasion; 2) injecting gas into a gap between the outer surface of the insert and the inner surface of the associated port to discourage process gas(es) from flowing into the gap and potentially depositing material in the gap that may later detach and form particulates; 3) causing, at least in part, directional gas flow configured to propel gas outwards (e.g., radially outwards) from an axis (e.g., center axis) of the gas distribution body, and thereby discourage process gas(es) from flowing into the gap between the gas distribution body and a second surface of the wafer facing the gas distribution body and/or reaching at least one of the ports, the inserts, and the second surface of the wafer or features formed thereon or therein; 4) preventing gas from flowing from the associated port in which the insert is at least partially supported; 5) adapting to different port sizes (e.g., lengths) to enable, for instance, a mating surface of a flange portion of the insert to abut against a corresponding surface of a gas distribution body, and thereby, to cap (or close) off the gap between the outer surface of the insert and the inner surface of the associated port to prevent or at least mitigate the potential for process gas(es) flowing into the gap and possibly depositing material in the gap that may later detach and form particulates.

Although various embodiments will be described in association with utilizing one or more inserts in combination with a gas distribution body to tailor a flow of one or more purge gases over a first surface of a wafer, it is also contemplated that, in some embodiments, the gas distribution body or another gas distribution body may include one or more inserts having one or more features such as described herein to tailor a flow of one or more process gases (and/or one or more other gases) over the first surface and/or a second surface of the wafer. In some implementations, the gas distribution body may be configured or otherwise modified to accommodate one or more different densities and/or spatial distributions of inserts to achieve a desired flow of one or more gases (e.g., purge gas(es), process gas(es), and/or the like). For instance, in one implementation, a gas distribution body may include a plurality of first gas distribution ports including one or more inserts at least partially supported therein that are configured to tailor a flow of one or more first gases (e.g., one or more purge gases) in a first case and a plurality of second gas distribution ports including one or more inserts at least partially supported therein that are configured to prevent the one or more first gases from flowing from the second gas distribution ports. In another implementation, one or more inserts at least partially supported in at least one of the first or second gas distribution ports may be changed to affect a density and/or spatial distribution of inserts, and thereby, points of gas or no gas flow from the gas distribution body. To this end, the changed/modified configuration of the gas distribution body may be utilized to tailor a flow of one or more second gases (e.g., one or more process gases) in a second case.

### Semiconductor Processing System

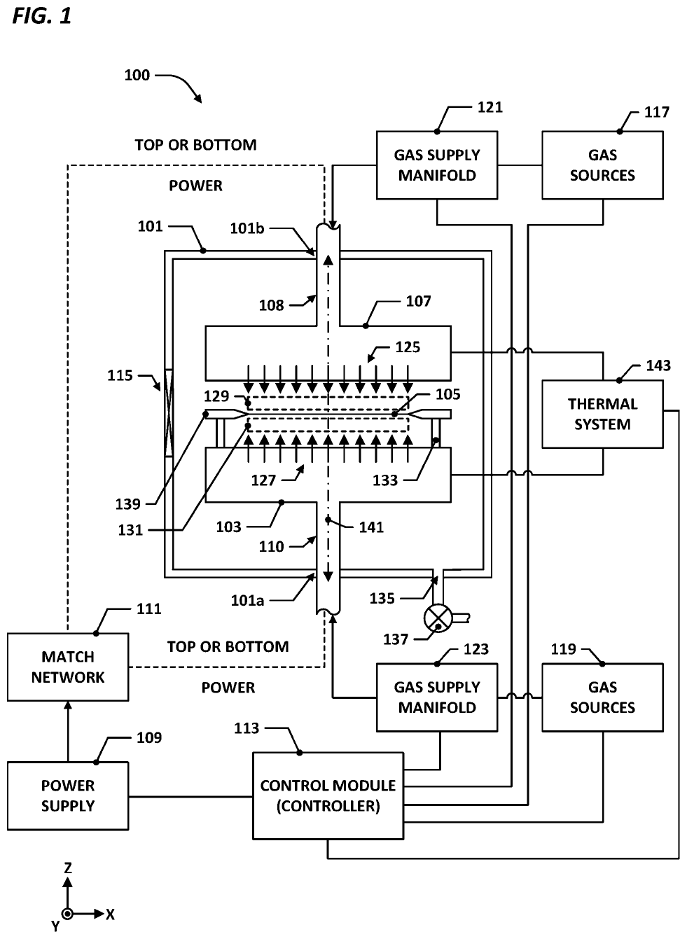

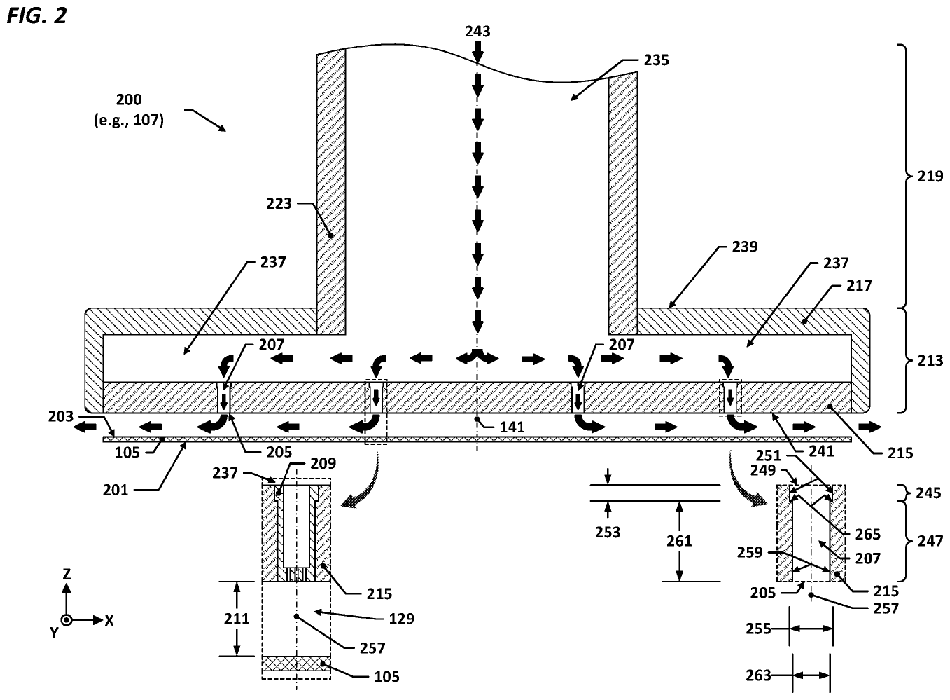

FIG. 1 schematically illustrates a substrate processing system, which may not only be used to process a wafer, but may also be capable of suppressing (or reducing) process gas interaction with a gas distributor and/or back diffusion into gas distribution ports of the gas distributor according to some embodiments. FIG. 2 schematically illustrates a partial cross-sectional view of a gas distributor and a wafer of the substrate processing system of FIG. 1 according to some embodiments.

System 100 includes a process chamber (or chamber) 101 that, in some instances, may be divided into an upper portion and a lower portion. A center column is configured to support pedestal 103 when a surface of wafer 105 is being processed, e.g., when a film is being formed on the surface of wafer 105 or a structure formed on the surface of wafer 105, a feature is being etched in the surface of wafer 105 or a structure formed on the surface of wafer 105, etc. In some embodiments, the surface may be associated with backside 201 of wafer 105 facing pedestal 103. It, however, is contemplated that the surface may be associated with frontside 203 of wafer 105 facing away from pedestal 103. In some embodiments, the surface may be associated with or include both backside 201 and frontside 203 of wafer 105. Accordingly, pedestal 103 may be or include a gas distribution body configured to deliver one or more gases to backside 201 of wafer 105 during a semiconductor processing operation. In some implementations, the one or more gases provided by way of pedestal 103 may be or include one or more process (e.g., reactive) gases and/or one or more inert gases. As such, pedestal 103 may be referred to as a showerhead pedestal. Another gas distribution body (e.g., gas distribution body 107) may be disposed over showerhead pedestal 103 and may be configured to deliver one or more gases towards frontside 203 of wafer 105 via one or more openings (e.g., openings 205) in gas distribution body 107. In some cases, the one or more gases provided by way of gas distribution body 107 may be or include one or more process (e.g., reactive) gases, one or more inert gases, and/or one or more dilution gases. As previously mentioned, a purge gas may be an inert gas, but it is also contemplated that at least one dilution gas may be utilized. In some cases, the one or more purge gases may be flowed from openings 205 in gas distribution body 107 while the one or more process gases are flowed from showerhead pedestal 103. In this manner, gas distribution body 107 may be referred to as a showerhead. As will become more apparent below, openings 205 may be fluidically connected to corresponding gas distribution ports 207 in showerhead 107 that may be configured to support respective gas distribution port inserts (e.g., gas distribution port insert (or insert) 209) at least partially therein. Generally speaking, the inserts, such as insert 209, may be configured to not only control a flow of one or more gases (e.g., one or more purge gases) from showerhead 107, but may also be configured in association with gas distribution ports 207 to suppress (or reduce) process gas interaction with showerhead 107 and/or back diffusion into openings 205. Example inserts will be described in more detail in association with FIGS. 3-10.

According to various embodiments, showerhead 107 may be or include an electrode. As such, showerhead 107 may be electrically coupled to power supply 109 via match network 111. Power supply 109 may be controlled by control module 113, such as a controller. In some embodiments, power may be provided to showerhead pedestal 103 instead of (or in addition to) showerhead 107. Control module 113 may be configured to operate system 100 by executing one or more sequences of one or more instructions defining at least one process recipe. Depending on whether frontside 203 or backside 201 of wafer 105 is to be processed, control module 113 may set various operational inputs for defining a process recipe, such as power levels, timing parameters, process gases, purge gases, mechanical movement of wafer 105, height of wafer 105 from showerhead pedestal 103, distance (e.g., distance 211) of frontside 230 of wafer 105 from second surface 241 of showerhead 107, and/or the like.

According to some embodiments, the center column may include a lift pin mechanism communicatively coupled to lift pins. The lift pin mechanism and, thereby, the lift pins may be controlled by a lift pin control signal from, for instance, control module 113. The lift pins may be used to raise wafer 105 from showerhead pedestal 103 to allow an end-effector to pick wafer 105 and to lower wafer 105 after being placed by the end-effector. In some embodiments, the lift pins may be part of the center column. To this end, chamber 101 may include chamber transport port 115 through which the end-effector may introduce or remove wafer 105 from chamber 101. In some cases, relative displacement between showerhead pedestal 103 and showerhead 107 (or between wafer 105 and showerhead 107) may be utilized to provide a controlled separation of wafer 105 from a surface of showerhead 107 facing wafer 105. Chamber 101 may also include openings 101a and 101b through which corresponding portions of showerhead pedestal 103 and showerhead 107 may extend, such as corresponding stem portions of showerhead pedestal 103 and showerhead 107. For example, stem portion 108 of showerhead 107 may be provided and may be configured (or include one or more components configured) to provide one or more gases to showerhead 107, control the temperature of showerhead 107, provide power to, for instance, one or more electrodes of or associated with showerhead 107, etc. As another example, stem portion 110 of showerhead pedestal 103 may be provided and may be configured (or include one or more components configured) to provide one or more gases to showerhead pedestal 103, control the temperature of showerhead pedestal 103, provide power to, for instance, one or more electrodes of or associated with showerhead pedestal 103, etc. In some examples, a plasma-suppression structure including, for instance, one or more spaced plates (not shown) may be provided around and/or above showerhead 107 and/or around and/or below showerhead pedestal 103 to suppress unwanted plasma from generated within chamber 101. It is contemplated, however, that one or more of stem portions 108 and 110 may be omitted. For example, showerhead 107 may be formed as or coupled to, for example, an upper and/or side wall(s) of chamber 101.

System 100 may further include gas sources 117 and 119, e.g., gas chemistry supplies from a facility and/or purge (e.g., inert) gases. Depending on the process(es) being performed relative to a surface of wafer 105, control module 113 may control the delivery of one or more gases from gas sources 117 and 119 to showerhead 107 and/or showerhead pedestal 103. In some embodiments, gas manifold 121 may be fluidically interposed between gas sources 117 and showerhead 107 and gas manifold 123 may be fluidically interposed between gas sources 119 and showerhead pedestal 103. Appropriate valving and mass flow control mechanisms may be employed and controlled via control module 113 to ensure suitable gases are delivered during, for example, deposition, etching, cleaning, and/or plasma treatment phases of a process. In this manner, respective gas flows into showerhead 107 and showerhead pedestal 103 may be respectively output as gas flows 125 and 127, and, thereby, distributed in corresponding regions 129 and 131 between wafer 105 and respective surfaces of showerhead 107 and showerhead pedestal 103 facing wafer 105 via one or more gas distribution structures of showerhead 107 and showerhead pedestal 103. Although illustrated as rectangular areas, regions 129 and 131 may be more of nebulous cloud-like regions in which, for instance, plasma may be generated and/or one or more process gases, purge gases, or both process and purge gases may flow.

During substrate processing, spacers (or other substrate support structure(s)) 133 may be used to maintain a predetermined separation of wafer 105 from a gas distribution surface of showerhead pedestal 103 to facilitate (e.g., optimize or otherwise improve) deposition or etching relative to backside 201 of wafer 105, while reducing (or even preventing) deposition or etching relative to frontside 203 of wafer 105. Spacers 133 may be disposed on (e.g., directly on) a surface of showerhead pedestal 103 facing backside 201 of wafer 105, as schematically illustrated in FIG. 1. In some embodiments, spacers 133 may be connected to showerhead pedestal 103, but not directly supported on the surface of showerhead pedestal 103 facing backside 201 of wafer 105. When spacers 133 that are disposed on showerhead pedestal 103 and/or connected to showerhead pedestal 103 are utilized, the spacers 133 may be configured to allow wafer 105 to maintain parallelism (or substantial parallelism) with respect to showerhead pedestal 103. For instance, showerhead pedestal 103 and wafer 105 supported by spacers 133 may be configured to be manipulated (e.g., translated, rotated, etc.) together when showerhead pedestal 103 is manipulated (e.g., translated up and/or down) inside chamber 101. Maintaining such parallelism (or substantial parallelism) may contribute to greater process uniformity across wafer 105 than when wafer 105 is supported by substrate support structures not connected to showerhead pedestal 103, but is rather connected to, for instance, showerhead 107 and/or one or more walls (e.g., sidewalls) of chamber 101 that are not necessarily manipulated as one unit with showerhead pedestal 103 as maintaining parallelism (or substantial parallelism) between backside 201 of wafer 105 and a facing surface (e.g., a top surface) of showerhead pedestal 103 when backside 201 of wafer 105 is being processed has the ability to improve process uniformity across wafer 105. In some embodiments, while deposition or etching is targeted for backside 201 of wafer 105, one or more purge gases may be flowed over frontside 203 of wafer 105 via showerhead 107 to prevent (or at least reduce the likelihood of) process gas entering into region 129 and/or to push reactant gas away from region 129, and, thereby, away from frontside 203 of wafer 105 and showerhead 107. Separately, and/or additionally, to protect, minimize, or reduce exposure of frontside 203 of wafer 105 to plasma during the processing of backside 201 of wafer 105, distance 211 between frontside 203 of wafer 105 and second surface 241 of showerhead 107 may be set to be less than the plasma sheath distance associated with the process. In this manner, reactant gas(es) output from showerhead pedestal 103 may be directed to region 131, and, thereby, towards backside 201 of wafer 105. According to various embodiments, the gas distribution structure of showerhead 107 may include one or more inserts (e.g., insert 209) at least partially supported in corresponding gas distribution ports 207 thereof that may cause, at least in part, gas flow 125 from showerhead 107 into and through region 129 to, for example, prevent or at least reduce the likelihood of gas flow 127 from interacting with showerhead 107 and/or back diffusion into gas distribution ports 207 of showerhead 107. In some cases, the gas distribution structure of showerhead 107 including the one or more inserts (such as insert 209) at least partially supported in corresponding gas distribution ports 207 thereof may prevent or at least reduce the potential for gas flow 127 from even entering region 129, interacting with frontside 203 of wafer 105, interacting with showerhead 107, and/or backflowing into openings 205 of showerhead 107 associated with gas distribution ports 207. In some cases, one or more different types of inserts may be utilized in combination with one another in various regions across a gas distribution surface of showerhead 107 to further tailor the flow of gas flow 125 and/or prevent or at least reduce the likelihood of gas flow 127 from interacting with showerhead 107 and/or back diffusion into gas distribution ports 207 of showerhead 107.

In various implementations, process and/or purge gases may exit chamber 101 via exhaust gas port (or outlet) 135 fluidically coupled to, for instance, vacuum pump 137, which may be a one or two stage mechanical dry pump and/or a turbomolecular pump. In some embodiments, more than one exhaust gas port (or outlet) may be provided in system 100. For instance, one or more exhaust gas ports may be provided on or in one or more side walls of chamber 101. In some cases, the sidewalls may be arranged in the upper and/or lower portions of chamber 101. In this manner, process and/or purge gases may be drawn out of chamber 101 to maintain a suitably low-pressure environment therein. To this end, a closed-loop flow restriction device, such as a throttle valve or a pendulum valve, may be controlled via control module 113 to further ensure a suitably low-pressure environment in chamber 101.

System 100 may further include carrier ring 139 encircling an outer region of showerhead pedestal 103. When frontside 203 of wafer 105 is being processed, e.g., a material is being deposited thereon, material is being removed therefrom, and/or the like, carrier ring 139 may be configured to sit over a carrier ring support region stepped down from a wafer support region in a center (or central portion) of showerhead pedestal 103. Carrier ring 139 may include an outer edge side of a disk structure, e.g., outer radius, and a wafer edge side of the disk structure, e.g., inner radius, that is closest to where wafer 105 is supported. The wafer edge side of carrier ring 139 may include a plurality of contact support structures configured to lift wafer 105 when carrier ring 139 is held by spacers 133. In this manner, spider forks (e.g., spider forks 5701 of FIG. 57) may be used to lift and maintain carrier ring 139 at a predetermined height during, for example, backside deposition or etching processing, as well as utilized to rotate wafer 105 about an axis (e.g., axis 141) perpendicular (or substantially perpendicular) to a surface of, for instance, showerhead 107 and/or showerhead pedestal 103. Thus, carrier ring 139 may also be lifted (or otherwise manipulated) along with wafer 105 to be, for example, rotated to another station, e.g., in a multi-station system, such as multi-station processing tool 5700 in FIG. 57. However, embodiments are not limited to the use of carrier ring 139. For example, in some embodiments, wafer 105 may be supported by spacers 133, without a carrier ring, during one or more processes.

According to some embodiments, system 100 may also include a liner (or shroud) lining one or more interior surfaces of chamber 101. The liner may be formed of a metal or metal alloy, such as aluminum or an aluminum alloy, but embodiments are not limited thereto. The liner may be configured to be removed during servicing of chamber 101 to prevent (or at least reduce) build-up of material, e.g., metallic material, on the walls of chamber 101. To this end, the liner may also be configured to reduce heat transfer to the walls of chamber 101 to help stabilize an internal temperature of chamber 101. As such, the liner may serve as a sacrificial layer configured to prevent (or reduce) damage to chamber 101. In this way, the liner may be cleaned, maintained, and replaced, and thereby, increase the lifetime of chamber 101.

In various implementations, system 100 may include or communicate with thermal system 143, which may be configured to actively control the temperature of showerhead 107 and/or showerhead pedestal 103. For instance, thermal system 143 may be configured to control one or more aspects associated with one or more thermal control elements, e.g., heating element(s), cooling conduit(s), and/or the like, of showerhead 107 and/or showerhead pedestal 103. It is noted that control module 113 may control the operation of thermal system 143, but embodiments are not limited thereto.

### Gas Distributor

FIG. 2 schematically illustrates a gas distributor in relation to a wafer of the substrate processing system of FIG. 1 according to some embodiments. Although gas distributor 200 will be described as corresponding to showerhead 107, embodiments are not limited thereto. For instance, gas distributor 200 may correspond to showerhead pedestal 103. Hereinafter, gas distributor 200 will be referred to as showerhead 107.

Referring to FIGS. 1 and 2, showerhead 107 may be configured to flow one or more purge gases, e.g., inert gases, dilution gases, etc., from a plurality of openings 205 in gas distribution body (or body) 213 towards frontside 203 of wafer 105 in association with one or more semiconductor processing operations (e.g., backside deposition, etching, etc.) of system 100. In some implementations, body 213 may include faceplate assembly 215 coupled to backplate 217 that, in turn, may be coupled to gas distribution stem 219. Gas distribution stem 219 may, in some embodiments, include an inner stem portion that interfaces with faceplate assembly 215 and sleeve portion 223 interfacing with backplate 217. Faceplate assembly 215 may include a faceplate formed of one or more ceramic materials, such as aluminum oxide, aluminum nitride, ruthenium oxide, titanium nitride, titanium aluminum nitride, titanium carbide, and/or the like, as well as include at least one embedded ground/power plane (or electrode), and at least one resistive heating element. In some cases, showerhead 107 may additionally or alternatively include one or more cooling conduits. The electrode may receive power (e.g., radio frequency (RF) power) from an input portion and the resistive heating element may receive power from thermal system 143 via another input portion. The resistive heating element may also be coupled to a reference power level (e.g., ground, floating ground, or another relatively low potential) via an output portion. In some embodiments, the input portions and the output portion may be housed in the inner stem portion, which may be configured to shield other components of showerhead 107 from stray RF energy that may otherwise prematurely induce plasma within one or more plenums of showerhead 107.

According to various embodiments, one or more input gases may be flowed into gas distribution body 213 via gas input passageway 235, which may be defined between the inner stem portion and sleeve portion 223. Gas input passageway 235 may be fluidically connected to a plurality of gas distribution ports 207 via one or more plenums 237 defined between first surface 239 and second surface 241 of gas distribution body 213. First surface 239 may be defined by backplate 217 and second surface 241 may be defined by faceplate assembly 215. It is also noted that second surface 241 may oppose first surface 239 in the axial direction, but embodiments are not limited thereto. As such, gas distribution ports 207 may be formed in the faceplate of faceplate assembly 215 and may be fluidically coupled to (or define) openings 205 in second surface 241. In some cases, backplate 217 and gas distribution stem 219 may be manufactured from aluminum, stainless steel, and/or the like, but any other conductive material(s) may be used. It is noted, however, that aluminum is comparatively easy to machine, relatively inexpensive, and builds up passivating aluminum fluoride (AlF₃) layers when exposed to fluorine rather than suffering material erosion.

Gas distribution port 207 may be arranged in any of several different configurations in gas distribution body 213, including grid arrays, polar arrays, hexagonal arrays, spirals, offset spirals, etc. The arrangement may result in varying hole density patterns across surface 241 of showerhead 107. In some cases, gas distribution ports 207 may be configured to support a plurality of gas distribution port inserts (e.g., gas distribution port insert 209) at least partially therein to achieve a desired gas flow from showerhead 107, such as gas flow 243, which may correspond to gas flow 125 in FIG. 1. Gas flow 243 may be configured to flow through region 129 to prevent or at least reduce the potential for gas flow 127 from showerhead pedestal 103 from entering region 129, interacting with frontside 203 of wafer 105, interacting with showerhead 107, and/or backflowing into openings 205 of showerhead 107.

According to various embodiments, gas distribution ports 207 may include first port portions 245 and second port portions 247 extending from first port portions 245 in an axial direction, which may extend in a direction opposite the z-axis direction. As will become more apparent below, the combination of first and second port portions 245 and 247 may be configured to interface with a gas distribution port insert, such as gas distribution port insert 209. Both first port portion 245 and second port portion 247 may be formed as voids having generally circular cylinder configurations, but embodiments are not limited thereto. For instance, either or both of first port portion 245 and second port portion 247 may be formed as voids having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, first and second port portions 245 and 247 will be described as having a generally cylindrical configurations, but it should be appreciated that reference to a surface (e.g., interior surface) of such a shape may refer to one or more surfaces of another shape or formation of either of first and second port portions 245 and 247.

As seen in FIG. 2, gas inlet opening 249 may be formed at a proximal end of first port portion 245 and second port portion 247 may extend from a distal end of first port portion 245. As used herein, the terms “proximal” and “distal” refer, respectively, to directions closer to and farther away from a particular reference point, such as source of gas flow. In this sense, an element referred to as being “proximal” may conversely be referred to as “distal” depending on the particular reference point chosen without departing from the teachings of the disclosure. It is noted that gas inlet opening 249 may be fluidically connected to one or more of plenums 237 of showerhead 107. Interior surface 251 of first port portion 245 may extend between the proximal end and the distal end of first port portion 245 along the axial direction. Accordingly, first port portion 245 may have length 253 in the axial direction and maximum dimension (e.g., diameter) 255 in, for example, a second direction transverse to the axial direction. In some cases, the second direction may be perpendicular (or substantially perpendicular) to the axial direction, and, as such, may extend in the x-axis direction. Further, reference axis 257 may form a central axis of first port portion 245.

Similar to first port portion 245, second port portion 247 may have a proximal end fluidically connected to first port portion 245 and a distal end defining gas outlet opening 205. Inner surface 259 of second port portion 247 may extend between the proximal end and the distal end of second port portion 247. As such, second port portion 247 may have length 261 in the axial direction and maximum dimension (e.g., diameter) 263 in the second direction. Depending on the geometric configuration first and second port portions 245 and 247, maximum dimensions 255 and 263 may be widths of gas distribution port 207. That being said, maximum dimension 255 may be greater than maximum dimension 263 such that resting surface 265 may be defined between first and second port portions 245 and 247. Further, second port portion 247 may be concentrically aligned with first port portion 245 such that reference axis 257 also forms a central axis of second port portion 247. It is noted that resting surface 265 may provide an abutment upon which a gas distribution port insert, e.g., gas distribution port insert 209, rests when inserted in gas distribution port 207. Various gas distribution port inserts will be described in association with FIGS. 3-41.

Although showerhead 107 has been described in association with a chandelier-type implementation, it is also contemplated that gas distribution stem 219 may be omitted or shortened in embodiments in which showerhead 107 is, for example, flush-mounted with an upper interior surface of chamber 101.

### Gas Distribution Port Insert—1

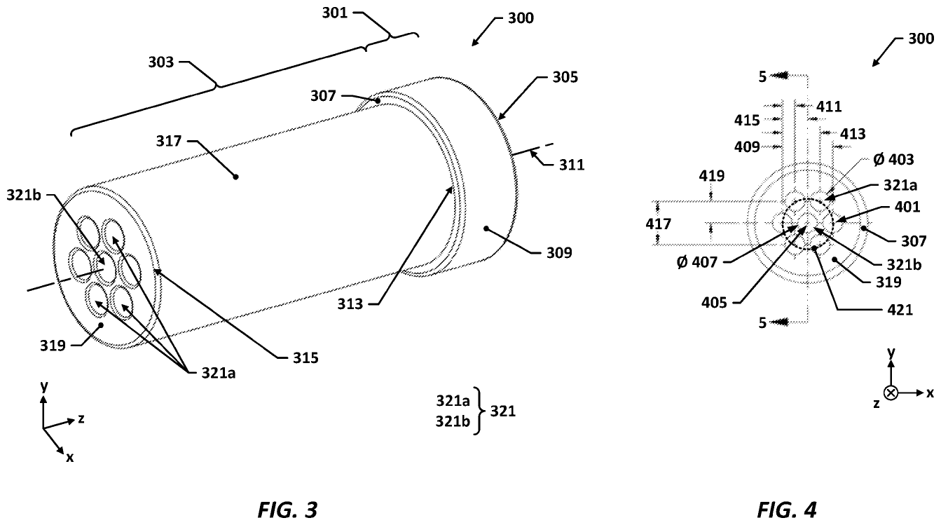

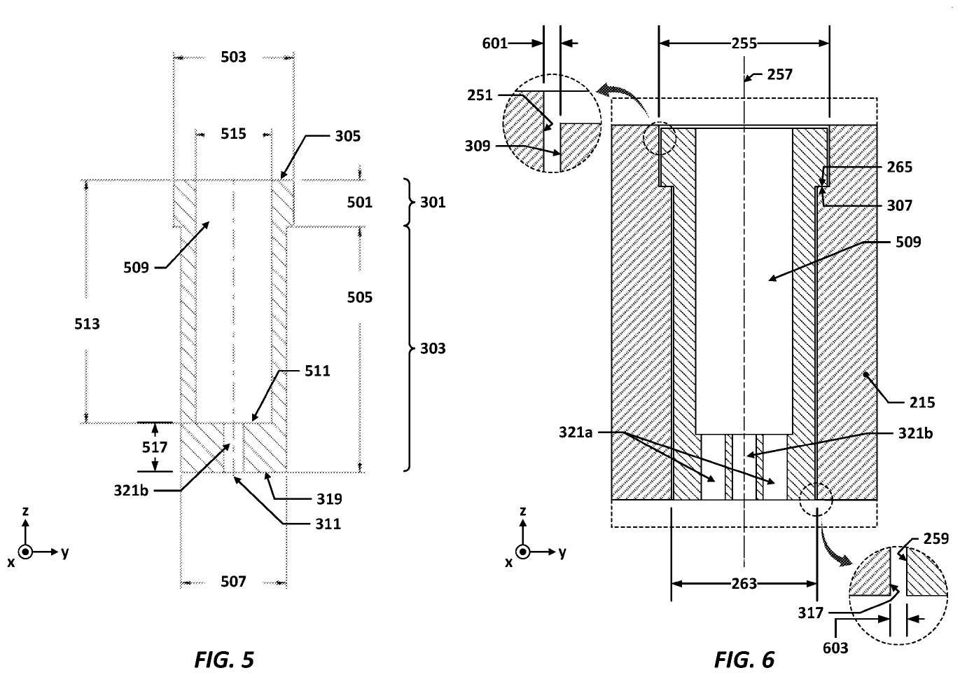

FIGS. 3-5 schematically depict various views of a gas distribution port insert (or insert) that may be incorporated as part of the showerhead of FIG. 2 according to some embodiments. For example, FIG. 3 depicts a perspective view of insert 300, FIG. 4 depicts a bottom view of insert 300, and FIG. 5 depicts a cross-sectional view of insert 300 taken along sectional line 5-5.

Referring to FIGS. 3-5, insert 300 may include head portion 301 and body portion 303 extending from head portion 301 in an axial direction, which may extend in a direction opposite the z-axis direction. Both head portion 301 and body portion 303 may be formed as generally circular cylinders, but embodiments are not limited thereto. For instance, either or both of head portion 301 and body portion 303 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 301 and body portion 303 will be described in association with FIGS. 3-5 as having generally cylindrical configurations, but it should be appreciated that reference to a surface of such a shape may refer to one or more surfaces of another shape.

According to various embodiments, head portion 301 may have length 501 in the axial direction and maximum dimension (e.g., diameter) 503 in, for example, a second direction transverse to the axial direction. For example, the second direction may be perpendicular (or substantially perpendicular) to the axial direction, and, as such, may extend in the y-axis direction. Body portion 303 may have length 505 in the axial direction and maximum dimension (e.g., diameter) 507 in the second direction. Depending on the geometric configuration of head portion 301 and body portion 303, maximum dimensions 503 and 507 may be widths of insert 300. In some embodiments, maximum dimension 503 may be between about 0.19 mm and about 0.33 mm, and maximum dimension 507 may be between about 0.13 mm and 0.25 mm. Whatever the case, maximum dimension 503 may be greater than maximum dimension 507, such as greater than maximum dimension 507 by about 15% to about 25%, but embodiments are not limited thereto. Length 501 may be between about 0.05 mm and about 0.15 mm, and length 505 may be between about 0.4 mm and about 0.6 mm. In some instances, length 505 may be greater than length 501, such as greater than length 501 by about 450% to about 550%, but embodiments are not limited thereto. As such, an overall length of insert 300 may be between about 0.5 mm and about 0.7 mm, but embodiments are not limited thereto.

Head portion 301 may include gas inlet surface 305, intermediate surface 307 opposing or spaced apart from gas inlet surface 305 in the axial direction, and lateral surface 309 connecting intermediate surface 307 to gas inlet surface 305. In this manner, head portion 301 may extend along reference axis 311, which may be a central axis of not only insert 300, but also head portion 301. Body portion 303 may include proximal end 313, distal end 315 opposing or spaced apart from proximal end 313 in the axial direction, and lateral surface 317 connecting distal end 315 to proximal end 313. As such, proximal end 313 may extend from, and, thereby, may be adjacent to intermediate surface 307. Distal end 315 may terminate at distal surface 319. In this manner, body portion 303 may also extend along reference axis 311, which may also be a central axis of body portion 303.

According to various implementations, insert 300 may include bore 509 extending from gas inlet surface 305 towards distal surface 319 along reference axis 311, which may be a central axis of bore 509. As such, bore 509 may form a central bore of insert 300, but embodiments are not limited thereto. Bore 509 may be formed as a void with a generally circular cylinder configuration, but implementations are not limited thereto. For instance, bore 509 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 509 will be described as having a generally cylindrical configuration, but it should be appreciated that reference to a surface (e.g., interior surface) of such a shape may refer to one or more surfaces of another shape or formation of bore 509.

As depicted in FIG. 5, bore 509 may terminate at distal surface 511 offset from distal surface 319 in a first direction (e.g., the z-axis direction) such that bore 509 extends through head portion 301 and partially through body portion 303. In this manner, bore 509 may have depth 513 in, for example, the axial direction, and a maximum dimension (e.g., diameter) 515 in, for instance, the second direction. For example, depth 513 may be between about 0.3 mm and about 0.6 mm, and maximum dimension 515 may be between about 0.1 mm and about 0.2 mm (and at least smaller than each of dimensions 503 and 507). It is noted that, depending on the geometric configuration of bore 509, maximum dimension 515 may be a width of bore 509. Body portion 303 may also include a plurality of gas outlet orifices 321 fluidically connected to bore 509 within an interior of insert 300. Although a total of seven gas outlet orifices 321 are depicted, insert 300 may include any suitable number of gas outlet orifices 321. In some cases, gas outlet orifices 321 may extend between distal surfaces 511 and 319 so as to enable one or more gases input to bore 509 at gas inlet surface 305 to flow through bore 509 and gas outlet orifices 321, and, thereby, to be output from distal surface 319.

Gas outlet orifices 321 may include first gas outlet orifices 321a and second gas outlet orifice 321b. Similar to bore 509, gas outlet orifices 321 may be formed as voids with generally circular cylinder configurations, but embodiments are not limited thereto. For instance, one or more of gas outlet orifices 321 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 321 will be described as having generally cylindrical configurations, but it should be appreciated that reference to a surface (e.g., interior surface) of such a shape may refer to one or more surfaces of another shape or formation. Whatever the case, each of gas outlet orifices 321 may have a central axis of longitudinal extension (hereinafter, “central axis”) and a maximum dimension (e.g., diameter) in a plane perpendicular to the central axis.

For instance, respective first gas outlet orifices 321a may have corresponding central axes, such as central axis 401, and corresponding maximum dimensions (e.g., diameters), such as maximum dimension 403. Second gas outlet orifice 321b may have central axis 405 and maximum dimension 407. In some implementations, central axes 401 and 405 may extend in the axial direction and maximum dimensions 403 and 407 may extend in, for instance, the second direction. Further, maximum dimensions 403 and 407 may, in some embodiments, be equivalent (or substantially equivalent). In some implementations, maximum dimensions 403 and 407 may be between about 0.01 mm and about 0.1 mm, such as between about 0.02 mm and about 0.07 mm, e.g., between about 0.03 mm and about 0.05 mm. Lengths (or depths) 517 of gas outlet orifices 321 may be smaller than depth 513 of bore 509. For instance, lengths 517 may be between about 0.08 mm to about 0.2 mm.

In some cases, first gas outlet orifices 321a may not only be circumferentially arranged about reference axis 311, but may also be circumferentially arranged about second gas outlet orifice 321b. As such, central axis 405 of second gas outlet orifice 321b may be coincident (or substantially coincident) with reference axis 311. In such a configuration, gas outlet orifices 321 may be arranged into three rows and three columns such that, with respect to a third direction (e.g., the x-axis direction), adjacent first gas outlet orifices 321a in a same middle row as one another may be spaced apart by distance 409, and adjacent first gas outlet orifices 321a in different rows from one another may be spaced apart by distance 411. Furthermore, with respect to the third direction and central axis 405, an outermost first gas outlet orifice 321a in the middle row and at a first side of central axis 405 may be spaced apart from an outermost first gas outlet orifice 321a in a different row and at a second side of central axis 405 by distance 413. In addition, with respect to the third direction and the middle row, a first gas outlet orifice among first gas outlet orifices 321a may be spaced apart from second gas outlet orifice 321b by distance 415. With respect to the second direction, adjacent first gas outlet orifices 321a in a same column as one another may be spaced apart by distance 417, and adjacent first gas outlet orifices 321a in a different column as one another may be spaced apart by distance 419. Similarly, with respect to the second direction, second gas outlet orifice 321b may be spaced apart from an adjacent first gas outlet orifice among first gas outlet orifices 321a by distance 419. As such, respective central axes (e.g., central axis 401) of the first gas outlet orifices 321a may be arranged on reference circle 421. A diameter of reference circle 421 may be greater than twice maximum dimension 403 and less than three times maximum dimension 403.

According to various embodiments, insert 300 may be formed of any suitable material, as well as formed in any suitable manner. For example, insert 300 may be formed of (or include) one or more ceramic materials, such as aluminum oxide, aluminum nitride, ruthenium oxide, titanium nitride, titanium aluminum nitride, titanium carbide, etc. In some cases, insert 300 may be formed of a first material and coated with a second material. For example, insert 300 may be manufactured from aluminum as the first material and may be coated with aluminum fluoride (AlF₃) as the second material, but embodiments are not limited thereto. In various implementations, insert 300 may be additively manufactured, stamped, injection molded, compression molded, cast, machined, and/or the like.

FIG. 6 schematically illustrates a partial cross-sectional view of the showerhead of FIG. 2 including the gas distribution port insert of FIGS. 3-5 according to some embodiments.

With reference to FIGS. 2 and 3-6, insert 300 may be at least partially supported in gas distribution port 207 such that intermediate surface 307 of insert 300 abuts against resting surface 265 of gas distribution port 207. To this end, insert 300 may be configured to form a clearance fit with gas distribution port 207. As used, herein, the phrase “clearance fit” means that a gap or clearance exists between two mating parts that enables at least one of the two parts to slide and/or rotate relative to the other when assembled, such as in the case of a first part being received in a hole defined in a second part that allows, for instance, the first part (or a portion thereof) to slide and/or rotate within the hole defined in the second part when the first and second parts are assembled. With respect to insert 300 and gas distribution port 207, the formation of a clearance fit may include gas distribution port 207 being sized larger than insert 300 that enables insert 300 (or a portion thereof) to slide and/or rotate within gas distribution port 207 when insert 300 is at least partially supported within gas distribution port 207. In some cases, this may include maximum dimension 503 of head portion 301 of insert 300 being about 1% to about 10% smaller than maximum dimension 255 of first port portion 245 of gas distribution port 207 such that lateral surface 309 of insert 300 is spaced apart from inner surface 251 of gas distribution port 207 by distance 601. To this end, maximum dimension 507 of body portion 303 of insert 300 may be about 1% to about 10% smaller than maximum dimension 263 of second port portion 247 of gas distribution port 207 such that lateral surface 317 of insert 300 is spaced apart from inner surface 259 of gas distribution port 207 by distance 603. In some implementations, distances 601 and 603 may be equivalent or substantially equivalent, but embodiments are not limited thereto. It is also noted that head portion 301 may serve as a centering mechanism when insert 300 is inserted into gas distribution port 207 so as to enable a central axis (e.g., reference axis 311) of insert 300 to be coincident (or substantially coincident) with central axis 257 of gas distribution port 207.

Formation of the above-noted clearance fits may increase the distance between lateral surfaces 309 and 317 of insert 300 and corresponding inner surfaces 251 and 259 of gas distribution port 207. This may reduce the potential for abrasion between insert 300 and gas distribution port 207 that might otherwise occur as a result of thermally induced movement of insert 300 relative to gas distribution port 207 that may be caused, at least in part, by temperature changes and/or fluctuations association with a semiconductor processing operation being performed via system 100. Although motion of insert 300 has been described as being caused in association with thermal effects, it is also contemplated that the motion of insert 300 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 300 and gas distribution port 207 that might otherwise cause, at least in part, defect causing contaminates being deposited onto frontside 203 of wafer 105 and/or structures formed thereon/therein. To this end, the centering effect of head portion 301 relative to body portion 303 may also serve to return insert 300 into concentric (or substantially concentric) alignment with gas distribution port 207 after movement of insert 300. This may help maintain a determined gas flow profile from showerhead 107.

### Gas Distribution Port Insert—2

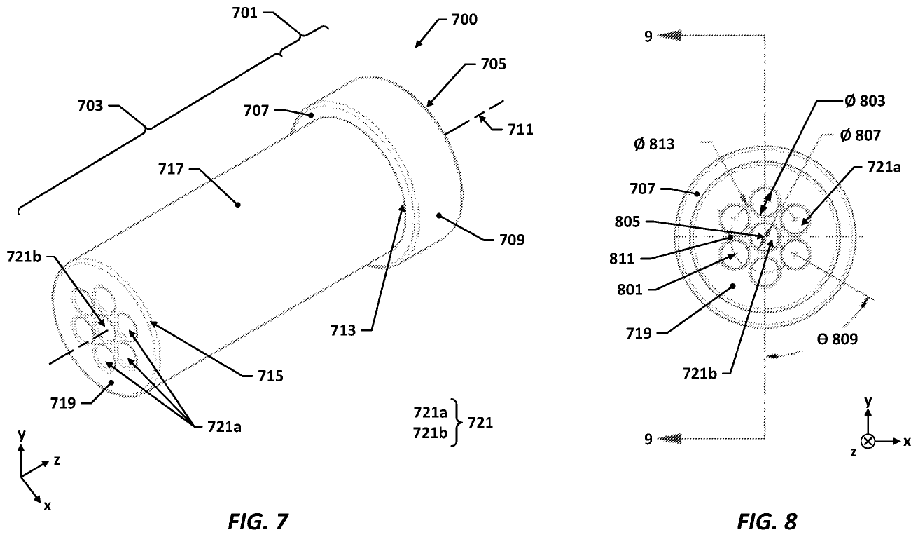

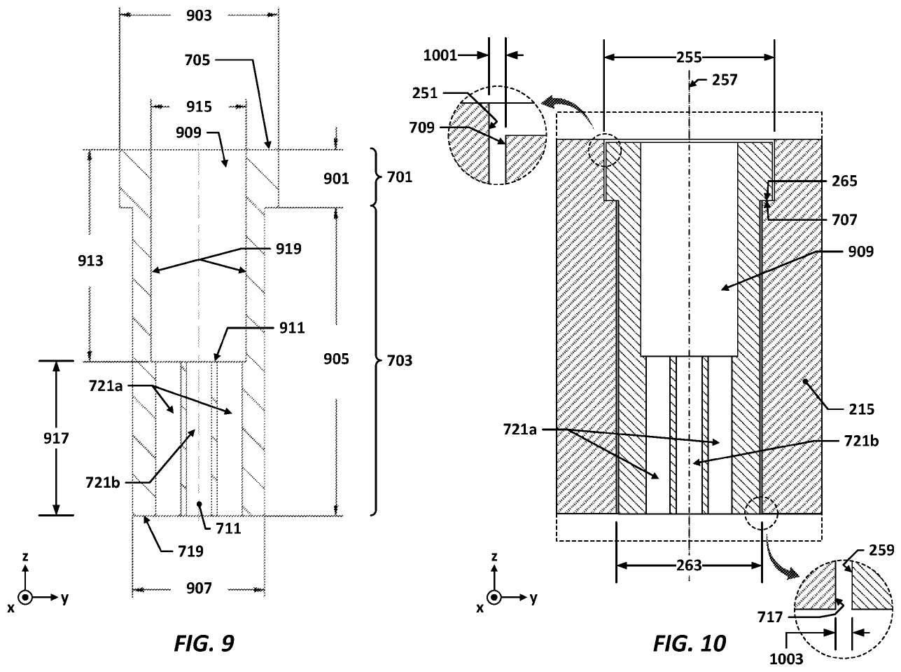

FIGS. 7-9 schematically depict various views of a gas distribution port insert (or insert) that may be incorporated as part of the showerhead of FIG. 2 according to some embodiments. For example, FIG. 7 depicts a perspective view of insert 700, FIG. 8 depicts a bottom view of insert 700, and FIG. 9 depicts a cross-sectional view of insert 700 taken along sectional line 9-9.

With reference to FIGS. 7-10, insert 700 may be similar to insert 300, and, as such, may include head portion 701 and body portion 703 extending from head portion 701 in an axial direction. The axial direction may extend in a direction opposite the z-axis direction. Both head portion 701 and body portion 703 may be formed as generally circular cylinders, but embodiments are not limited thereto. For instance, either or both of head portion 701 and body portion 703 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 701 and body portion 703 will be described in association with FIGS. 7-9 as having generally cylindrical configurations, but it should be appreciated that reference to a surface of such a shape may refer to one or more surfaces of another shape.

According to various embodiments, head portion 701 may have length 901 in the axial direction and maximum dimension (e.g., diameter) 903 in, for example, a second direction transverse to the axial direction. For example, the second direction may be perpendicular (or substantially perpendicular) to the axial direction, and, as such, may extend in the y-axis direction. Body portion 703 may have length 905 in the axial direction and maximum dimension (e.g., diameter) 907 in the second direction. Depending on the geometric configuration of head portion 701 and body portion 703, maximum dimensions 903 and 907 may be widths of insert 700. In some embodiments, maximum dimension 903 may be between about 0.1 mm and about 0.4 mm, and maximum dimension 907 may be between about 0.1 mm and 0.2 mm. Further, maximum dimension 903 may be greater than maximum dimension 907, such as greater than maximum dimension 907 by about 15% to about 25%, but embodiments are not limited thereto. Length 901 may be between about 0.05 mm and about 0.1 mm, and length 905 may be between about 0.4 mm and about 0.6 mm. Length 905 may be greater than length 901, such as greater than length 901 by about 450% to about 550%, but embodiments are not limited thereto. In this manner, an overall length of insert 700 may be between about 0.5 mm and about 0.7 mm, but embodiments are not limited thereto.

Head portion 701 may include gas inlet surface 705, intermediate surface 707 opposing or spaced apart from gas inlet surface 705 in the axial direction, and lateral surface 709 connecting intermediate surface 707 to gas inlet surface 705. In this manner, head portion 701 may extend along reference axis 711, which may be a central axis of not only insert 700, but also head portion 701. Body portion 703 may include proximal end 713, distal end 715 opposing or spaced apart from proximal end 713 in the axial direction, and lateral surface 717 connecting distal end 715 to proximal end 713. As such, proximal end 713 may extend from, and, thereby, may be adjacent to intermediate surface 707. Distal end 715 may terminate at distal surface 719. In this manner, body portion 703 may also extend along reference axis 711, which may also be a central axis of body portion 703.

According to various implementations, insert 700 may include bore 909 extending from gas inlet surface 705 towards distal surface 719 along reference axis 711, which may be a central axis of bore 909. As such, bore 909 may form a central bore of insert 700, but embodiments are not limited thereto. Bore 909 may be formed as a void with a generally circular cylinder configuration, but implementations are not limited thereto. For instance, bore 909 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 909 will be described as having a generally cylindrical configuration, but it should be appreciated that reference to a surface (e.g., interior surface) of such a shape may refer to one or more surfaces of another shape or formation of bore 909.

As depicted in FIG. 9, bore 909 may terminate at distal surface 911 offset from distal surface 719 in a first direction (e.g., the z-axis direction) such that bore 909 extends through head portion 701 and partially through body portion 703. In this manner, bore 909 may have depth 913 in, for example, the axial direction, and a maximum dimension (e.g., diameter) 915 in, for instance, the second direction. For example, depth 913 may be between about 0.1 mm and about 0.6 mm, and maximum dimension 915 may be between about 0.1 mm and about 0.2 mm. In this manner, bore 909 may have a smaller depth within insert 700 than bore 509 within insert 300. It is noted that, depending on the geometric configuration of bore 909, maximum dimension 915 may be a width of bore 909. Body portion 703 may also include a plurality of gas outlet orifices 721 fluidically connected to bore 909 within an interior of insert 700. Although a total of seven gas outlet orifices 721 are depicted, insert 700 may include any suitable number of gas outlet orifices 321. In some cases, gas outlet orifices 721 may extend between distal surfaces 911 and 719 so as to enable one or more gases input to bore 909 at gas inlet surface 705 to flow through bore 909 and gas outlet orifices 721, and, thereby, to be output from distal surface 719.

Gas outlet orifices 721 may include first gas outlet orifices 721a and second gas outlet orifice 721b. Similar to bore 909, gas outlet orifices 721 may be formed as voids with generally circular cylinder configurations, but embodiments are not limited thereto. For instance, one or more of gas outlet orifices 721 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 721 will be described as having generally cylindrical configurations, but it should be appreciated that reference to a surface (e.g., interior surface) of such a shape may refer to one or more surfaces of another shape or formation. Whatever the case, each of gas outlet orifices 721 may have a central axis and a maximum dimension (e.g., diameter) in a plane perpendicular to the central axis.

For instance, respective first gas outlet orifices 721a may have corresponding central axes, such as central axis 801, and corresponding maximum dimensions (e.g., diameters), such as maximum dimension 803. Second gas outlet orifice 721b may have central axis 805 and maximum dimension 807. In some implementations, central axes 801 and 805 may extend in the axial direction and maximum dimensions 803 and 807 may extend in, for instance, the second direction. Further, maximum dimensions 803 and 807 may, in some embodiments, be equivalent (or substantially equivalent). In some implementations, maximum dimensions 803 and 807 may be between about 0.01 mm and about 0.1 mm, such as between about 0.02 mm and about 0.07 mm, e.g., between about 0.03 mm and about 0.05 mm. Lengths (or depths) 917 of gas outlet orifices 721 may be smaller than depth 913 of bore 909. For instance, lengths 917 may be between about 0.2 mm to about 0.3 mm. In this manner, gas outlet orifices 721 may have longer lengths within insert 700 than gas outlet orifices 321 within insert 300. This decrease in depth of bore 909 and increase in length of gas outlet orifices 721 may cause, at least in part, a greater pressure drop between gas inlet surface 705 and distal surface 719 in association with a flow of gas through insert 700 under conditions in the slip flow regime (e.g., Knudsen number being greater than 0.01 and less than 0.1). With such a decrease in downstream pressure, a throughput (or mean velocity) of the gas through insert 700 may be greater than through insert 300, and more of the gas may be output from insert 700 via second gas outlet orifice 721b than respective first gas outlet orifices 721a, but embodiments are not limited thereto. This makes sense as, in the slip flow regime, gas flow is expected to slow with decreasing distance from interior wall 919 that may cause, at least in part, more gas to flow via second gas outlet orifice 721b than respective first gas outlet orifices 721a. For instance, assuming a flow of gas within the slip flow regime, a pressure drop through insert 700 may be less than or equal to about 850×10⁻⁴ Torr, such as less than or equal to about 800×10⁻⁴ Torr, e.g., about 798×10⁻⁴ Torr. As used, herein, the phrase “mean velocity” may refer to the time average of the velocity of a fluid (e.g., purge gas) at one or more points along its flow path and may be determined over an arbitrary time interval offset from a fixed time. For instance, one or more mean velocities of purge gas flow may be time averaged velocities determined at various points in an insert after steady-state (or substantially steady-state) flow conditions are achieved.

In some cases, first gas outlet orifices 721a may not only be circumferentially arranged about reference axis 711, but may also be circumferentially arranged about second gas outlet orifice 721b. As such, central axis 805 of second gas outlet orifice 721b may be coincident (or substantially coincident) with reference axis 711. In such a configuration, first gas outlet orifices 721a may be arranged about reference axis 711 with angular pitch 809. Assuming insert 700 has “n” first gas outlet orifices 721a (where “n” is an integer greater than or equal to two), then angular pitch 809 may be equivalent (or substantially equivalent) to 360° divided by “n.” For example, insert 700 is shown including six first gas outlet orifices 721a such that angular pitch 809 may be about 60°, but embodiments are not limited thereto. In this manner, respective central axes (e.g., central axis 801) of first gas outlet orifices 721a may be arranged on reference circle 811. Diameter 813 of reference circle 811 may be greater than twice maximum dimension 803 and less than three times maximum dimension 803. For instance, diameter 813 of reference circle 811 may, in some embodiments, be greater than or equal to about 0.1 mm and less than or equal to about 0.3 mm.

According to various embodiments, insert 700 may be formed of any suitable material, as well as formed in any suitable manner. For example, insert 700 may be formed of (or include) one or more ceramic materials, such as aluminum oxide, aluminum nitride, ruthenium oxide, titanium nitride, titanium aluminum nitride, titanium carbide, etc. In some cases, insert 700 may be formed of a first material and coated with a second material. For example, insert 700 may be manufactured from aluminum as the first material and may be coated with aluminum fluoride (AlF₃) as the second material, but embodiments are not limited thereto. In various implementations, insert 700 may be additively manufactured, stamped, injection molded, compression molded, cast, machined, and/or the like.

FIG. 10 schematically illustrates a partial cross-sectional view of the showerhead of FIG. 2 including the gas distribution port insert of FIGS. 7-9 according to some embodiments.

With reference to FIGS. 2 and 7-9, insert 700 may be at least partially supported in gas distribution port 207 such that intermediate surface 707 of insert 700 abuts against resting surface 265 of gas distribution port 207. To this end, insert 700 may be configured to form a clearance fit with gas distribution port 207. For instance, in some cases, maximum dimension 903 of head portion 701 of insert 700 may be about 1% to about 10% smaller than maximum dimension 255 of first port portion 245 of gas distribution port 207 such that lateral surface 709 of insert 700 is spaced apart from inner surface 251 of gas distribution port 207 by distance 1001. To this end, maximum dimension 907 of body portion 703 of insert 700 may be about 1% to about 10% smaller than maximum dimension 263 of second port portion 247 of gas distribution port 207 such that lateral surface 717 of insert 700 is spaced apart from inner surface 259 of gas distribution port 207 by distance 1003. In some cases, distances 1001 and 1003 may be equivalent or substantially equivalent, but embodiments are not limited thereto. It is also noted that head portion 701 may serve as a centering mechanism when inserting insert 700 into gas distribution port 207 so as to enable a central axis (e.g., reference axis 711) of insert 700 to be coincident (or substantially coincident) with central axis 257 of gas distribution port 207.

As with insert 300, the formation of the above-noted clearance fits may increase the distance between lateral surfaces 709 and 717 of insert 700 and corresponding inner surfaces 251 and 259 of gas distribution port 207. This may reduce the potential for abrasion between insert 700 and gas distribution port 207 that might otherwise occur as a result of thermally induced movement of insert 700 relative to gas distribution port 207 that may be caused, at least in part, by temperature changes and/or fluctuations association with a semiconductor processing operation being performed via system 100. Although motion of insert 700 has been described as being caused in association with thermal effects, it is also contemplated that the motion of insert 700 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 700 and gas distribution port 207 that might otherwise cause, at least in part, defect causing contaminates being deposited onto frontside 203 of wafer 105 and/or structures formed thereon/therein. To this end, the centering effect of head portion 701 relative to body portion 703 may also serve to return insert 700 into concentric (or substantially concentric) alignment with gas distribution port 207 after movement of insert 700. This may help maintain a determined gas flow profile from showerhead 107.

### Gas Distribution Port Insert—3

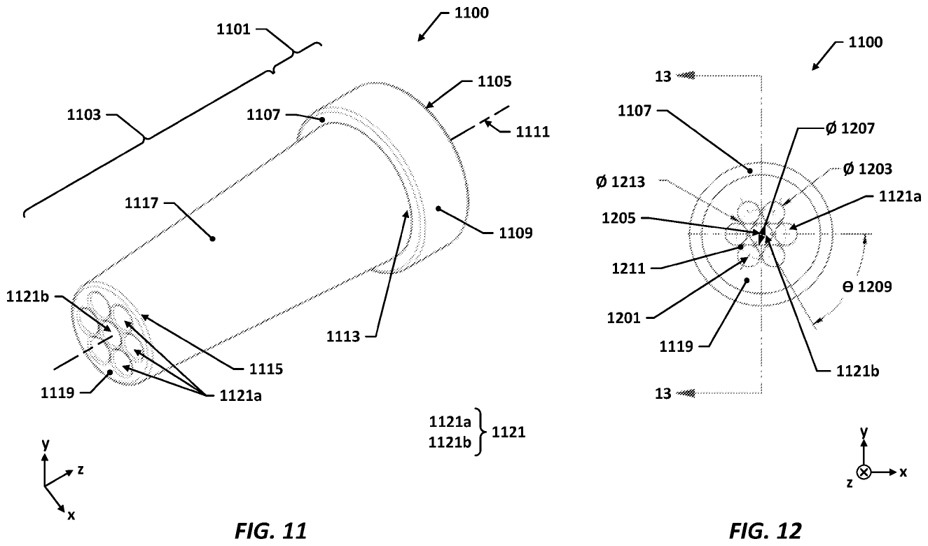

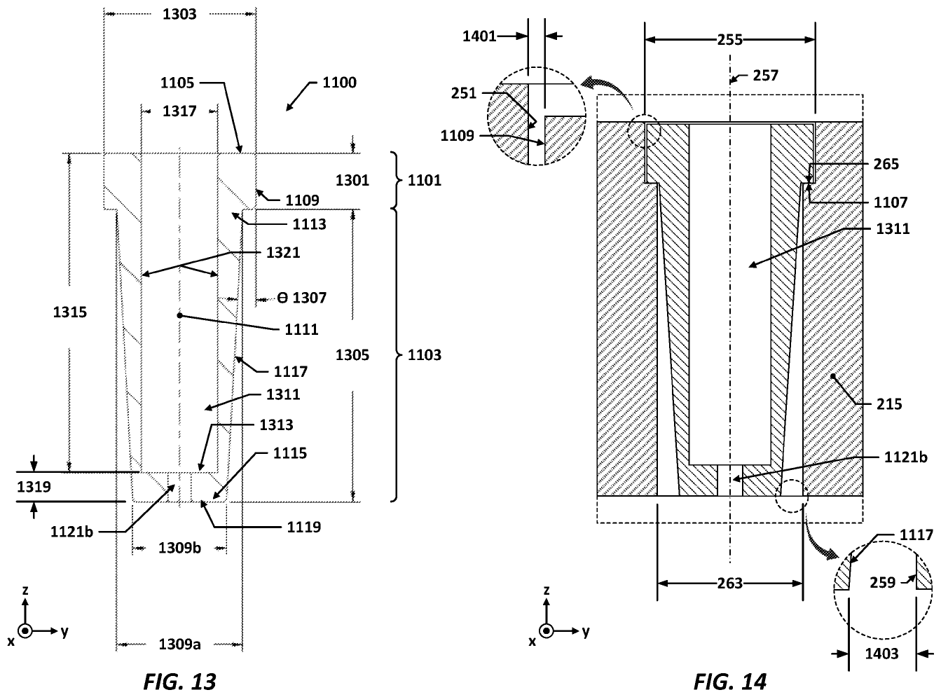

FIGS. 11-13 schematically depict various views of a gas distribution port insert (or insert) that may be incorporated as part of the showerhead of FIG. 2 according to some embodiments. For example, FIG. 11 depicts a perspective view of insert 1100, FIG. 12 depicts a bottom view of insert 1100, and FIG. 13 depicts a cross-sectional view of insert 1100 taken along sectional line 13-13.

With reference to FIGS. 11-13, insert 1100 may be similar to inserts 300 and 700, and, as such, may include head portion 1101 and body portion 1103 extending from head portion 1101 in an axial direction. The axial direction may extend in a direction opposite the z-axis direction. Head portion 1101 may be formed as a generally circular cylinder and body portion 1103 may be formed as a generally conical frustum, but embodiments are not limited thereto. For instance, either or both of head portion 1101 and body portion 1103 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, however, head portion 1101 and body portion 1103 will be described in association with FIGS. 11-13 as respectively having a generally cylindrical configuration and a generally conical frustum configuration, but it should be appreciated that reference to a surface of such shapes may refer to one or more surfaces of another shape.

Head portion 1101 may include gas inlet surface 1105, intermediate surface 1107 opposing or spaced apart from gas inlet surface 1105 in the axial direction, and lateral surface 1109 connecting intermediate surface 1107 to gas inlet surface 1105. In this manner, head portion 1101 may extend along reference axis 1111, which may be a central axis of not only insert 1100, but also head portion 1101. Body portion 1103 may include proximal end 1113, distal end 1115 opposing or spaced apart from proximal end 1113 in the axial direction, and lateral surface 1117 connecting distal end 1115 to proximal end 1113. As such, proximal end 1113 may extend from, and, thereby, may be adjacent to intermediate surface 1107. Distal end 1115 may terminate at distal surface 1119. In this manner, body portion 1103 may also extend along reference axis 1111, which may also be a central axis of body portion 1103.

According to various embodiments, head portion 1101 may have length 1301 in the axial direction and maximum dimension (e.g., diameter) 1303 in, for example, a second direction transverse to the axial direction. The second direction may be perpendicular (or substantially perpendicular) to the axial direction, and, as such, may extend in the y-axis direction. Body portion 1103 may have length 1305 in the axial direction and a variable width (e.g., diameter) in, for example, the second direction. In some embodiments, the width of body portion 1103 may vary linearly along the axial direction such that lateral surface 1117 forms angle of inclination (or angle) 1307 with the axial direction, and, in some cases, with lateral surface 1109. Angle 1307 may be greater than 0° and less than about 10°, such as greater than or equal to about 2.00° and less than or equal to about 5.00°, e.g., greater than or equal to about 2.75° and less than or equal to about 3.25°. As depicted, the width of body portion 1103 may have dimension 1309a at proximal end 1113 and dimension 1309b at distal end 1115. Depending on the geometric configuration of head portion 1101 and/or body portion 1103, dimensions 1303, 1309a, and/or 1309b may be widths of insert 1100. In some embodiments, dimension 1303 may be between about 0.1 mm and about 0.4 mm, dimension 1309a may be between about 0.1 mm and 0.2 mm, and dimension 1309b may be between about 0.1 mm and about 0.2 mm. To this end, maximum dimension 1303 may be greater than each of dimensions 1309a and 1309b. For instance, maximum dimension 1303 may be about 15% to about 25% greater than at least dimension 1309a (that is greater than dimension 1309b), but embodiments are not limited thereto. Length 1301 may be between about 0.05 mm and about 0.1 mm, and length 1305 may be between about 0.4 mm and about 0.6 mm. It is noted that length 1305 may be greater than length 1301, such as greater than length 1301 by about 450% to about 550%, but embodiments are not limited thereto. In this manner, an overall length of insert 1100 may be between about 0.5 mm and about 0.7 mm, but embodiments are not limited thereto.

According to various implementations, insert 1100 may include bore 1311 extending from gas inlet surface 1105 towards distal surface 1119 along reference axis 1111, which may be a central axis of bore 1311. As such, bore 1311 may form a central bore of insert 1100, but embodiments are not limited thereto. Bore 1311 may be formed as a void with a generally circular cylinder configuration, but implementations are not limited thereto. For instance, bore 1311 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 1311 will be described as having a generally cylindrical configuration, but it should be appreciated that reference to a surface (e.g., interior surface) of such a shape may refer to one or more surfaces of another shape or formation of bore 1311.

As shown in FIG. 13, bore 1311 may terminate at distal surface 1313 offset from distal surface 1119 in a first direction (e.g., the z-axis direction) such that bore 1311 extends through head portion 1101 and partially through body portion 1103. In this manner, bore 1311 may have depth 1315 in, for example, the axial direction, and a maximum dimension (e.g., diameter) 1317 in, for instance, the second direction. For example, depth 1315 may be between about 0.4 mm and about 0.7 mm, and maximum dimension 1317 may be between about 0.1 mm and about 0.2 mm (and at least smaller than each of dimensions 1309a and 1309b). In this manner, bore 1311 may have a greater depth within insert 1100 than each of bore 509 within insert 300 and bore 909 within insert 700. It is also noted that, depending on the geometric configuration of bore 1311, maximum dimension 1317 may be a width of bore 1311. Body portion 1103 may also include a plurality of gas outlet orifices 1121 fluidically connected to bore 1311 within an interior of insert 1100. Although a total of seven gas outlet orifices 1121 are depicted, insert 1100 may include any suitable number of gas outlet orifices 1121. In some cases, gas outlet orifices 1121 may extend between distal surfaces 1313 and 1119 so as to enable one or more gases input to bore 1311 at gas inlet surface 1105 to flow through bore 1311 and gas outlet orifices 1121, and, thereby, to be output from distal surface 1119.

Gas outlet orifices 1121 may include first gas outlet orifices 1121a and second gas outlet orifice 1121b. Similar to bore 1311, gas outlet orifices 1121 may be formed as voids with generally circular cylinder configurations, but embodiments are not limited thereto. For instance, one or more of gas outlet orifices 1121 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 1121 will be described as having generally cylindrical configurations, but it should be appreciated that reference to a surface (e.g., interior surface) of such a shape may refer to one or more surfaces of another shape or formation. Whatever the case, each of gas outlet orifices 1121 may have a central axis and a maximum dimension (e.g., diameter) in a plane perpendicular to the central axis.

For instance, respective first gas outlet orifices 1121a may have respective central axes, such as central axis 1201, and respective maximum dimensions (e.g., diameters), such as maximum dimension 1203. Second gas outlet orifice 1121b may have central axis 1205 and maximum dimension 1207. In some implementations, central axes 1201 and 1205 may extend in the axial direction and maximum dimensions 1203 and 1207 may extend in, for instance, the second direction. Further, maximum dimensions 1203 and 1207 may, in some embodiments, be equivalent (or substantially equivalent). In some implementations, maximum dimensions 1203 and 1207 may be between about 0.01 mm and about 0.1 mm, such as between about 0.02 mm and about 0.07 mm, e.g., between about 0.03 mm and about 0.05 mm. Lengths (or depths) 1319 of gas outlet orifices 1121 may be smaller than depth 1315 of bore 1311. For instance, lengths 1319 may be between about 0.02 mm to about 0.07 mm. In this manner, gas outlet orifices 1121 may have shorter lengths within insert 1100 than gas outlet orifices 321 within insert 300 and gas outlet orifices 721 within insert 700. This increase in depth of bore 1311 and decrease in length of gas outlet orifices 1121 may cause, at least in part, a smaller pressure drop between gas inlet surface 1105 and distal surface 1119 in association with a flow of gas through insert 1100 under conditions in the slip flow regime. With such an increase in downstream pressure, a throughput (or mean velocity) of the gas through insert 1100 may be smaller than through inserts 300 and 700. For instance, assuming a flow of gas within the slip flow regime, a pressure drop through insert 1100 may be less than or equal to about 500×10⁻⁴ Torr, such as less than or equal to about 425×10⁻⁴ Torr, e.g., about 405×10⁻⁴ Torr. Further, as will become more apparent below, a more even distribution of the gas may be output from insert 1100 via gas outlet orifices 1121 given that gas outlet orifices 1121 are more tightly arranged about reference axis 1111, but embodiments are not limited thereto. This makes sense as, in the slip flow regime, gas flow is expected to be more constant in a central portion of bore 1311, but slow with decreasing distance from interior wall 1321 that may cause, at least in part, a more equal distribution of gas to flow via gas outlet orifices 1121 than via gas outlet orifices 721 in insert 700.

In some cases, first gas outlet orifices 1121a may not only be circumferentially arranged about reference axis 1111, but may also be circumferentially arranged about second gas outlet orifice 1121b. As such, central axis 1205 of second gas outlet orifice 1121b may be coincident (or substantially coincident) with reference axis 1111. In such a configuration, first gas outlet orifices 1121a may be arranged about reference axis 1111 with angular pitch 1209. Assuming insert 1100 has “n” first gas outlet orifices 1121a (where “n” is an integer greater than or equal to two), then angular pitch 1209 may be equivalent (or substantially equivalent) to 360° divided by “n.” For example, insert 1100 is shown including six first gas outlet orifices 1121a such that angular pitch 1209 may be about 60°, but embodiments are not limited thereto. In this manner, respective central axes (e.g., central axis 1201) of first gas outlet orifices 721a may be arranged on reference circle 1211. It is noted, however, that diameter 1213 of reference circle 1211 may be smaller than diameter 813 of reference circle 811 of insert 700. This may equate to gas outlet orifices 1121 being more tightly arranged about reference axis 1111 in insert 1100 than an arrangement of gas outlet orifices 721 about reference axis 711 in insert 700. As previously noted, this may cause, at least in part, a more equal distribution of gas to flow via gas outlet orifices 1121 than via gas outlet orifices 721 in insert 700. In some embodiments, diameter 1213 may be greater than or equal to about 0.08 mm and less than or equal to about 0.2 mm.

According to various embodiments, insert 1100 may be formed of any suitable material, as well as formed in any suitable manner. For example, insert 1100 may be formed of (or include) one or more ceramic materials, such as aluminum oxide, aluminum nitride, ruthenium oxide, titanium nitride, titanium aluminum nitride, titanium carbide, etc. In some cases, insert 1100 may be formed of a first material and coated with a second material. For example, insert 1100 may be manufactured from aluminum as the first material and may be coated with aluminum fluoride (AlF₃) as the second material, but embodiments are not limited thereto. In various implementations, insert 1100 may be additively manufactured, stamped, injection molded, compression molded, cast, machined, and/or the like.

FIG. 14 schematically illustrates a partial cross-sectional view of the showerhead of FIG. 2 including the gas distribution port insert of FIGS. 11-13 according to some embodiments.

With reference to FIGS. 2 and 11-13, insert 1100 may be at least partially supported in gas distribution port 207 such that intermediate surface 1107 of insert 1100 abuts against resting surface 265 of gas distribution port 207. To this end, insert 1100 may be configured to form a clearance fit with gas distribution port 207. For instance, in some cases, maximum dimension 1303 of head portion 1101 of insert 1100 may be about 1% to about 10% smaller than maximum dimension 255 of first port portion 245 of gas distribution port 207 such that lateral surface 1109 of insert 1100 is spaced apart from inner surface 251 of gas distribution port 207 by distance 1401. Dimension 1309a of body portion 1103 of insert 1100 may be about 1% to about 10% smaller than maximum dimension 263 of second port portion 247 of gas distribution port 207 and dimension 1309b may be about 8% to about 15% smaller than maximum dimension 263 of second port portion 247 of gas distribution port 207. In this manner, lateral surface 1117 of insert 1100 may be spaced apart from inner surface 259 of gas distribution port 207 by a first distance, e.g., distance 1401, with respect to proximal end 1113 of body portion 1103 and may be spaced apart from inner surface 259 of gas distribution port 207 by second distance 1403 with respect to distal end 1115 of body portion 1103. Distance 1403 may, in some cases, be less than or equal to a sheath thickness associated with a process being performed in association with system 100. For example, distance 1403 may be greater than or equal to about 0.7 mm and less than or equal to about 1.1 mm, e.g., greater than or equal to about 0.9 mm and less than or equal to about 1 mm, such as about 0.997 mm. It is also noted that head portion 1101 may serve as a centering mechanism when insert 1100 is inserted into gas distribution port 207 so as to enable a central axis (e.g., reference axis 1111) of insert 1100 to be coincident (or substantially coincident) with central axis 257 of gas distribution port 207.

Similar to inserts 300 and 700, the formation of the above-noted clearance fits associated with insert 1100 may increase the distance between lateral surface 1109 and inner surface 251 of gas distribution port 207, as well as further increase the distance between lateral surface 1117 of insert 1100 and inner surface 259 of gas distribution port 207. Again, this may reduce the potential for abrasion between insert 1100 and gas distribution port 207 that might otherwise occur as a result of thermally induced movement of insert 1100 relative to gas distribution port 207 that may be caused, at least in part, by temperature changes and/or fluctuations association with a semiconductor processing operation being performed via system 100. Although motion of insert 1100 has been described as being caused in association with thermal effects, it is also contemplated that the motion of insert 1100 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 1100 and gas distribution port 207 that might otherwise cause, at least in part, defect causing contaminates being deposited onto frontside 203 of wafer 105 and/or structures formed thereon/therein. To this end, the centering effect of head portion 1101 relative to body portion 1103 may also serve to return insert 1100 into concentric (or substantially concentric) alignment with gas distribution port 207 after movement of insert 1100. This may help maintain a determined gas flow profile from showerhead 107.

### Gas Distribution Port Insert—4

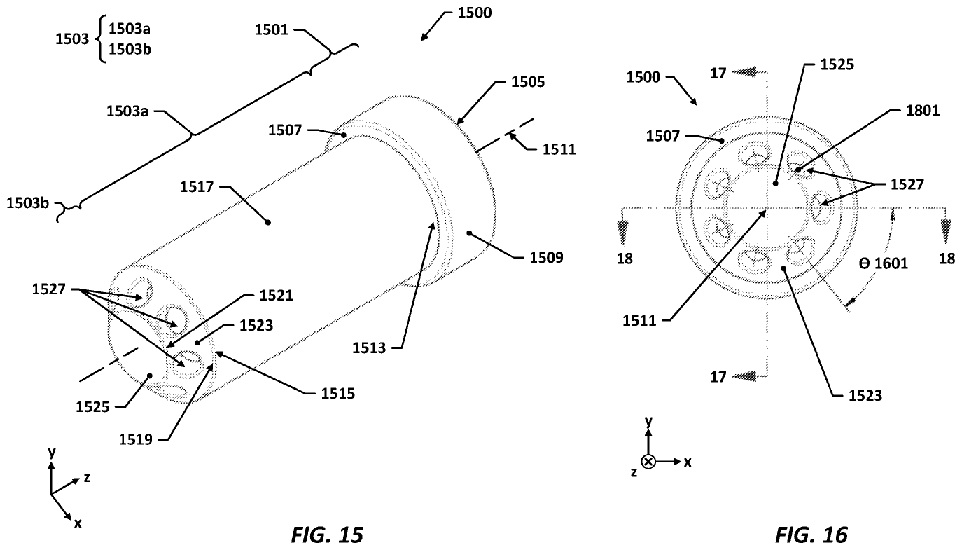

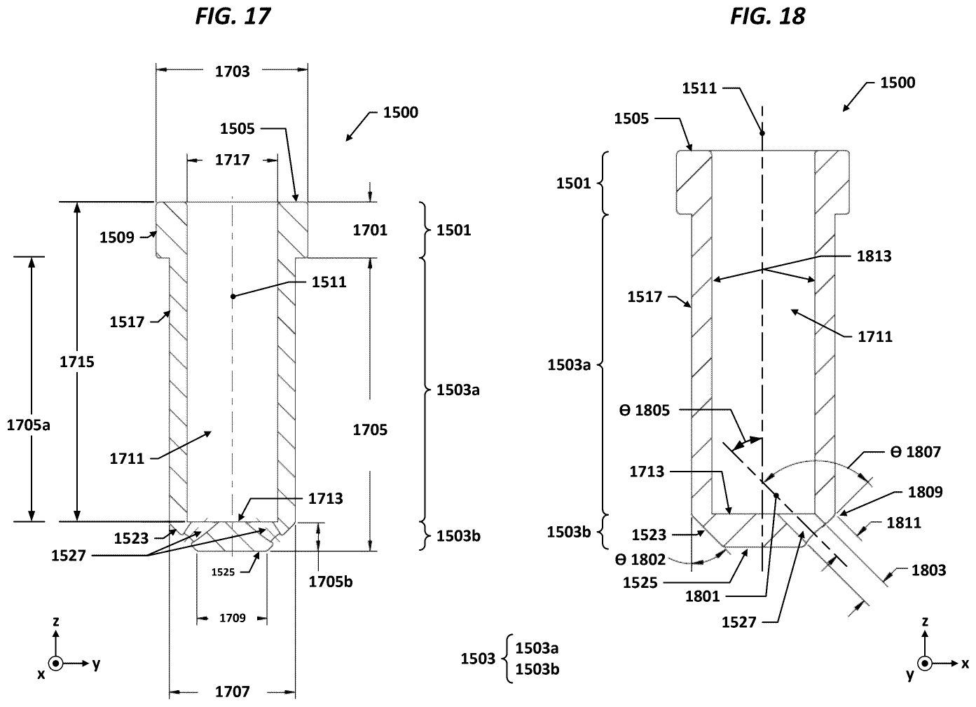

FIGS. 15-18 schematically depict various views of a gas distribution port insert (or insert) that may be incorporated as part of the showerhead of FIG. 2 according to some embodiments. For example, FIG. 15 depicts a perspective view of insert 1500, FIG. 12 depicts a bottom view of insert 1500, FIG. 17 depicts a cross-sectional view of insert 1500 taken along sectional line 17-17, and FIG. 18 depicts a cross-sectional view of insert 1500 taken along sectional line 18-18.

With reference to FIGS. 15-18, insert 1500 may be similar to inserts 300 and 700, and, as such, may include head portion 1501 and body portion 1503 extending from head portion 1501 in an axial direction. The axial direction may extend in a direction opposite the z-axis direction. Body portion 1503, however, may include first body portion 1503a extending from head portion 1501 in the axial direction and second body portion 1503b extending from first body portion 1503a in the axial direction. Both head portion 1501 and first body portion 1503a may be formed as generally circular cylinders and second body portion 1503b may be formed as a generally conical frustum, but embodiments are not limited thereto. For instance, one or more of head portion 1501, first body portion 1503a, and second body portion 1503b may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 1501 and first body portion 1503a will be described as having generally cylindrical configurations, whereas second body portion 1503b will be described as having a generally conical frustum configuration, but it should be appreciated that reference to a surface of such shapes may refer to one or more surfaces of another shape.

Head portion 1501 may include gas inlet surface 1505, intermediate surface 1507 opposing or spaced apart from gas inlet surface 1505 in the axial direction, and lateral surface 1509 connecting intermediate surface 1507 to gas inlet surface 1505. In this manner, head portion 1501 may extend along reference axis 1511, which may be a central axis of not only insert 1500, but also head portion 1501. First body portion 1503a may include proximal end 1513, distal end 1515 opposing or spaced apart from proximal end 1513 in the axial direction, and lateral surface 1517 connecting distal end 1515 to proximal end 1513. As such, proximal end 1513 may extend from, and, thereby, may be adjacent to intermediate surface 1507. Distal end 1515 may terminate at proximal end 1519 of second body portion 1503b, which also includes distal end 1521 opposing or spaced apart from proximal end 1519 in the axial direction and lateral surface 1523 connecting distal end 1521 to proximal end 1519. It is noted that proximal end 1519 of second body portion 1503b may correspond to distal end 1515 of first body portion 1503a. Further, distal end 1521 of second body portion 1503b may terminate at distal surface 1525. In this manner, first and second body portions 1503a and 1503b may also extend along reference axis 1511, which may also be a central axis of first and second body portions 1503a and 1503b.

According to some embodiments, head portion 1501 may have length 1701 in the axial direction and maximum dimension (e.g., diameter) 1703 in, for example, a second direction transverse to the axial direction. The second direction may be perpendicular (or substantially perpendicular) to the axial direction, and, as such, may extend in the y-axis direction. Body portion 1503 may have length 1705 in the axial direction and maximum dimension (e.g., diameter) 1707 in the second direction. In this manner, first body portion 1503a may have length 1705a in the axial direction and maximum dimension (e.g., diameter) 1707 in the second direction. Second body portion 1503b may have length 1705b in the axial direction and a variable width (e.g., diameter) in, for example, the second direction. In some embodiments, the width of second body portion 1503b may vary linearly along the axial direction such that lateral surface 1523 forms angle of inclination (or angle) 1802 with the axial direction, and, in some cases, with lateral surface 1517. Angle 1802 may be greater than 0° and less than about 80°, such as greater than or equal to about 20° and less than or equal to about 50°, e.g., about 45°. In this manner, second body portion 1503b may not only have a maximum dimension (e.g., diameter) corresponding to maximum dimension 1707 in association with proximal end 1519, but may also have minimum dimension (e.g., diameter) 1709 associated with distal end 1521.

Depending on the geometric configuration of head portion 1501, first body portion 1503a, and second body portion 1503b, dimensions 1703, 1707, and/or 1709 may be widths of insert 1500. In some embodiments, dimension 1703 may be between about 0.1 mm and about 0.4 mm, dimension 1707 may be between about 0.1 mm and 0.2 mm, and dimension 1709 may be between about 0.1 mm and about 0.2 mm. To this end, maximum dimension 1703 may be greater than each of dimensions 1707 and 1709. For instance, maximum dimension 1703 may be about 15% to about 25% greater than at least dimension 1707 (that is greater than dimension 1709), but embodiments are not limited thereto. Length 1701 may be between about 0.05 mm and about 0.1 mm, and length 1705 may be between about 0.4 mm and about 0.6 mm. To this end, length 1705a may be between about 0.3 mm and about 0.6 mm, and length 1705b may be between about 0.03 mm and about 0.06 mm It is noted that length 1705 may be greater than length 1701, such as greater than length 1701 by about 450% to about 550%, but embodiments are not limited thereto. In this manner, an overall length of insert 1500 may be between about 0.5 mm and about 0.7 mm, but embodiments are not limited thereto.

In various implementations, insert 1500 may include bore 1711 extending from gas inlet surface 1505 towards distal surface 1525 along reference axis 1511, which may be a central axis of bore 1711. As such, bore 1711 may form a central bore of insert 1500, but embodiments are not limited thereto. Bore 1711 may be formed as a void with a generally circular cylinder configuration, but implementations are not limited thereto. For instance, bore 1711 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 1711 will be described as having a generally cylindrical configuration, but it should be appreciated that reference to a surface (e.g., interior surface) of such a shape may refer to one or more surfaces of another shape or formation of bore 1711.

As seen in FIGS. 17 and 18, bore 1711 may terminate at distal surface 1713, which may be offset from distal surface 1119 in a first direction (e.g., the z-axis direction) such that bore 1711 extends through head portion 1501 and partially through body portion 1503. In some implementations, bore 1711 extends through (or substantially through) first body portion 1503a and terminates in a transitional region between first body portion 1503a and second body portion 1503b. As such, bore 1711 may not extend in second body portion 1503b, but embodiments are not limited thereto. Accordingly, bore 1711 may have depth 1715 in, for example, the axial direction, and a maximum dimension (e.g., diameter) 1717 in, for instance, the second direction. For example, depth 1715 may be between about 0.4 mm and about 0.7 mm, and maximum dimension 1717 may be between about 0.1 mm and about 0.2 mm (and at least smaller than each of dimensions 1707 and 1709). It is noted that maximum dimension 1717 of bore 1711 in insert 1500 may be greater than maximum dimension 1317 of bore 1311 in insert 1100. Bore 1711, however, may have a greater depth in insert 1500 than each of bore 509 in insert 300 and bore 909 in insert 700. It is also noted that, depending on the geometric configuration of bore 1711, maximum dimension 1717 may be a width of bore 1711. Second body portion 1503b may also include a plurality of gas outlet orifices 1527 fluidically connected to bore 1711 within an interior of insert 1500. Although a total of seven gas outlet orifices 1527 are depicted, insert 1500 may include any suitable number of gas outlet orifices 1527. In some cases, gas outlet orifices 1527 may extend between distal surface 1713 and lateral surface 1523 so as to enable one or more gases input to bore 1711 at gas inlet surface 1505 to flow through bore 1711 and gas outlet orifices 1527, and, thereby, to be output from lateral surface 1523.

Similar to bore 1711, gas outlet orifices 1527 may be formed as voids with generally circular cylinder configurations, but embodiments are not limited thereto. For instance, one or more of gas outlet orifices 1527 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 1527 will be described as having generally cylindrical configurations, but it should be appreciated that reference to a surface (e.g., interior surface) of such a shape may refer to one or more surfaces of another shape or formation. Whatever the case, each of gas outlet orifices 1527 may have a central axis and a maximum dimension (e.g., diameter) in a plane perpendicular to the central axis.

For instance, respective gas outlet orifices 1527 may have corresponding central axes, such as central axis 1801, and respective maximum dimensions (e.g., diameters), such as maximum dimension 1803. The central axes (e.g., central axis 1801) of gas outlet orifices 1527 may extend outwards from reference axis 1511, and, thereby, form respective angles of inclination (or angles), such as angle 1805, with reference axis 1511. In some instances, the central axes (e.g., central axis 1801) may form respective angles (e.g., angle 1807) with lateral surface 1523. For example, the central axes (e.g., central axis 1801) may extend perpendicularly (or substantially perpendicularly) to (or form) lateral surface 1523. This angling of gas outlet orifices 1527 relative to reference axis 1511 and inner surface 259 of gas distribution port 207 may help inject purge gas into a gap between lateral surface 1523 of insert 1500 and a lower portion of inner surface 259 of gas distribution port 207 near opening 205 before flowing through region 129. Such a flow of the purge gas(es) may additionally discourage process gas(es) from flowing into one or more of the gap, insert 1500, and/or showerhead 107 that might otherwise degrade insert 1500 and/or showerhead 107. In this manner, the flow of gas from gas outlet orifices 1527 may also prevent or at least reduce the likelihood of material deposition between insert 1500 and inner surface 259 of gas distribution port 207, and/or decrease the likelihood of material shedding and/or particulate formation that may result in defect causing contaminates being deposited onto frontside 203 of wafer 105 or structures formed thereon/therein.

With respect to lateral surface 1523, the central axes (e.g., central axis 1801) of gas outlet orifices 1527 may be respectively spaced apart from transition region 1809 by corresponding distances (e.g., distance 1811) in a direction of extension of lateral surface 1523. It is noted that transition region 1809 may be a region (e.g., plane) of body portion 1503 in which first body portion 1503a transitions into second body portion 1503b. It is also noted that the respective maximum dimensions (e.g., maximum dimension 1803) of gas outlet orifices 1527 may extend in a direction perpendicular to a direction of extension of a corresponding central axis (e.g., central axis 1801) of a corresponding gas outlet orifice among gas outlet orifices 1527. With such a configuration, gas outlet orifices 1527 may be arranged about reference axis 1511 with angular pitch 1601. Assuming insert 1500 has “n” gas outlet orifices 1527 (where “n” is an integer greater than or equal to two), then angular pitch 1601 may be equivalent (or substantially equivalent) to 360° divided by “n.” For example, insert 1500 is shown including seven gas outlet orifices 1527 such that angular pitch 1601 may be about 51.4°, but embodiments are not limited thereto.

In some implementations, the respective maximum dimensions (e.g., maximum dimension 1803) of corresponding gas outlet orifices 1527 may be between about 0.01 mm and about 0.1 mm, such as between about 0.02 mm and about 0.07 mm, e.g., between about 0.03 mm and about 0.05 mm. Distance 1811 may be equivalent (or substantially equivalent) to the respective maximum dimensions (e.g., maximum dimension 1803) of corresponding gas outlet orifices 1527. Respective lengths (or depths) of gas outlet orifices 1527 may be smaller than depth 1715 of bore 1711. In this manner, gas outlet orifices 1527 may have respectively shorter lengths within insert 1500 than gas outlet orifices 321 within insert 300 and gas outlet orifices 721 within insert 700. This increase in depth of bore 1711, increase in maximum dimension 1717 of bore 1711, and decrease in length of gas outlet orifices 1527 may cause, at least in part, a smaller pressure drop between gas inlet surface 1505 and lateral surface 1523 in association with a flow of gas through insert 1500 under conditions in the slip flow regime. With such an increase in downstream pressure, a throughput (or mean velocity) of the gas through insert 1500 may be smaller than through inserts 300, 700, and 1100. This also makes sense from the perspective of the positioning of inlet openings of gas outlet orifices 1527 relative to interior wall 1813 of bore 1711. In other words, in the slip flow regime, gas flow is expected to decrease with decreasing distance from interior wall 1813 that may cause, at least in part, a slower flow of gas from gas outlet orifices 1527 than via gas outlet orifices 321, 721, and 1121 in respective inserts 300, 700, and 1100. For instance, assuming a flow of gas in the slip flow regime, a pressure drop through insert 1500 may be less than or equal to about 500×10⁻⁴ Torr, such as less than or equal to about 375×10⁻⁴ Torr, e.g., about 340×10⁻⁴ Torr.

According to various embodiments, insert 1500 may be formed of any suitable material, as well as formed in any suitable manner. For example, insert 1500 may be formed of (or include) one or more ceramic materials, such as aluminum oxide, aluminum nitride, ruthenium oxide, titanium nitride, titanium aluminum nitride, titanium carbide, etc. In some cases, insert 1500 may be formed of a first material and coated with a second material. For example, insert 1500 may be manufactured from aluminum as the first material and may be coated with aluminum fluoride (AlF₃) as the second material, but embodiments are not limited thereto. In various implementations, insert 1500 may be additively manufactured, stamped, injection molded, compression molded, cast, machined, and/or the like.

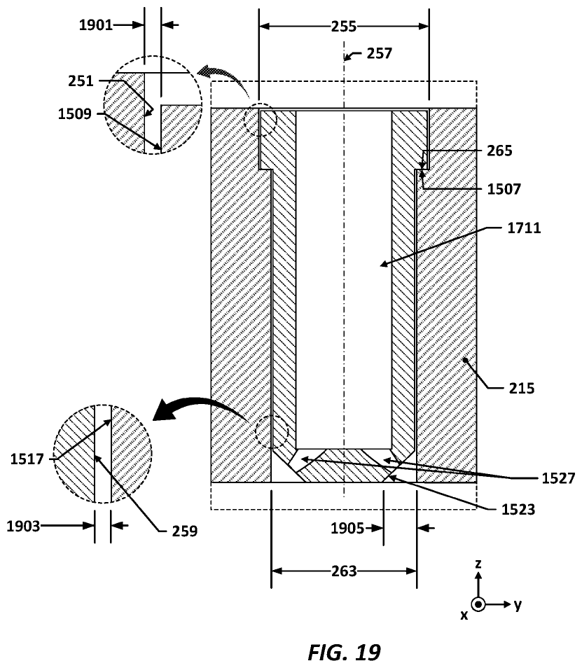

FIG. 19 schematically illustrates a partial cross-sectional view of the showerhead of FIG. 2 including the gas distribution port insert of FIGS. 15-18 according to some embodiments.

With reference to FIGS. 2 and 15-19, insert 1500 may be at least partially supported in gas distribution port 207 such that intermediate surface 1507 of insert 1500 abuts against resting surface 265 of gas distribution port 207. To this end, insert 1500 may be configured to form a clearance fit with gas distribution port 207. For instance, in some cases, maximum dimension 1703 of head portion 1501 of insert 1100 may be about 1% to about 10% smaller than maximum dimension 255 of first port portion 245 of gas distribution port 207 such that lateral surface 1509 of insert 1500 is spaced apart from inner surface 251 of gas distribution port 207 by distance 1901. In addition, dimension 1707 of first body portion 1503a of insert 1500 may be about 1% to about 10% smaller than maximum dimension 263 of second port portion 247 of gas distribution port 207 and minimum dimension 1709 of second body portion 1503b may be about 8% to about 15% smaller than maximum dimension 263 of second port portion 247 of gas distribution port 207. In this manner, lateral surface 1517 of insert 1500 may be spaced apart from inner surface 259 of gas distribution port 207 by a first distance, e.g., distance 1903, and lateral surface 1523 may be variably spaced apart from inner surface 259 of gas distribution port 207. For instance, lateral surface 1523 may be spaced apart from inner surface 259 of gas distribution port 207 by the first distance, e.g., distance 1903, in association with proximal end 1519 and may be spaced apart from inner surface 259 of gas distribution port 207 by a second distance, e.g., distance 1905, in association with distal end 1521. In some embodiments, distance 1905 may be less than or equal to a sheath thickness associated with a process performed in association with system 100. For example, distance 1905 may be greater than or equal to about 0.4 mm and less than or equal to about 1.1 mm, such as greater than or equal to about 0.7 mm and less than or equal to about 1 mm. It is also noted that head portion 1501 may serve as a centering mechanism when insert 1500 is inserted into gas distribution port 207 so as to enable a central axis (e.g., reference axis 1511) of insert 1500 to be coincident (or substantially coincident) with central axis 257 of gas distribution port 207.

Similar to inserts 300, 700, and 1100, the formation of these clearance fits associated with insert 1500 may increase the distance between lateral surfaces 1509 and 1517 of insert 1500 and corresponding inner surfaces 251 and 259 of gas distribution port 207. As before, this may reduce the potential for abrasion between insert 1500 and gas distribution port 207 that might otherwise occur as a result of thermally induced movement of insert 1500 relative to gas distribution port 207 that may be caused, at least in part, by temperature changes and/or fluctuations association with a semiconductor processing operation being performed via system 100. Although motion of insert 1500 has been described as being caused in association with thermal effects, it is also contemplated that the motion of insert 1500 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 1500 and gas distribution port 207 that might otherwise cause, at least in part, defect causing contaminates being deposited onto frontside 203 of wafer 105 and/or structures formed thereon/therein. To this end, the centering effect of head portion 1501 relative to body portion 1503 may also serve to return insert 1500 into concentric (or substantially concentric) alignment with gas distribution port 207 after movement of insert 1500. This may help maintain a determined gas flow profile from showerhead 107.

### Gas Distribution Port Insert—5

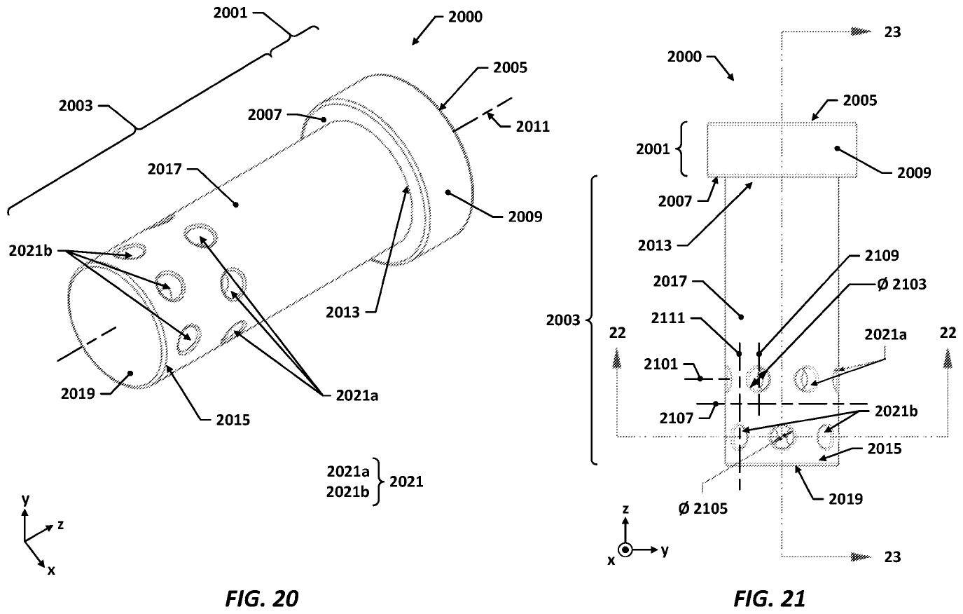

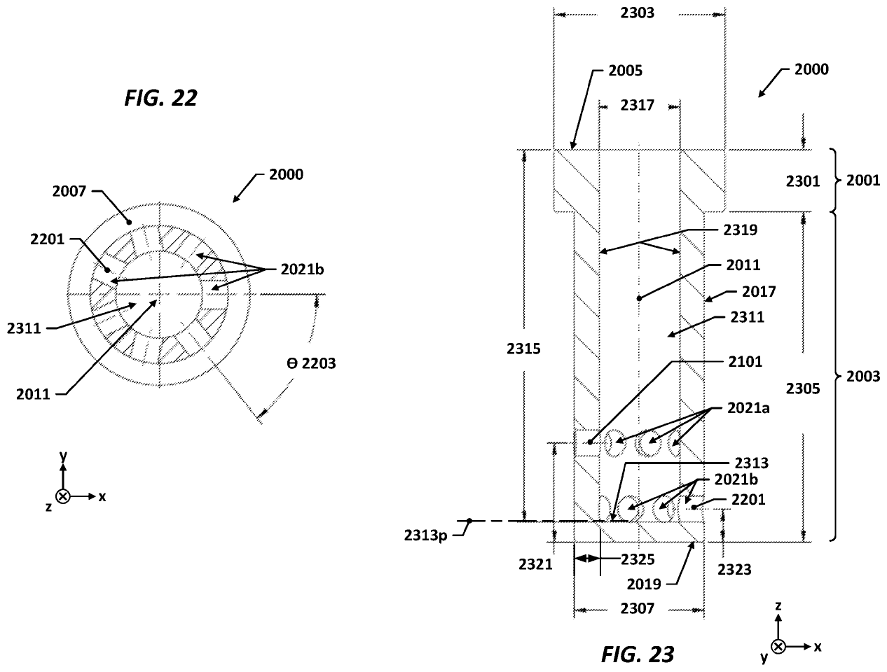

FIGS. 20-23 schematically depict various views of a gas distribution port insert (or insert) that may be incorporated as part of the showerhead of FIG. 2 according to some embodiments. For example, FIG. 20 depicts a perspective view of insert 2000, FIG. 21 depicts a side view of insert 2000, FIG. 22 depicts a bottom view of insert 2000, and FIG. 23 depicts a cross-sectional view of insert 2000 taken along sectional line 23-23.

With reference to FIGS. 20-23, insert 2000 may include head portion 2001 and body portion 2003 extending from head portion 2001 in an axial direction. The axial direction may extend in a direction opposite the z-axis direction. Both head portion 2001 and body portion 2003 may be formed as generally circular cylinders, but embodiments are not limited thereto. For instance, either or both of head portion 2001 and body portion 2003 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 2001 and body portion 2003 will be described in association with FIGS. 20-23 as having generally cylindrical configurations, but it should be appreciated that reference to a surface of such a shape may refer to one or more surfaces of another shape.

According to various embodiments, head portion 2001 may have length 2301 in the axial direction and maximum dimension (e.g., diameter) 2303 in, for example, a second direction transverse to the axial direction. For example, the second direction may be perpendicular (or substantially perpendicular) to the axial direction, and, as such, may extend in the x-axis direction. Body portion 2003 may have length 2305 in the axial direction and maximum dimension (e.g., diameter) 2307 in the second direction. Depending on the geometric configuration of head portion 2001 and body portion 2003, maximum dimensions 2303 and 2307 may be widths of insert 2000. In some embodiments, maximum dimension 2303 may be between about 0.1 mm and about 0.4 mm, and maximum dimension 2307 may be between about 0.1 mm and 0.3 mm. Further, maximum dimension 2303 may be greater than maximum dimension 2307, such as greater than maximum dimension 2307 by about 15% to about 25%, but embodiments are not limited thereto. Length 2301 may be between about 0.05 mm and about 0.1 mm, and length 2305 may be between about 0.4 mm and about 0.6 mm. Length 2305 may be greater than length 2301, such as greater than length 1001 by about 450% to about 550%, but embodiments are not limited thereto. In this manner, overall length 2309 of insert 2000 may be between about 0.5 mm and about 0.7 mm, but embodiments are not limited thereto.

Head portion 2001 may include gas inlet surface 2005, intermediate surface 2007 opposing or spaced apart from gas inlet surface 2005 in the axial direction, and lateral surface 2009 connecting intermediate surface 2007 to gas inlet surface 2005. In this manner, head portion 2001 may extend along reference axis 2011, which may be a central axis of not only insert 2000, but also head portion 2001. Body portion 2003 may include proximal end 2013, distal end 2015 opposing or spaced apart from proximal end 2013 in the axial direction, and lateral surface 2017 connecting distal end 2015 to proximal end 2013. As such, proximal end 2013 may extend from, and, thereby, may be adjacent to intermediate surface 2007. Distal end 2015 may terminate at distal surface 2019. In this manner, body portion 2003 may also extend along reference axis 2011, which may also be a central axis of body portion 2003.

According to some implementations, insert 2000 may include bore 2311 extending from gas inlet surface 2005 towards distal surface 2019 along reference axis 2011, which may be a central axis of bore 2311. As such, bore 2311 may form a central bore of insert 2000, but embodiments are not limited thereto. Bore 2311 may be formed as a void with a generally circular cylinder configuration, but implementations are not limited thereto. For instance, bore 2311 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 2311 will be described as having a generally cylindrical configuration, but it should be appreciated that reference to a surface (e.g., interior surface) of such a shape may refer to one or more surfaces of another shape or formation of bore 2311.

As depicted in FIG. 23, bore 2311 may terminate at distal surface 2313 offset from distal surface 2019 in a first direction (e.g., the z-axis direction) such that bore 2311 extends through head portion 2001 and partially through body portion 2003. In this manner, bore 2311 may have depth 2315 in, for example, the axial direction, and a maximum dimension (e.g., diameter) 2317 in, for instance, the second direction. For example, depth 2315 may be between about 0.5 mm and about 0.6 mm, and maximum dimension 2317 may be between about 0.1 mm and about 0.1 mm. In this manner, bore 2311 may have a greater depth within insert 2000 than bores 509, 909, 1311, and 1711 respectively within inserts 300, 700, 1100, and 1700. Furthermore, maximum dimension 2317 of bore 2311 may be smaller than respective maximum dimensions 515, 915, 1317, and 1717 of bores 509, 909, 1311, and 1711 within corresponding inserts 300, 700, 1100, and 1700. It is noted that, depending on the geometric configuration of bore 2311, maximum dimension 2317 may be a width of bore 2311. Body portion 2003 may also include a plurality of gas outlet orifices 2021 fluidically connected to bore 2311 within an interior of insert 2000. Although a total of fourteen gas outlet orifices 2021 are depicted, insert 2000 may include any suitable number of gas outlet orifices 2021. In some cases, gas outlet orifices 2021 may extend between interior surface 2319 of bore 2311 and lateral surface 2017 so as to enable one or more gases input to bore 2311 at gas inlet surface 2005 to flow through bore 2311 and gas outlet orifices 2021, and, thereby, to be output from lateral surface 2017.

Gas outlet orifices 2021 may include first gas outlet orifices 2021a and second gas outlet orifices 2021b offset from first gas outlet orifices 2021a in the axial direction. First gas outlet orifices 2021a may be closer to proximal end 2013 of body portion 2003 than second gas outlet orifices 2021b. Similar to bore 2311, gas outlet orifices 2021 may be formed as voids with generally circular cylinder configurations, but embodiments are not limited thereto. For instance, one or more of gas outlet orifices 2021 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 2021 will be described as having generally cylindrical configurations, but it should be appreciated that reference to a surface (e.g., interior surface) of such a shape may refer to one or more surfaces of another shape or formation. Whatever the case, each of gas outlet orifices 2021 may have a central axis and a maximum dimension (e.g., diameter) in a plane perpendicular to the central axis.

For instance, first gas outlet orifices 2021a may have respective central axes (e.g., central axis 2101) and corresponding maximum dimensions (e.g., diameters), such as maximum dimension 2103. Second gas outlet orifices 2021b may have respective central axes (e.g., central axis 2201) and corresponding maximum dimensions (e.g., maximum dimension 2105). In some cases, central axes 2101 and 2201 may extend outwards from reference axis 2011, such as radially outwards from reference axis 2011. It is contemplated, however, that central axes 2101 and 2201 may extend outwards from reference axis 2011 in a manner that central axes 2101 and 2201 form corresponding angles of inclination with respect to reference axis 2011 or first reference plane 2107, which may be perpendicular (or substantially perpendicular) to reference axis 2011. It is noted that central axes (e.g., central axis 2101) of first gas outlet orifices 2021a may be spaced apart from distal surface 2313 by (or substantially by) distance 2321, and central axes (e.g., central axis 2201) of second gas outlet orifices 2021b may be spaced apart from distal surface 2313 by (or substantially by) distance 2323. It is noted that distances 2321 and 2323 may extend in the axial direction, but embodiments are not limited thereto. It is also noted that the corresponding maximum dimensions (e.g., maximum dimensions 2103 and 2105) of first and second gas outlet orifices 2021a and 2021b may extend in, for instance, the second direction. Maximum dimensions 2103 and 2105 may, in some embodiments, be equivalent (or substantially equivalent). In some implementations, maximum dimensions 2103 and 2105 may be between about 0.01 mm and about 0.1 mm, such as between about 0.02 mm and about 0.07 mm, e.g., between about 0.03 mm and about 0.05 mm. Also, in various embodiments, respective surfaces of second gas outlet orifices 2021b may be tangent to reference plane 2313p, which may include distal surface 2313.

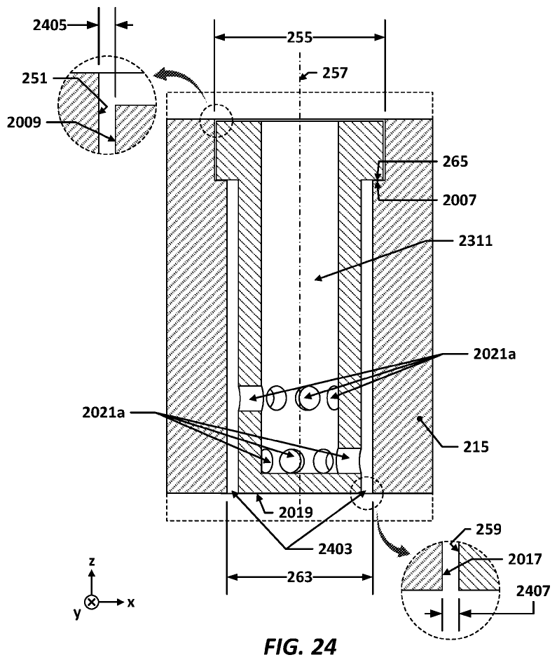

Corresponding lengths (e.g., length 2325) of gas outlet orifices 2021 may be respectively smaller than depth 2315 of bore 2311. For instance, the lengths (e.g., length 2325) may be between about 0.06 mm and about 0.08 mm. In this manner, gas outlet orifices 2021 may have longer lengths within insert 2000 than gas outlet orifices 1121 within insert 1100. This increase in depth of bore 2311, decrease in maximum dimension 2317 of bore 2311, and increase in length of gas outlet orifices 2021 may cause, at least in part, a greater pressure drop between gas inlet surface 2005 and lateral surface 2017 in association with a flow of gas through insert 2000 under conditions in the slip flow regime. This decrease in downstream pressure may also be attributable to a combination between insert 2000 and gas distribution port 207 of gas distributor 200. For example, when insert 2000 is at least partially supported in gas distribution port 207, a spacing (such as distance 2407 in FIG. 24) between lateral surface 2017 of body portion 2003 and inner surface 259 of gas distribution port 207 may extend the effective lengths of gas outlet orifices 2021 and effectively form a single gas outlet port 2403 (see, e.g., FIG. 24) encircling distal surface 2019 of insert 2000. An effective outlet area of gas outlet port 2403 may be greater than respective outlet areas of gas outlet orifices 2021, and, in this manner, flow conductance may increase. For instance, assuming a flow of gas in the slip flow regime, a pressure drop through insert 2000 may be less than or equal to about 150×10⁻³ Torr, such as less than or equal to about 100×10⁻³ Torr, e.g., about 81×10⁻³ Torr. In some embodiments, increasing the flow conductance decreases flow resistance, which enables a greater throughput to be achieved in association with gas outlet port 2403.

In various embodiments, an acceleration of gas flow in an area corresponding to gas outlet port 2403 may prevent or at least reduce the likelihood of back diffusion into gas distribution port 207, and, thereby, into showerhead 107. For example, gas flow from gas outlet orifices 2021 may help inject purge gas into a gap between lateral surface 2017 of insert 2000 and a lower portion of inner surface 259 of gas distribution port 207 near opening 205 before flowing through region 129. It is noted that gas outlet orifices 2021 may be configured to inject the purges gas(es) further up gas distribution port 207 than gas outlet orifices 1527 of insert 1500. Such a flow of the purge gas(es) may additionally discourage process gas(es) from flowing into one or more of the gap, insert 2000, and/or showerhead 107 that might otherwise degrade insert 2000 and/or showerhead 107. Moreover, given that gas outlet orifices 2021 may be configured to inject the purges gas(es) further up gas distribution port 207 than gas outlet orifices 1527 of insert 1500, insert 2000 may form a greater barrier to the process gas(es) than insert 1500. In addition, the flow of gas from gas outlet orifices 2021 may also prevent or at least reduce the likelihood of material deposition between insert 2000 and inner surface 259 of gas distribution port 207, and/or decrease the likelihood material shedding and/or particulate formation that may result in defect causing contaminates being deposited onto frontside 203 of wafer 105 or structures formed thereon/therein. It is also contemplated that the acceleration of the gas flow in the area corresponding to gas outlet port 2403 may be utilized during a clean cycle (or process) to remove a coating, residue, debris, etc., on inner surface 259 of gas distribution port 207 and/or lateral surface 2017.

According to various embodiments, first and second gas outlet orifices 2021a and 2021b may be circumferentially arranged about reference axis 2011. In such a configuration, first gas outlet orifices 2021a and second gas outlet orifices 2021b may be arranged about reference axis 2011 with corresponding angular pitches, such as angular pitch 2203. In some instances, an angular pitch associated with first gas outlet orifices 2021a may be equivalent (or substantially equivalent) to an angular pitch (e.g., angular pitch 2203) associated with second gas outlet orifices 2021b, but embodiments are not limited thereto. Assuming insert 2000 has “k” second gas outlet orifices 2021b (where “k” is an integer greater than or equal to two), then angular pitch 2203 may be equivalent (or substantially equivalent) to 360° divided by “k.” For example, insert 2000 is shown including seven second gas outlet orifices 2021b such that angular pitch 2203 may be about 51.4°, but embodiments are not limited thereto. The same may be true with respect to the angular pitch associated with first gas outlet orifices 2021a. It is also noted that first gas outlet orifices 2021a may be circumferentially offset from second gas outlet orifices 2021b such that center lines (e.g., center line 2109) extending in the axial direction of first gas outlet orifices 2021a may be incongruent with center lines (e.g., center line 2111) extending in the axial direction of second gas outlet orifices 2021b. In some instances, the circumferential offset between first gas outlet orifices 2021a and second gas outlet orifices 2021b may be half the amount of angular pitch 2203, but embodiments are not limited thereto.

According to various embodiments, insert 2000 may be formed of any suitable material, as well as formed in any suitable manner. For example, insert 2000 may be formed of (or include) one or more ceramic materials, such as aluminum oxide, aluminum nitride, ruthenium oxide, titanium nitride, titanium aluminum nitride, titanium carbide, etc. In some cases, insert 2000 may be formed of a first material and coated with a second material. For example, insert 2000 may be manufactured from aluminum as the first material and may be coated with aluminum fluoride (AlF₃) as the second material, but embodiments are not limited thereto. In various implementations, insert 2000 may be additively manufactured, stamped, injection molded, compression molded, cast, machined, and/or the like.

FIG. 24 schematically illustrates a partial cross-sectional view of the showerhead of FIG. 2 including the gas distribution port insert of FIGS. 20-23 according to some embodiments.

With reference to FIGS. 2 and 20-23, insert 2000 may be at least partially supported in gas distribution port 207 such that intermediate surface 2007 of insert 2000 abuts against resting surface 265 of gas distribution port 207. Such an abutment between surfaces 265 and 2007 may prevent or at least reduce the likelihood of back diffusion into gas distribution port 207, and, thereby, into gas distributor 200. To this end, insert 2000 may be configured to form a clearance fit with gas distribution port 207. For instance, in some cases, maximum dimension 2303 of head portion 2001 of insert 2000 may be about 1% to about 10% smaller than maximum dimension 255 of first port portion 245 of gas distribution port 207 such that lateral surface 2009 of insert 2000 is spaced apart from inner surface 251 of gas distribution port 207 by distance 2405. To this end, maximum dimension 2307 of body portion 2003 of insert 2000 may be about 4% to about 15% smaller than maximum dimension 263 of second port portion 247 of gas distribution port 207 such that lateral surface 2017 of insert 2000 is spaced apart from inner surface 259 of gas distribution port 207 by distance 2407. In some cases, distance 2407 may be greater than distance 2405, but embodiments are not limited thereto. Further, distance 2407 may be less than or equal to about three quarters of a sheath thickness associated with a process performed in association with system 100. In some implementations, distance 2407 may be greater than or equal to about 0.3 mm and less than or equal to about 0.7 mm, e.g., greater than or equal to about 0.4 mm and less than or equal to about 0.6 mm, such as about 0.5 mm. Similar to head portions 301, 701, 1101, and 1501 of respective inserts 300, 700, 1100, and 1500, head portion 2001 of insert 2000 may serve as a centering mechanism when, for example, insert 2000 is inserted into gas distribution port 207 so as to enable a central axis (e.g., reference axis 2011) of insert 2000 to be coincident (or substantially coincident) with central axis 257 of gas distribution port 207.

Similar to inserts 300, 700, 1100, and 1500, the formation of the above-noted clearance fits may increase the distance between lateral surfaces 2009 and 2017 of insert 2000 and corresponding inner surfaces 251 and 259 of gas distribution port 207. This may reduce the potential for abrasion between insert 2000 and gas distribution port 207 that might otherwise occur as a result of thermally induced movement of insert 2000 relative to gas distribution port 207 that may be caused, at least in part, by temperature changes and/or fluctuations association with a semiconductor processing operation being performed via system 100. Although motion of insert 2000 has been described as being caused in association with thermal effects, it is also contemplated that the motion of insert 2000 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 2000 and gas distribution port 207 that might otherwise cause, at least in part, defect causing contaminates being deposited onto frontside 203 of wafer 105 and/or structures formed thereon/therein. To this end, the centering effect of head portion 2001 relative to body portion 2003 may also serve to return insert 2000 into concentric (or substantially concentric) alignment with gas distribution port 207 after movement of insert 2000. This may help maintain a determined gas flow profile from showerhead 107. The additional distance between lateral surface 2017 of insert 2000 and inner surface 259 of gas distribution port 207 relative to the distance between, for example, lateral surface 317 of insert 300 and inner surface 259 of gas distribution port 207 may also allow for a sufficient flow of purge gas from gas outlet orifices 2021.

### Gas Distribution Port Insert—6

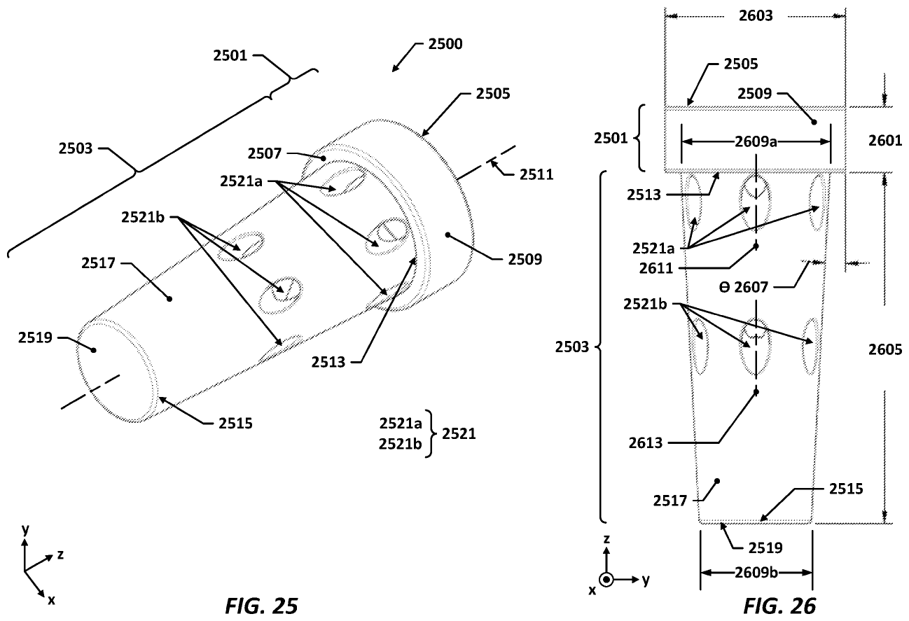

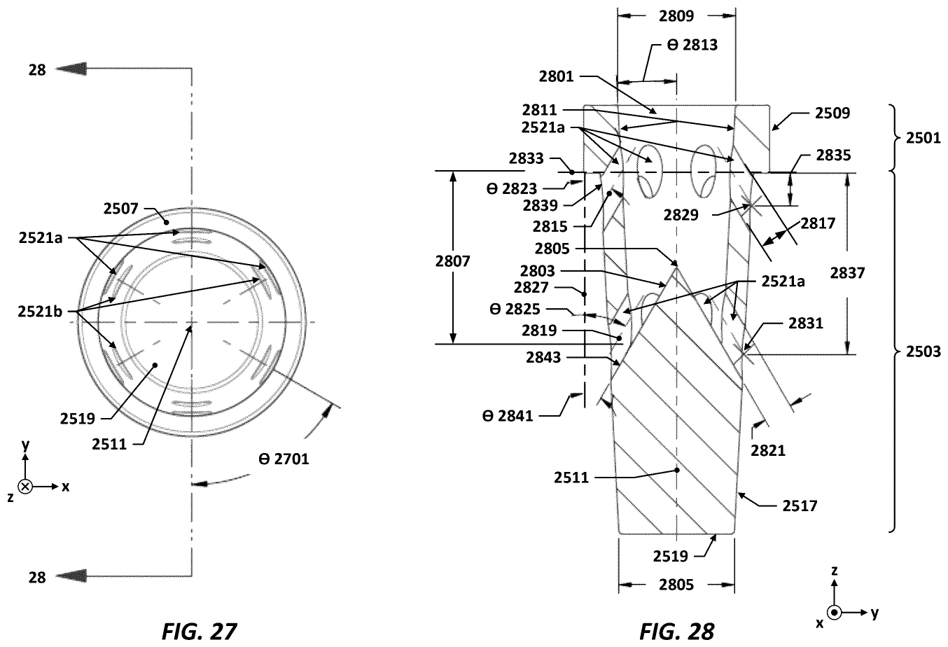

FIGS. 25-28 schematically depict various views of a gas distribution port insert (or insert) that may be incorporated as part of the showerhead of FIG. 2 according to some embodiments. For example, FIG. 25 depicts a perspective view of insert 2500, FIG. 26 depicts a side view of insert 2500, FIG. 27 depicts a bottom view of insert 2500, and FIG. 28 depicts a cross-sectional view of insert 2500 taken along sectional line 28-28.

With reference to FIGS. 25-28, insert 2500 may be similar to inserts 1100 and 2000, and, as such, may include head portion 2501 and body portion 2503 extending from head portion 2501 in an axial direction. The axial direction may extend in a direction opposite the z-axis direction. Head portion 2501 may be formed as a generally circular cylinder and body portion 2503 may be formed as a generally conical frustum, but embodiments are not limited thereto. For instance, either or both of head portion 2501 and body portion 2503 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, however, head portion 2501 and body portion 2503 will be described in association with FIGS. 25-28 as respectively having a generally cylindrical configuration and a generally conical frustum configuration, but it should be appreciated that reference to a surface of such a shape may refer to one or more surfaces of another shape.

Head portion 2501 may include gas inlet surface 2505, intermediate surface 2507 opposing or spaced apart from gas inlet surface 2505 in the axial direction, and lateral surface 2509 connecting intermediate surface 2507 to gas inlet surface 2505. In this manner, head portion 2501 may extend along reference axis 2511, which may be a central axis of not only insert 2500, but also head portion 2501. Body portion 2503 may include proximal end 2513, distal end 2515 opposing or spaced apart from proximal end 2513 in the axial direction, and lateral surface 2517 connecting distal end 2515 to proximal end 2513. As such, proximal end 2513 may extend from, and, thereby, may be adjacent to intermediate surface 2507. Distal end 2515 may terminate at distal surface 2519. In this manner, body portion 2503 may also extend along reference axis 2511, which may also be a central axis of body portion 2503.

According to various embodiments, head portion 2501 may have length 2601 in the axial direction and maximum dimension (e.g., diameter) 2603 in, for example, a second direction transverse to the axial direction. The second direction may be perpendicular (or substantially perpendicular) to the axial direction, and, as such, may extend in the y-axis direction. Body portion 2503 may have length 2605 in the axial direction and a variable width (e.g., diameter) in, for example, the second direction. In some embodiments, the width of body portion 2503 may vary linearly along the axial direction such that lateral surface 2517 forms angle of inclination (or angle) 2607 with the axial direction, and, in some cases, with lateral surface 2509. Angle 2607 may be greater than 0° and less than about 10°, such as greater than or equal to about 2.00° and less than or equal to about 5.00°, e.g., greater than or equal to about 2.75° and less than or equal to about 3.25°. As depicted, the width of body portion 2503 may have dimension 2609a at proximal end 2513 and dimension 2609b at distal end 2515. Depending on the geometric configuration of head portion 2501 and/or body portion 2503, dimensions 2603, 2609a, and/or 2609b may be widths of insert 2500. In some embodiments, dimension 2603 may be between about 0.1 mm and about 0.4 mm, dimension 2609a may be between about 0.1 mm and 0.2 mm, and dimension 2609b may be between about 0.1 mm and about 0.2 mm. To this end, maximum dimension 2603 may be greater than each of dimensions 2609a and 2609b. For instance, maximum dimension 2603 may be about 15% to about 25% greater than at least dimension 2609a (that is greater than dimension 2609b), but embodiments are not limited thereto. Length 2601 may be between about 0.05 mm and about 0.1 mm, and length 2605 may be between about 0.4 mm and about 0.6 mm. It is noted that length 2605 may be greater than length 2601, such as greater than length 2601 by about 450% to about 550%, but embodiments are not limited thereto. In this manner, an overall length of insert 2500 may be between about 0.5 mm and about 0.7 mm, but embodiments are not limited thereto.

According to various implementations, insert 2500 may include bore 2801 extending from gas inlet surface 2505 towards distal surface 2519 along reference axis 2511, which may be a central axis of bore 2801. As such, bore 2801 may form a central bore of insert 2500, but embodiments are not limited thereto. Bore 1311 may be formed as a void with a generally conical frustum configuration, but implementations are not limited thereto. For instance, bore 2801 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 2801 will be described as having a generally conical frustum configuration, but it should be appreciated that reference to a surface (e.g., interior surface) of such a shape may refer to one or more surfaces of another shape or formation of bore 2801.

As shown in FIG. 28, bore 2801 may terminate at distal surface 2803 offset from distal surface 2519 in a first direction (e.g., the z-axis direction) such that bore 2801 extends through head portion 2501 and partially through body portion 2503. It is noted, however, that unlike distal surface 1313 in insert 1100, distal surface 2803 may be formed as a generally conical protrusion having apex 2805 extending in the first direction towards gas inlet surface 2505. In some embodiments, reference axis 2511 may extend through apex 2805 such that apex 2805 is concentrically aligned with bore 2801. Also, bore 2801 may have a maximum depth 2807 in, for example, the axial direction, and a maximum dimension (e.g., diameter) 2809 in, for instance, the second direction at gas inlet surface 2505. Inner sidewall 2811 of bore 2801 may converge towards reference axis 2511 such that inner sidewall 2811 forms angle 2813 with reference axis 2511. In some cases, angle 2813 may be greater than about 0° and less than or equal to about 10°. It is noted that depth 2807 of bore 2801 may be smaller than depth 1315 of bore 1311 in insert 1100. Maximum dimension 2809 may be greater than maximum dimension 1317 of bore 1311 in insert 1100. In some cases, maximum dimension 2809 may be between about 0.1 mm and about 0.2 mm (and at least smaller than each of dimensions 2609a and 2609b). In this manner, bore 2801 may have a smaller greater depth within insert 2500 than each of bores 509, 909, 1311, 1711 respectively in inserts 300, 700, 1100, and 1500. It is also noted that, depending on the geometric configuration of bore 2801, maximum dimension 2809 may be a width of bore 2801. Body portion 2503 may also include a plurality of gas outlet orifices 2521 fluidically connected to bore 2801 within an interior of insert 2500. Although a total of twelve gas outlet orifices 2521 are depicted, insert 2500 may include any suitable number of gas outlet orifices 2521. In some cases, gas outlet orifices 2521 may extend between inner sidewall 2811 and lateral surface 2517 so as to enable one or more gases input to bore 2801 at gas inlet surface 2505 to flow through bore 2801 and gas outlet orifices 2521, and, thereby, to be output from lateral surface 2517.

Gas outlet orifices 2521 may include first gas outlet orifices 2521a and second gas outlet orifices 2521b offset from first gas outlet orifices 2521a in the axial direction. First gas outlet orifices 2521a may be closer to proximal end 2513 of body portion 2503 than second gas outlet orifices 2521b. Gas outlet orifices 2521 may be formed as voids with generally circular cylinder configurations, but embodiments are not limited thereto. For instance, one or more of gas outlet orifices 2521 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 2521 will be described as having generally cylindrical configurations, but it should be appreciated that reference to a surface (e.g., interior surface) of such a shape may refer to one or more surfaces of another shape or formation. Whatever the case, each of gas outlet orifices 2521 may have a central axis and a maximum dimension (e.g., diameter) in a plane perpendicular to the central axis.

For instance, first gas outlet orifices 2521a may have respective central axes, such as central axis 2815, and corresponding maximum dimensions (e.g., diameters), such as maximum dimension 2817. Second gas outlet orifices 2521b may have respective central axes (e.g., central axis 2819) and corresponding maximum dimensions (e.g., maximum dimension 2821). In some cases, maximum dimensions 2817 and 2821 may be equivalent (or substantially equivalent). Further, central axes 2815 and 2819 may extend outwards from reference axis 2511, and, thereby, form respective angles of inclination (or angles), e.g., angles 2823 and 2825, with reference axis 2511. However, for convenience, angles 2823 and 2825 are depicted relative to reference plane 2827, which extends parallel to reference axis 2511. Angles 2823 and 2825 may be equivalent (or substantially equivalent), but embodiments are not limited thereto. Also, central axes 2815 and 2819 may respectively intersect with lateral surface 2517 at points 2829 and 2831, which may be respectively spaced apart from reference plane 2833 by distances 2835 and 2837 in the axial direction.

Similar to inserts 1500 and 2000, the angling of gas outlet orifices 2521 relative to reference axis 2011 and inner surface 259 of gas distribution port 207 may help inject purge gas into a gap between lateral surface 2517 of insert 2500 and a lower portion of inner surface 259 of gas distribution port 207 near opening 205 before flowing through region 129. It is noted, however, that gas outlet orifices 2521 may be configured to inject the purges gas(es) even further up gas distribution port 207 than gas outlet orifices 1527 of insert 1500 and gas outlet orifices 2021 of insert 2000. Such a flow of the purge gas(es) may additionally discourage process gas(es) from flowing into one or more of the gap, insert 2500, and/or showerhead 107 that might otherwise degrade insert 2500 and/or showerhead 107. Moreover, given that gas outlet orifices 2521 may be configured to inject the purges gas(es) even further up gas distribution port 207 than gas outlet orifices 1527 of insert 1500 and gas outlet orifices 2021 of insert 2000, insert 2500 may form an even greater barrier to the process gas(es) than inserts 1500 and 2000. In addition, the flow of gas from gas outlet orifices 2527 may also prevent or at least reduce the likelihood of material deposition between insert 2500 and inner surface 259 of gas distribution port 207, and/or decrease the likelihood of material shedding and/or particulate formation that may result in defect causing contaminates being deposited onto frontside 203 of wafer 105 or structures formed thereon/therein.

In some embodiments, intermediate surface 2507 may extend in reference plane 2833 and maximum dimensions (e.g., maximum dimensions 2817) of first gas outlet orifices 2521a may be sized such that respective openings 2839 of first gas outlet orifices 2521a are formed tangent to reference plane 2833. As such, first gas outlet orifices 2521a may include respective portions extending within head portion 2501 of insert 2500. According to some implementations, slope angle (or angle) 2841 of distal surface 2803 may be equivalent (or substantially equivalent) to angle 2825 and maximum dimensions (such as maximum dimensions 2821) of second gas outlet orifices 2521b may be sized such that corresponding portions of distal surface 2803 form respective portions of interior surfaces 2843 of second gas outlet orifices 2521b. In other words, respective interior surfaces 2843 of second gas outlet orifices 2521b may be tangent to distal surface 2803. With such a configuration, the respective openings of gas outlet orifices 2521 (such as opening 2839) may have generally elliptical shapes in lateral surface 2517 and inner sidewall 2811 although gas outlet orifices 2521 may have respective generally circular cross-sections in planes perpendicular to their corresponding axes of longitudinal extension.

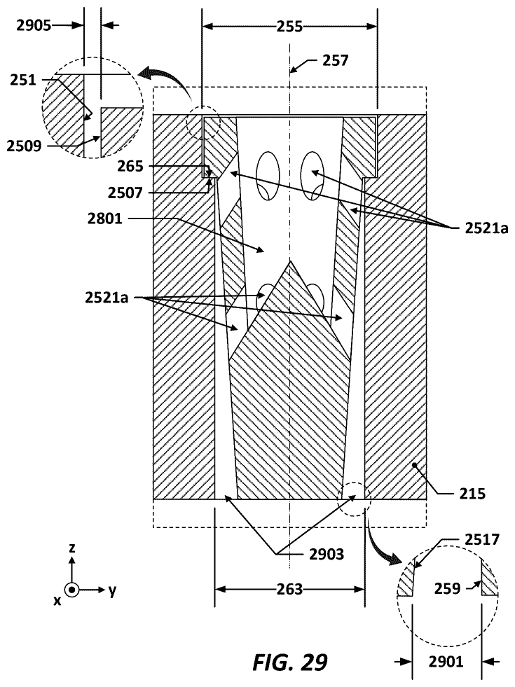

According to various implementations, maximum dimensions 2817 and 2821 may be between about 0.01 mm and about 0.1 mm, such as between about 0.02 mm and about 0.07 mm, e.g., between about 0.03 mm and about 0.05 mm. Respective lengths (or depths) of gas outlet orifices 2521 may be smaller than depth 2807 of bore 2801. In this manner, gas outlet orifices 2521 may have respectively shorter lengths within insert 2500 than gas outlet orifices 321 within insert 300 and gas outlet orifices 721 within insert 700, but may have respectively longer lengths within insert 2500 than gas outlet orifices 1527 within insert 1500 and gas outlet orifices 2021 within insert 2000. The shorting of maximum depth 2807 of bore 2801 and the relative sizing of the corresponding lengths of gas outlet orifices 2521 may cause, at least in part, a pressure drop between gas inlet surface 2505 and lateral surface 2517 in association with a flow of gas through insert 2500 under conditions in the slip flow regime similar in magnitude to the pressure drop exhibited in association with insert 2000. This decrease in downstream pressure may also be attributable to the protruding, conical shape of distal surface 2803 in bore 2801 and a combination between insert 2500 and gas distribution port 207 of gas distributor 200. For example, in the slip flow regime, it is expected that the mean velocity of the gas flow in a central portion of bore 2803 would be relatively constant and greater than the mean velocity of the gas flow near inner sidewall 2811 of bore 2801. Accordingly, the protruding, conical shape of distal surface 2803 in bore 2801 may distribute and force more of this faster moving gas out of second gas outlet orifices 2521b before it has more of an opportunity to lose momentum. Moreover, when insert 2500 is at least partially supported in gas distribution port 207, a spacing (such as distance 2901 in FIG. 29) between lateral surface 2517 of body portion 2503 and inner surface 259 of gas distribution port 207 may extend the effective lengths of gas outlet orifices 2521 and effectively form a single gas outlet port 2903 (see, e.g., FIG. 29) encircling distal surface 2519 of insert 2500. An effective outlet area of gas outlet port 2903 may be greater than the respective outlet areas of gas outlet orifices 2521, and, in this manner, flow conductance may increase. In various embodiments, increasing the flow conductance decreases flow resistance, which enables a greater throughput to be achieved in association with gas outlet port 2903. For instance, assuming a flow of gas in the slip flow regime, a pressure drop through insert 2500 may be less than or equal to about 150×10⁻³ Torr, such as less than or equal to about 100×10⁻³ Torr, e.g., about 80×10⁻³ Torr. It is noted that an acceleration of gas flow in an area corresponding to gas outlet port 2903 may prevent or at least reduce the likelihood of back diffusion into gas distribution port 207, and, thereby, into gas distributor 200. Such an acceleration of the gas flow in the area corresponding to gas outlet port 2903 may be utilized during a clean cycle (or process) to remove a coating, residue, debris, etc., on inner surface 259 of gas distribution port 207 and/or lateral surface 2517. Further, given the tapering configuration of body portion 2503 of insert 2500 and the closer positioning of gas outlet orifices 2521 to intermediate surface 2507 than gas outlet orifices 2021 relative to intermediate surface 2007 of insert 2000, more of inner surface 259 of gas distributor 200 and lateral surface 2517 of insert 2500 may be exposed to this faster moving gas, and, as such, may further promote the aforementioned preventative and cleaning features.

With particular reference to FIGS. 26 and 27, first and second gas outlet orifices 2521a and 2521b may be circumferentially arranged about reference axis 2511. In such a configuration, first gas outlet orifices 2521a and second gas outlet orifices 2521b may be arranged about reference axis 2511 with corresponding angular pitches, such as angular pitch 2701. In some instances, an angular pitch associated with first gas outlet orifices 2521a may be equivalent (or substantially equivalent) to an angular pitch associated with second gas outlet orifices 2521b, but embodiments are not limited thereto. Assuming insert 2500 includes “k” first gas outlet orifices 2521b (where “k” is an integer greater than or equal to two), then the angular pitch between adjacent first gas outlet orifices 2521b may be equivalent (or substantially equivalent) to 360° divided by “k.” For example, insert 2500 is shown including six first gas outlet orifices 2521a such that the angular pitch between adjacent first gas outlet orifices 2521b may be about 60°, but embodiments are not limited thereto. The same may be true with respect to the angular pitch between adjacent second gas outlet orifices 2021b. In some implementations, respective central axes 2815 of first gas outlet orifices 2521a may be circumferentially aligned with corresponding central axes 2819 of second gas outlet orifices 2521b such that center lines (e.g., center line 2611) extending tangent to lateral surface 2517 of first gas outlet orifices 2521a may be congruent with center lines (e.g., center line 2613) extending tangent to lateral surface 2517 of second gas outlet orifices 2521b, but embodiments are not limited thereto.

According to various embodiments, insert 2500 may be formed of any suitable material, as well as formed in any suitable manner. For example, insert 2500 may be formed of (or include) one or more ceramic materials, such as aluminum oxide, aluminum nitride, ruthenium oxide, titanium nitride, titanium aluminum nitride, titanium carbide, etc. In some cases, insert 2500 may be formed of a first material and coated with a second material. For example, insert 2500 may be manufactured from aluminum as the first material and may be coated with aluminum fluoride (AlF₃) as the second material, but embodiments are not limited thereto. In various implementations, insert 2500 may be additively manufactured, stamped, injection molded, compression molded, cast, machined, and/or the like.

FIG. 29 schematically illustrates a partial cross-sectional view of the showerhead of FIG. 2 including the gas distribution port insert of FIGS. 25-28 according to some embodiments.

With reference to FIGS. 2 and 25-28, insert 2500 may be at least partially supported in gas distribution port 207 such that intermediate surface 2507 of insert 2500 abuts against resting surface 265 of gas distribution port 207. To this end, insert 2500 may be configured to form a clearance fit with gas distribution port 207. For instance, in some cases, maximum dimension 2603 of head portion 2501 of insert 2500 may be about 1% to about 10% smaller than maximum dimension 255 of first port portion 245 of gas distribution port 207 such that lateral surface 2509 of insert 2500 is spaced apart from inner surface 251 of gas distribution port 207 by distance 2905. Dimension 2609a of body portion 2503 of insert 2500 may be about 1% to about 10% smaller than maximum dimension 263 of second port portion 247 of gas distribution port 207 and dimension 2609b may be about 8% to about 15% smaller than maximum dimension 263 of second port portion 247 of gas distribution port 207. In this manner, lateral surface 2517 of insert 2500 may be spaced apart from inner surface 259 of gas distribution port 207 by a first distance, e.g., distance 2905, with respect to proximal end 2513 of body portion 2503 and may be spaced apart from inner surface 259 of gas distribution port 207 by a second distance, e.g., distance 2901, with respect to distal end 2515 of body portion 2503. In some cases, distance 2901 may be less than or equal to a sheath thickness associated with a process being performed in association with system 100. For example, distance 2901 may be greater than or equal to about 0.6 mm and less than or equal to about 0.9 mm, e.g., greater than or equal to about 0.7 mm and less than or equal to about 0.8 mm, such as about 0.76 mm. It is also noted that head portion 2501 may serve as a centering mechanism when insert 2500 is inserted into gas distribution port 207 so as to enable a central axis (e.g., reference axis 2511) of insert 2500 to be coincident (or substantially coincident) with central axis 257 of gas distribution port 207 when incorporated as part of gas distributor 200.

Similar to inserts 300, 700, 1100, 1500, and 2000, the formation of the above-noted clearance fits may increase the distance between lateral surfaces 2509 and 2517 of insert 2500 and corresponding inner surfaces 251 and 259 of gas distribution port 207. This may reduce the potential for abrasion between insert 2500 and gas distribution port 207 that might otherwise occur as a result of thermally induced movement of insert 2500 relative to gas distribution port 207 that may be caused, at least in part, by temperature changes and/or fluctuations association with a semiconductor processing operation being performed via system 100. Although motion of insert 2500 has been described as being caused in association with thermal effects, it is also contemplated that the motion of insert 2500 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 2500 and gas distribution port 207 that might otherwise cause, at least in part, defect causing contaminates being deposited onto frontside 203 of wafer 105 and/or structures formed thereon/therein. Also, the centering effect of head portion 2501 relative to body portion 2503 may also serve to return insert 2500 into concentric (or substantially concentric) alignment with gas distribution port 207 after movement of insert 2500. This may help maintain a determined gas flow profile from showerhead 107. The additional distance between lateral surface 2517 of insert 2500 and inner surface 259 of gas distribution port 207 relative to the distance between, for example, lateral surface 317 of insert 300 and inner surface 259 of gas distribution port 207 may also allow for a sufficient flow of purge gas from gas outlet orifices 2521.

### Gas Distribution Port Insert—7

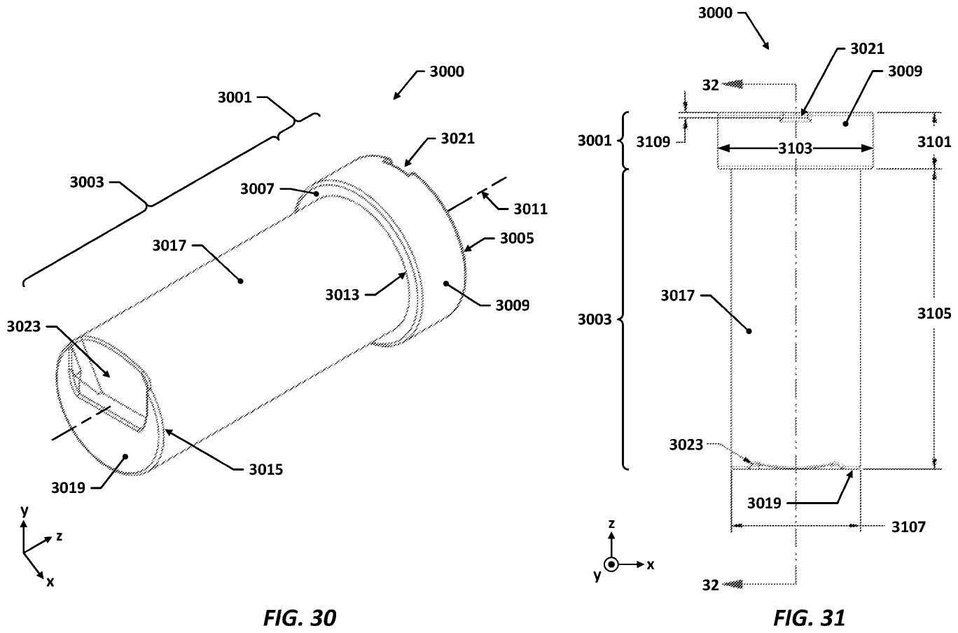

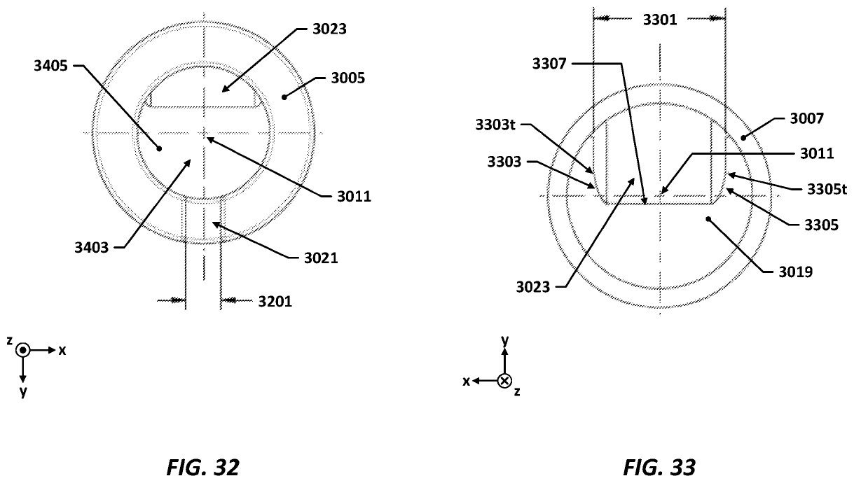

FIGS. 30-33 schematically depict various views of a gas distribution port insert (or insert) that may be incorporated as part of the showerhead of FIG. 2 according to some embodiments. For example, FIG. 30 depicts a perspective view of insert 3000, FIG. 31 depicts a side view of insert 2000, FIG. 32 depicts a top view of insert 3000, FIG. 33 depicts a bottom view of insert 3000, and FIG. 34 depicts a cross-sectional view of insert 3000 taken along sectional line 34-34.

Referring to FIGS. 30-33, insert 3000 may include head portion 3001 and body portion 3003 extending from head portion 3001 in an axial direction, which may extend in a direction opposite the z-axis direction. Both head portion 3001 and body portion 3003 may be formed as generally circular cylinders, but embodiments are not limited thereto. For instance, either or both of head portion 3001 and body portion 3003 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 3001 and body portion 3003 will be described in association with FIGS. 30-33 as having generally cylindrical configurations, but it should be appreciated that reference to a surface of such a shape may refer to one or more surfaces of another shape.

According to various embodiments, head portion 3001 may have length 3101 in the axial direction and maximum dimension (e.g., diameter) 3103 in, for example, a second direction transverse to the axial direction. For example, the second direction may be perpendicular (or substantially perpendicular) to the axial direction, and, as such, may extend in the x-axis direction. Body portion 3003 may have length 3105 in the axial direction and maximum dimension (e.g., diameter) 3107 in the second direction. Depending on the geometric configuration of head portion 3001 and body portion 3003, maximum dimensions 3103 and 3107 may be widths of insert 3100. In some embodiments, maximum dimension 3103 may be between about 0.1 mm and about 0.4 mm, and maximum dimension 3107 may be between about 0.1 mm and 0.2 mm. Whatever the case, maximum dimension 3103 may be greater than maximum dimension 3107, such as greater than maximum dimension 3107 by about 15% to about 25%, but embodiments are not limited thereto. It is also noted that length 3101 may be between about 0.05 mm and about 0.1 mm, and length 3105 may be between about 0.4 mm and about 0.6 mm. In some instances, length 3105 may be greater than length 3101, such as greater than length 3101 by about 450% to about 550%, but embodiments are not limited thereto. As such, overall length 3401 of insert 3000 may be between about 0.5 mm and about 0.7 mm, but embodiments are not limited thereto.

Head portion 3001 may include gas inlet surface 3005, intermediate surface 3007 opposing or spaced apart from gas inlet surface 3005 in the axial direction, and lateral surface 3009 connecting intermediate surface 3007 to gas inlet surface 3005. In this manner, head portion 3001 may extend along reference axis 3011, which may be a central axis of not only insert 3000, but also head portion 3001. Body portion 3003 may include proximal end 3013, distal end 3015 opposing or spaced apart from proximal end 3013 in the axial direction, and lateral surface 3017 connecting distal end 3015 to proximal end 3013. As such, proximal end 3013 may extend from, and, thereby, may be adjacent to intermediate surface 3007. Distal end 3015 may terminate at distal surface 3019. In this manner, body portion 3003 may also extend along reference axis 3011, which may also be a central axis of body portion 3003.

According to various embodiments, insert 3000 may include bore 3403 extending from gas inlet surface 3005 towards distal surface 3019 along reference axis 3011, which may be a central axis of bore 3403. As such, bore 3403 may form a central bore of insert 3000, but embodiments are not limited thereto. Bore 3403 may be formed as a void with a generally circular cylinder configuration, but implementations are not limited thereto. For instance, bore 3403 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 3403 will be described as having a generally cylindrical configuration, but it should be appreciated that reference to a surface (e.g., interior surface) of such a shape may refer to one or more surfaces of another shape or formation of bore 3403.

As depicted in FIG. 34, bore 3403 may terminate at distal surface 3405 offset from distal surface 3019 in a first direction (e.g., the z-axis direction) such that bore 3403 extends through head portion 3001 and partially through body portion 3003. In this manner, bore 3403 may have depth 3407 in, for example, the axial direction, and a maximum dimension (e.g., diameter) 3409 in, for instance, the second direction. For example, depth 3407 may be between about 0.4 mm and about 0.7 mm, and maximum dimension 3409 may be between about 0.1 mm and about 0.2 mm (and at least smaller than each of dimensions 3103 and 3107). It is noted that, depending on the geometric configuration of bore 3403, maximum dimension 3409 may be a width of bore 3403.

According to various embodiments, head portion 3001 may include recessed portion 3021 in gas inlet surface 3005. Recessed portion 3021 may have depth 3109 in the axial direction and may longitudinally extend in a third direction transverse to the axial direction. For example, the third direction may extend in the y-axis direction. In this manner, recessed portion 3021 may extend from lateral surface 3009 to bore 3403, and, thereby, may be fluidically connected to bore 3403 within head portion 3001. Width 3201 of recessed portion 3021 may extend in, for example, the second direction. In various implementations, width 3201 may be between about 0.02 mm and about 0.06 mm, and depth 3109 may be between about 0.005 mm and about 0.02 mm. Body portion 3003 may include gas outlet orifice 3023 having proximal end opening 3411 fluidically connected to bore 3403 within an interior of insert 3000 and distal end opening 3413 at least formed in distal surface 3019. As such, gas outlet orifice 3023 may at least extend between distal surfaces 3405 and 3019 so as to enable one or more gases input to bore 3403 at gas inlet surface 3005 to flow through bore 3403 and gas outlet orifice 3023, and, thereby, to be output from at least distal surface 3019. In some cases, gas outlet orifice 3023 may also be formed in a portion of lateral surface 3017 such that at least some of the one or more input gases may be output from lateral surface 3017. In this manner, distal end opening 3413 of gas outlet orifice 3023 may span between distal surface 3019 and lateral surface 3017.

Gas outlet orifice 3023 may be formed as a void with generally rectilinear prism configuration, but embodiments are not limited thereto. For instance, gas outlet orifice 3023 may be formed as a void having any suitable geometric configuration, such as a generally cylindrical void, a cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifice 3023 will be described as having a generally rectilinear prism configuration, but it should be appreciated that reference to a surface (e.g., interior surface) of such a shape may refer to one or more surfaces of another shape or formation. Whatever the case, gas outlet orifice 3023 may have central axis of longitudinal extension (hereinafter, “central axis”) 3415 extending in a fourth direction transverse to the axial direction, maximum width 3301 in the second direction, and height 3417 in a fifth direction perpendicular to the fourth direction. In some implementations, rearward portions 3303 and 3305 of opposing sidewalls of gas outlet orifice 3023 may be arcuately formed such that a width of gas outlet orifice 3023 increases in size with increasing distance from rearward surface 3307 up to points 3303t and 3305t at which point the width of gas outlet orifice may be maximum width 3301, but embodiments are not limited thereto. Points 3303t and 3305t may be formed forward of reference axis 3011 in the y-axis direction, whereas rearward surface 3307 may be formed aft of reference axis 3011 in a direction opposite the y-axis direction. Central axis 3415 may form angle 3418 with reference plane 3419, which may extend perpendicularly to the axial direction and may include distal surface 3019. In some instances, angle 3418 may be greater than or equal to about 10° and less than or equal to about 30°, such as greater than or equal to about 15° and less than or equal to about 25°, e.g., about 20°. Further, maximum width 3301 may be between about 0.1 mm and about 0.2 mm, and height 3417 may be between about 0.2 mm and about 0.5 mm. Such a configuration of insert 3000 may cause, at least in part, a pressure drop between gas inlet surface 3005 and distal end opening 3413 of less than 500×10⁻⁴ Torr in association with a flow of gas through insert 3000 under conditions in the slip flow regime, e.g., about 495×10⁻⁴ Torr.

Further, the configuration of insert 3000 may be configured to cause, at least in part, a substantially directional flow of gas in the fourth direction from gas outlet orifice 3023. Accordingly, when one or more of inserts 3000 are incorporated as part of, for example, showerhead 107, such a directional flow of gas from gas outlet orifices 3023 may be utilized to propel purge gas radially outwards from an axis (e.g., central axis 141) of showerhead 107 in region 129. This may discourage process gas(es) from region 131 from flowing into the gap between showerhead 107 and frontside 203 of wafer 105 and/or reaching at least one of gas distribution ports 207 of showerhead 107, inserts 3000 incorporated as part of showerhead 107, and frontside 203 of wafer 105 or features formed thereon or therein. By discouraging such a flow of purge gas(es) into region 129, showerhead 107 including one or more of inserts 3000 may prevent or at least reduce the potential for process gas interaction with showerhead 107 and/or back diffusion into gas distribution ports 207 of showerhead 107.

According to various embodiments, insert 3000 may be formed of any suitable material, as well as formed in any suitable manner. For example, insert 3000 may be formed of (or include) one or more ceramic materials, such as aluminum oxide, aluminum nitride, ruthenium oxide, titanium nitride, titanium aluminum nitride, titanium carbide, etc. In some cases, insert 3000 may be formed of a first material and coated with a second material. For example, insert 3000 may be manufactured from aluminum as the first material and may be coated with aluminum fluoride (AlF₃) as the second material, but embodiments are not limited thereto. In various implementations, insert 3000 may be additively manufactured, stamped, injection molded, compression molded, cast, machined, and/or the like.

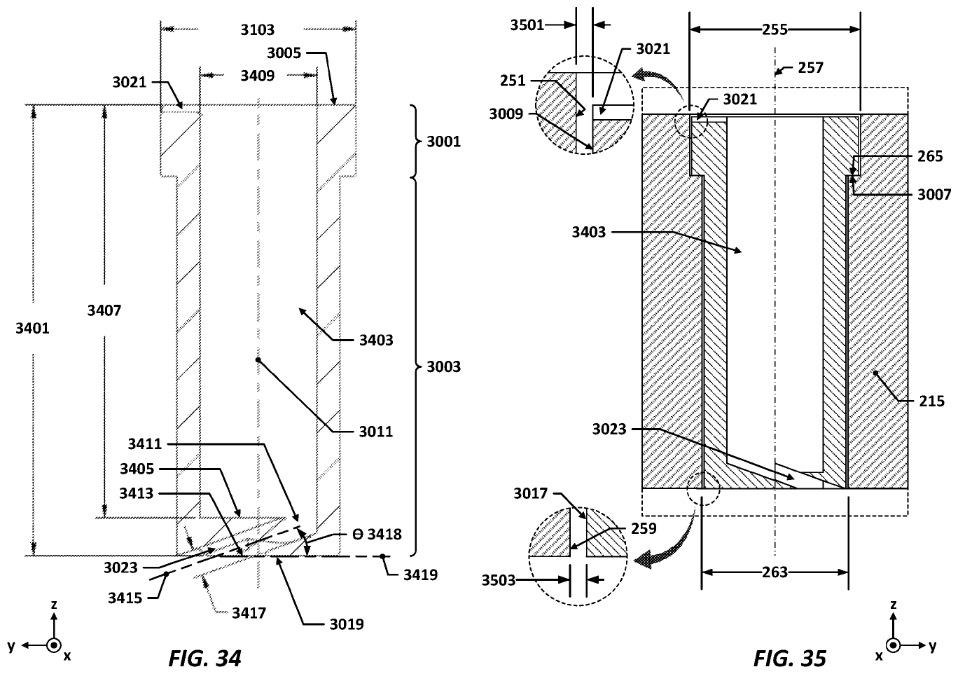

FIG. 35 schematically illustrates a partial cross-sectional view of the showerhead of FIG. 2 including the gas distribution port insert of FIGS. 30-33 according to some embodiments.

With reference to FIGS. 2 and 30-34, insert 3000 may be at least partially supported in gas distribution port 207 such that intermediate surface 3007 of insert 3000 abuts against resting surface 265 of gas distribution port 207. To this end, insert 3000 may be configured to form a clearance fit with gas distribution port 207. For instance, in some cases, maximum dimension 3103 of head portion 3001 of insert 3000 may be about 1% to about 10% smaller than maximum dimension 255 of first port portion 245 of gas distribution port 207 such that lateral surface 3009 of insert 3000 is spaced apart from inner surface 251 of gas distribution port 207 by distance 3501. To this end, maximum dimension 3107 of body portion 3003 of insert 3000 may be about 1% to about 10% smaller than maximum dimension 263 of second port portion 247 of gas distribution port 207 such that lateral surface 3017 of insert 3000 is spaced apart from inner surface 259 of gas distribution port 207 by distance 3503. In some cases, distances 3501 and 3503 may be equivalent or substantially equivalent, but embodiments are not limited thereto. It is also noted that head portion 3001 may serve as a centering mechanism when insert 3000 is inserted into gas distribution port 207 so as to enable a central axis (e.g., reference axis 3011) of insert 3000 to be coincident (or substantially coincident) with central axis 257 of gas distribution port 207.

Similar to inserts 300, 700, 1100, 1500, 2000, and 2500, the formation of the above-noted clearance fits may increase the distance between lateral surfaces 3009 and 3017 of insert 3000 and corresponding inner surfaces 251 and 259 of gas distribution port 207. This may reduce the potential for abrasion between insert 3000 and gas distribution port 207 that might otherwise occur as a result of thermally induced movement of insert 3000 relative to gas distribution port 207 that may be caused, at least in part, by temperature changes and/or fluctuations association with a semiconductor processing operation being performed via system 100. Although motion of insert 3000 has been described as being caused in association with thermal effects, it is also contemplated that the motion of insert 3000 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 3000 and gas distribution port 207 that might otherwise cause, at least in part, defect causing contaminates being deposited onto frontside 203 of wafer 105 and/or structures formed thereon/therein. Also, the centering effect of head portion 3001 relative to body portion 3003 may also serve to return insert 3000 into concentric (or substantially concentric) alignment with gas distribution port 207 after movement of insert 3000. This may help maintain a determined gas flow profile from showerhead 107.

### Gas Distribution Port Insert—8

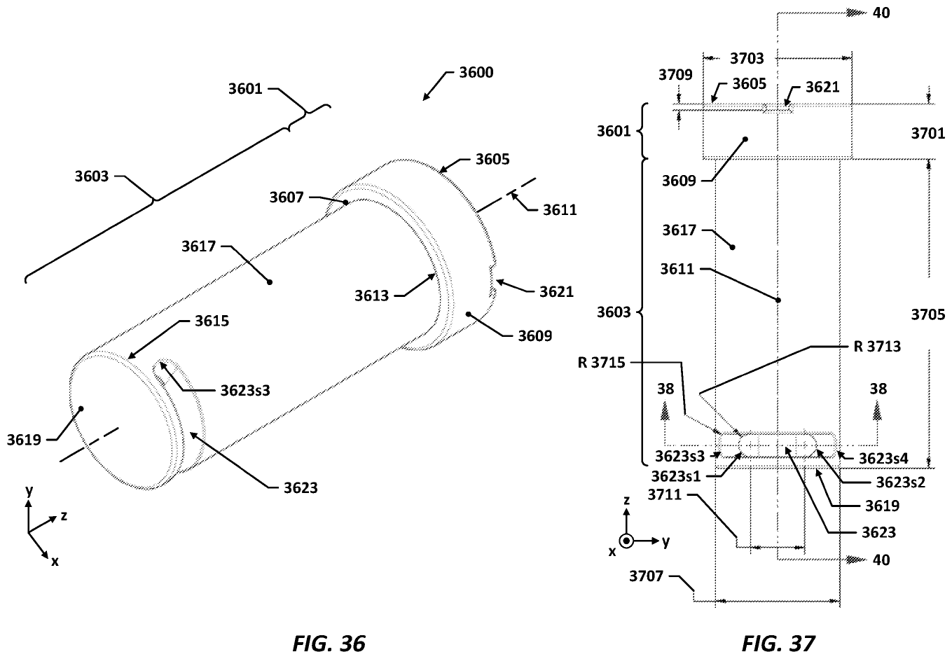

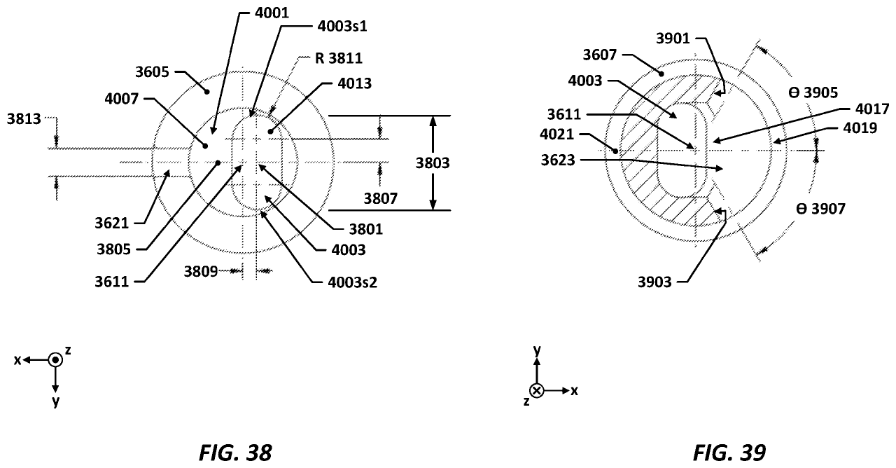

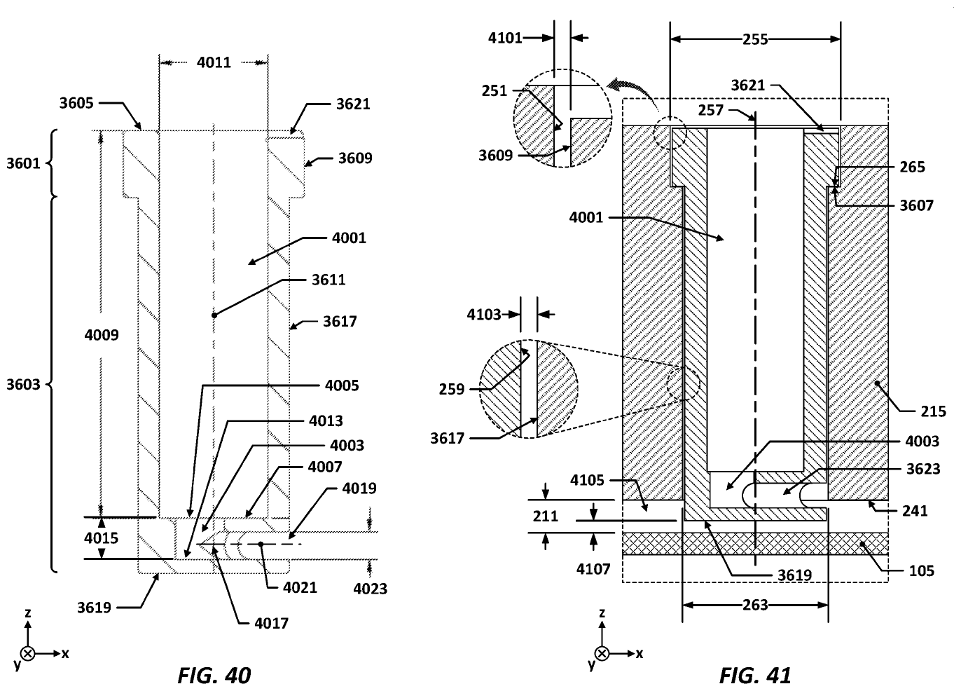

FIGS. 36-40 schematically depict various views of a gas distribution port insert (or insert) that may be incorporated as part of the showerhead of FIG. 2 according to some embodiments. For example, FIG. 36 depicts a perspective view of insert 3600, FIG. 37 depicts a side view of insert 3600, FIG. 38 depicts a top view of insert 3600, FIG. 39 depicts a cross-sectional view of insert 3600 taken along sectional line 39-39, and FIG. 40 depicts a cross-sectional view of insert 3600 taken along sectional line 40-40.

With reference to FIGS. 36-40, insert 3600 may be similar to insert 3000, and, as such, may include head portion 3601 and body portion 3603 extending from head portion 3601 in an axial direction, which may extend in a direction opposite the z-axis direction. Both head portion 3601 and body portion 3603 may be formed as generally circular cylinders, but embodiments are not limited thereto. For instance, either or both of head portion 3601 and body portion 3603 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 3601 and body portion 3603 will be described in association with FIGS. 36-40 as having generally cylindrical configurations, but it should be appreciated that reference to a surface of such a shape may refer to one or more surfaces of another shape.

According to various embodiments, head portion 3601 may have length 3701 in the axial direction and maximum dimension (e.g., diameter) 3703 in, for example, a second direction transverse to the axial direction. For example, the second direction may be perpendicular (or substantially perpendicular) to the axial direction, and, as such, may extend in the y-axis direction. Body portion 3603 may have length 3705 in the axial direction and maximum dimension (e.g., diameter) 3707 in the second direction. Depending on the geometric configuration of head portion 3601 and body portion 3603, maximum dimensions 3703 and 3707 may be widths of insert 3700. In some embodiments, maximum dimension 3703 may be between about 0.1 mm and about 0.4 mm, and maximum dimension 3707 may be between about 0.1 mm and 0.2 mm. Whatever the case, maximum dimension 3703 may be greater than maximum dimension 3707, such as greater than maximum dimension 3707 by about 15% to about 25%, but embodiments are not limited thereto. It is also noted that length 3701 may be between about 0.05 mm and about 0.1 mm, and length 3705 may be between about 0.4 mm and about 0.7 mm. In some instances, length 3705 may be greater than length 3701, such as greater than length 3701 by about 500% to about 600%, but embodiments are not limited thereto. As such, an overall length of insert 3600 in the axial direction may be between about 0.6 mm and about 0.7 mm, but embodiments are not limited thereto.

Head portion 3601 may include gas inlet surface 3605, intermediate surface 3607 opposing or spaced apart from gas inlet surface 3605 in the axial direction, and lateral surface 3609 connecting intermediate surface 3607 to gas inlet surface 3605. In this manner, head portion 3601 may extend along reference axis 3611, which may be a central axis of not only insert 3600, but also head portion 3601. Body portion 3603 may include proximal end 3613, distal end 3615 opposing or spaced apart from proximal end 3613 in the axial direction, and lateral surface 3617 connecting distal end 3615 to proximal end 3613. As such, proximal end 3613 may extend from, and, thereby, may be adjacent to intermediate surface 3607. Distal end 3615 may terminate at distal surface 3619. In this manner, body portion 3603 may also extend along reference axis 3611, which may also be a central axis of body portion 3603.

According to various embodiments, insert 3600 may include bore 4001 extending from gas inlet surface 3605 towards distal surface 3619 along reference axis 3611, which may be a central axis of bore 4001. As such, bore 4001 may form a central bore of insert 3600, but embodiments are not limited thereto. Body portion 3603 of insert 3600 may include an additional bore, e.g., bore 4003, fluidically connected to bore 4001. Bore 4003 may extend in the axial direction from distal end opening 4005 of bore 4001 towards distal surface 3619 along reference axis 3801. Reference axis 3801 may be parallel to, but offset from reference axis 3611 in a third direction transverse to the axial direction, and, thereby, may extend in a direction opposite the x-axis direction. Bore 4001 may be formed as a void with a generally circular cylinder configuration, but implementations are not limited thereto. Similar to bore 4001, bore 4003 may be formed as an elongated void having a generally stadium (or obround)-shaped cross-section in a plane perpendicular to reference axis 3611, but implementations are not limited thereto For instance, either or both of bores 4001 and 4003 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 4001 will be described as having a generally cylindrical configuration and bore 4003 will be described as having a generally elongated configuration with a generally stadium-shaped cross-section in a plane perpendicular to reference axis 3611, but it should be appreciated that reference to surfaces (e.g., interior surfaces) of such shapes may refer to one or more surfaces of another shape or formation of bore 4001 or bore 4003.

As depicted in FIG. 40, bore 4001 may terminate at distal surface 4007 offset from distal surface 3619 in a first direction (e.g., the z-axis direction) such that bore 4001 extends through head portion 3601 and partially through body portion 3603. In this manner, bore 4001 may have depth 4009 in, for example, the axial direction, and a maximum dimension (e.g., diameter) 4011 in, for instance, the second direction. Similar to bore 4001, bore 4003 may terminate at distal surface 4013 offset from distal surface 3619 in the first direction such that bore 4003 extends from distal end opening 4005 of bore 4001 further into body portion 3603. In this manner, bore 4003 may have depth 4015 in, for instance, the axial direction, and maximum width 3803 in the second direction. To this end, central axes of semicircle sides 3803s1 and 3803s2 of bore 4003 may not only be spaced apart from reference axis 3805 by distance 3807 in the second direction, but also spaced apart from reference axis 3611 in the third direction by distance 3809. As such, the rectangular portion of the stadium shape may have a width equivalent to twice distance 3807 and semicircle sides 3803s1 and 3803s2 may have radii 3811. In various implementations, depth 4009 may be between about 0.4 mm and about 0.7 mm, and maximum dimension 4011 may be between about 0.1 mm and about 0.2 mm (and at least smaller than each of dimensions 3703 and 3707). Depth 4015 may be between about 0.3 mm and about 0.5 mm, maximum width 3803 may be between about 0.2 mm and about 0.1 mm, and radii 3811 may be between about 0.02 mm and about 0.05 mm. Distance 3807 may be between about 0.02 mm and about 0.05 mm (and, in some cases, less than radii 3811), and distance 3809 may be between about 0.01 mm and about 0.02 mm. It is noted that, depending on the geometric configuration of bore 4001, maximum dimension 4011 may be a width of bore 4001. Further, depth 4009 of bore 4001 may be greater than depth 3407 of bore 3403 of insert 3000. It is also noted that a cross-sectional area of bore 4003 in the plane perpendicular to reference axis 3611 may be smaller than a cross-sectional area of bore 4001 such that bore 4003 is encircled by bore 4001 when viewed in the axial direction. In this manner, bore 4003 may be configured to constrict a flow of gas through insert 3600 that may cause, at least in part, an acceleration of the flow of gas from bore 4001 through bore 4003.

According to various embodiments, head portion 3601 may include recessed portion 3621 in gas inlet surface 3605. Recessed portion 3621 may have depth 3709 in the axial direction and may longitudinally extend in a third direction transverse to the axial direction. For example, the third direction may extend in a direction opposite the x-axis direction. In this manner, recessed portion 3621 may extend from lateral surface 3609 to bore 4001, and, thereby, may be fluidically connected to bore 4001 within head portion 3601. Width 3813 of recessed portion 3621 may extend in, for example, the second direction. In various implementations, width 3813 may be between about 0.02 mm and about 0.06 mm, and depth 3709 may be between about 0.005 mm and about 0.02 mm. Body portion 3603 may include gas outlet orifice 3623 having proximal end opening 4017 fluidically connected to bore 4001 within an interior of insert 3600 and distal end opening 4019 in lateral surface 3617. In this manner, bore 4003 may be fluidically interposed between bore 4001 and gas outlet orifice 3623. Accordingly, the combination of bore 4001, bore 4003, and gas outlet orifice 3623 may enable one or more gases input to bore 4001 at gas inlet surface 3605 to flow through bore 4001, bore 4003, and gas outlet orifice 3623, and, thereby, to be output from lateral surface 3617 via distal end opening 4019.

Gas outlet orifice 3623 may be formed as a void extending along central axis 4021 and expanding in cross-sectional area (in a plane perpendicular to central axis 4021) from proximal end opening 4017 to distal end opening 4019. In some embodiments, central axis 4021 may extend in a fourth direction transverse to the axial direction, and, in some cases, may be equivalent (or substantially equivalent) to the third direction. The third and fourth directions may be perpendicular or substantially perpendicular to the axial direction, but embodiments are not limited thereto. Further, height 4023 of gas outlet orifice 3623 may extend in a fifth direction perpendicular to central axis 4021. In some cases, the fifth direction may extend in the axial direction.

According to some embodiments, gas outlet orifice 3623 may have a first generally stadium-shaped cross-sectional area at proximal end opening 4017 with central axes of semicircle sides 3623s1 and 3623s2 being spaced apart from one another by distance 3711 and having respective radii 3713, and may have a second generally stadium-shaped cross-sectional opening at distal end opening 4019 with semicircle sides 3623s3 and 3623s4 having respective radii 3715. Distance 3711 may be between about 0.05 mm and about 0.1 mm, and radii 3713 and 3715 may be between about 0.01 mm and about 0.03 mm, but embodiments are not limited thereto. To this end, sidewalls 3901 and 3903 of gas outlet orifice 3623 may extend from proximal end opening 4017 to distal end opening 4019 such that sidewall 3901 extends in a sixth direction oblique to central axis 4021 and sidewall 3903 extends in a seventh direction oblique to central axis 4021. The sixth direction may form angle 3905 with central axis 4021 and the seventh direction may form angle 3907 with central axis 4021. Magnitudes of angles 3905 and 3907 may be between about 45° and about 75°, and may be equivalent or substantially equivalent. It is also noted that width 3803 of bore 4003 in the second direction may be less than or equal to a minimum width of gas outlet orifice 3623 in the second direction, and height 4015 of bore 4003 in the first direction may be greater than height 4023 of gas outlet orifice 3623 in the first direction. In some cases, height 4023 of gas outlet orifice 3623 may be between about 0.02 mm and about 0.05 mm.

According to various embodiments, the increased depth of bore 4001 as compared to depth 3407 of bore 3403 of insert 3000, the constricting nature of bore 4003, and an increased cross-sectional area of gas outlet orifice 3623 in comparison to the cross-sectional area of gas outlet orifice 3023 of insert 3000 may cause, at least in part, a greater pressure drop through insert 3600 than through insert 3000. For instance, assuming a flow of gas within the slip flow regime, a pressure drop through insert 3600 may be less than or equal to about 850×10⁻⁴ Torr, such as about 817×10⁻⁴ Torr, whereas a pressure drop through insert 3000 may be less than or equal to about 500×10⁻⁴ Torr.

Further, the configuration of insert 3600 may be configured to cause, at least in part, a substantially directional flow of gas in the fourth direction from gas outlet orifice 3623. Accordingly, when one or more of inserts 3600 are incorporated as part of, for example, showerhead 107, such a directional flow of gas from gas outlet orifices 3623 may be utilized to propel purge gas radially outwards from an axis (e.g., central axis 141) of showerhead 107 in region 129. This may discourage process gas(es) from region 131 from flowing into the gap between showerhead 107 and frontside 203 of wafer 105 and/or reaching at least one of gas distribution ports 207 of showerhead 107, inserts 3600 incorporated as part of showerhead 107, and frontside 203 of wafer 105 or features formed thereon or therein. By discouraging such a flow of purge gas(es) into region 129, showerhead 107 including one or more of inserts 3600 may prevent or at least reduce the potential for process gas interaction with showerhead 107 and/or back diffusion into gas distribution ports 207 of showerhead 107.

Although gas outlet orifice 3623 has been described in association with a particular geometric configuration, embodiments are not limited thereto. For instance, gas outlet orifice 3623 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations.

According to various embodiments, insert 3600 may be formed of any suitable material, as well as formed in any suitable manner. For example, insert 3600 may be formed of (or include) one or more ceramic materials, such as aluminum oxide, aluminum nitride, ruthenium oxide, titanium nitride, titanium aluminum nitride, titanium carbide, etc. In some cases, insert 3600 may be formed of a first material and coated with a second material. For example, insert 3600 may be manufactured from aluminum as the first material and may be coated with aluminum fluoride (AlF₃) as the second material, but embodiments are not limited thereto. In various implementations, insert 3600 may be additively manufactured, stamped, injection molded, compression molded, cast, machined, and/or the like.

FIG. 41 schematically illustrates a partial cross-sectional view of the showerhead of FIG. 2 including the gas distribution port insert of FIGS. 36-40 according to some embodiments.

With reference to FIGS. 2 and 36-40, insert 3600 may be at least partially supported in gas distribution port 207 such that intermediate surface 3607 of insert 3600 abuts against resting surface 265 of gas distribution port 207. To this end, insert 3600 may be configured to form a clearance fit with gas distribution port 207. For instance, in some cases, maximum dimension 3703 of head portion 3601 of insert 3600 may be about 1% to about 10% smaller than maximum dimension 255 of first port portion 245 of gas distribution port 207 such that lateral surface 3609 of insert 3600 is spaced apart from inner surface 251 of gas distribution port 207 by distance 4101. To this end, maximum dimension 3707 of body portion 3603 of insert 3600 may be about 1% to about 10% smaller than maximum dimension 263 of second port portion 247 of gas distribution port 207 such that lateral surface 3617 of insert 3600 is spaced apart from inner surface 259 of gas distribution port 207 by distance 4103. In some cases, distances 4101 and 4103 may be equivalent or substantially equivalent, but embodiments are not limited thereto.

Further, an overall length of insert 3600 may be configured such that distal surface 3619 of insert 3600 extends beyond second surface 241 of showerhead 107 into gap region 4105 between showerhead 107 and wafer 105. Although gap region 4105 may have height 211 in the axial direction, the protruding nature of distal surface 3619 may reduce the distance between distal surface 3619 and a facing surface of wafer 105 to height 4107. In some cases, height 4107 may be between about 0.2 mm and about 0.2 mm. This may further discourage process gas(es) from region 131 from flowing into gap region 4105 between showerhead 107 and frontside 203. Also, head portion 3601 may serve as a centering mechanism when insert 3600 is inserted into gas distribution port 207 so as to enable a central axis (e.g., reference axis 3611) of insert 3600 to be coincident (or substantially coincident) with central axis 257 of gas distribution port 207.

Similar to inserts 300, 700, 1100, 1500, 2000, 2500, and 3000, the formation of the above-noted clearance fits may increase the distance between lateral surfaces 3609 and 3617 of insert 3600 and corresponding inner surfaces 251 and 259 of gas distribution port 207. This may reduce the potential for abrasion between insert 3600 and gas distribution port 207 that might otherwise occur as a result of thermally induced movement of insert 3600 relative to gas distribution port 207 that may be caused, at least in part, by temperature changes and/or fluctuations association with a semiconductor processing operation being performed via system 100. Although motion of insert 3600 has been described as being caused in association with thermal effects, it is also contemplated that the motion of insert 3600 may be additionally or alternatively caused by other factors, such as, for example, pressure differentials, movement of showerhead 107, etc. In any event, reducing the potential for such abrasion may concomitantly reduce the potential for particulate generation and/or shedding in/from the gap between insert 3600 and gas distribution port 207 that might otherwise cause, at least in part, defect causing contaminates being deposited onto frontside 203 of wafer 105 and/or structures formed thereon/therein. Also, the centering effect of head portion 3601 relative to body portion 3603 may also serve to return insert 3600 into concentric (or substantially concentric) alignment with gas distribution port 207 after movement of insert 3600. This may help maintain a determined gas flow profile from showerhead 107.

### Gas Distribution Port Insert—9

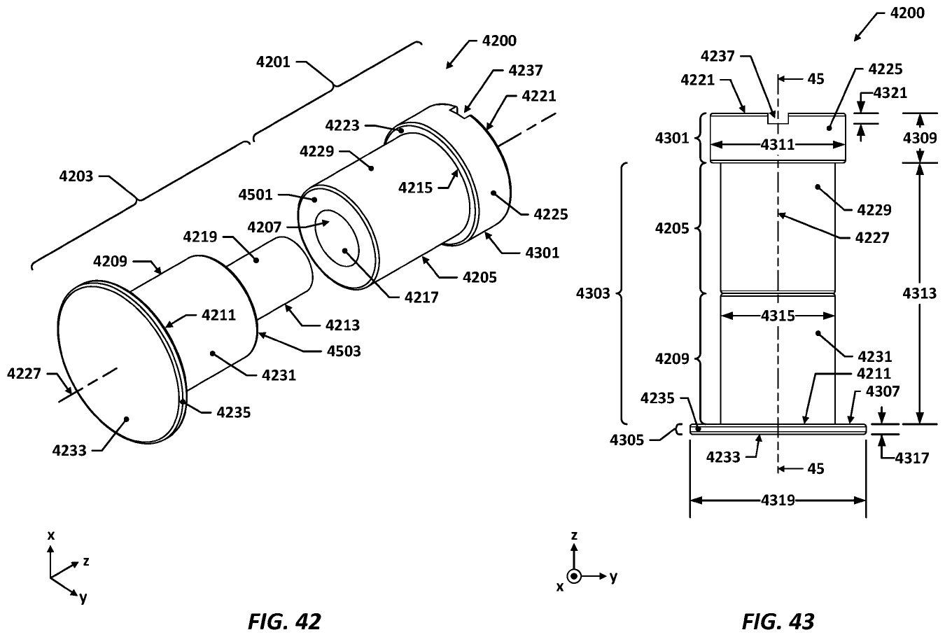

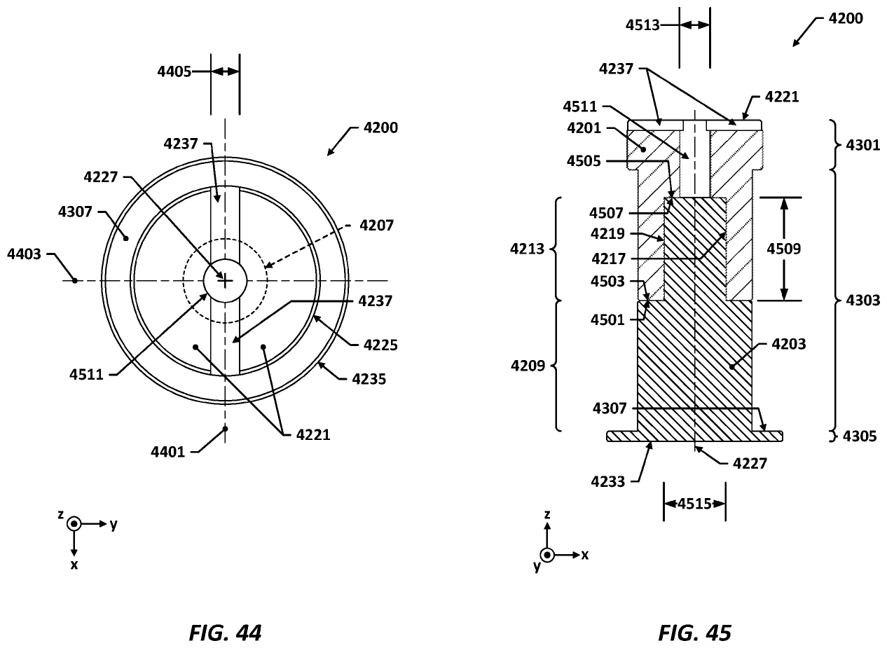

FIGS. 42-45 schematically depict various views of a gas distribution port insert that may be incorporated as part of the showerhead of FIG. 2 according to some embodiments. For example, FIG. 42 depicts an exploded perspective view of insert 4200, FIG. 43 depicts a side view of insert 4200, FIG. 44 depicts a top view of insert 4200, and FIG. 45 depicts a cross-sectional view of insert 4200 taken along sectional line 45-45.

With reference to FIGS. 42-45, insert 4200 may be similar to inserts 300, 700, 1100, 1500, 2000, 2500, 3000, and 3600, and as such, may include head portion 4301 and body portion 4303 extending from (or connected to) head portion 4301 in an axial direction. The axial direction may extend in a direction opposite the z-axis direction. Insert 4200 may be formed as an assembly of parts or components configured to not only reduce the likelihood of unwanted gas interaction with a gas distribution body (e.g., gas distribution body 107) and/or back diffusion into a gas distribution port (e.g., gas distribution port 207) of the gas distribution body including insert 4200 at least partially supported therein, but may also be configured to reduce and/or prevent gas flow from or through the gas distribution port of the gas distribution body. In some embodiments, unlike inserts 300, 700, 1100, 1500, 2000, 2500, 3000, and 3600, insert 4200 may be devoid of gas outlet orifices such that it is configured to reduce and/or prevent gas flow from or through gas distribution port 207 in which insert 4200 is at least partially supported. Moreover, insert 4200 may include flange portion 4305 connected to (or extending from) body portion 4303 in the axial direction that, as will become more apparent below, may be configured to cap or otherwise close off the gas distribution port in which it may be at least partially supported. Head portion 4301, body portion 4303, and flange portion 4305 may be formed as generally circular cylinders, but embodiments are not limited thereto. For instance, each or at least one of head portion 4301, body portion 4303, and flange portion 4305 may be formed having any suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 4301, body portion 4303, and flange portion 4305 will be described in association with FIGS. 42-45 as having generally cylindrical configurations, but it should be appreciated that reference to a surface of such a shape may refer to one or more surfaces of another shape.

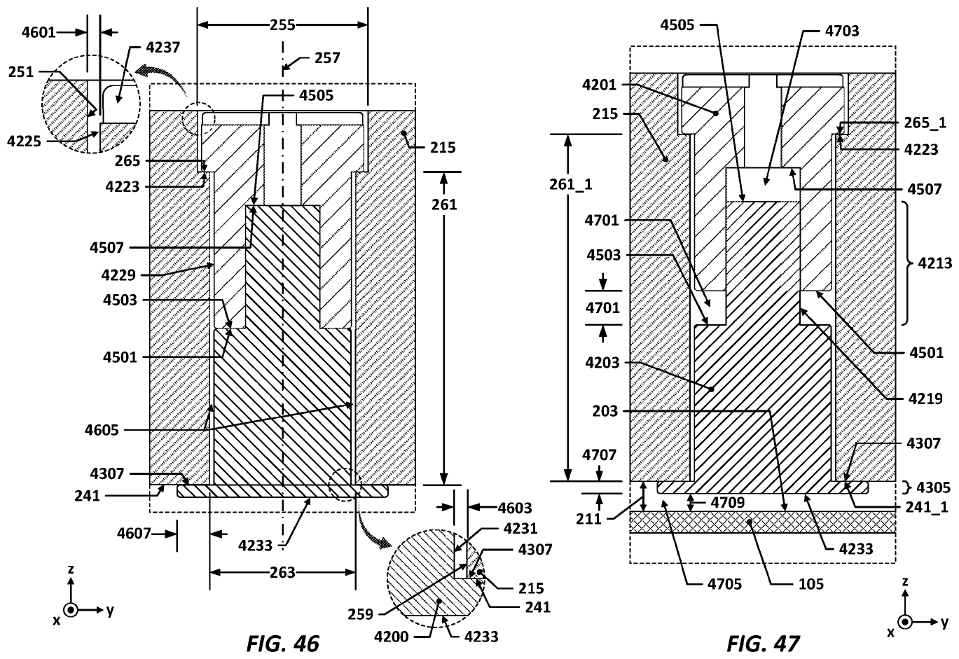

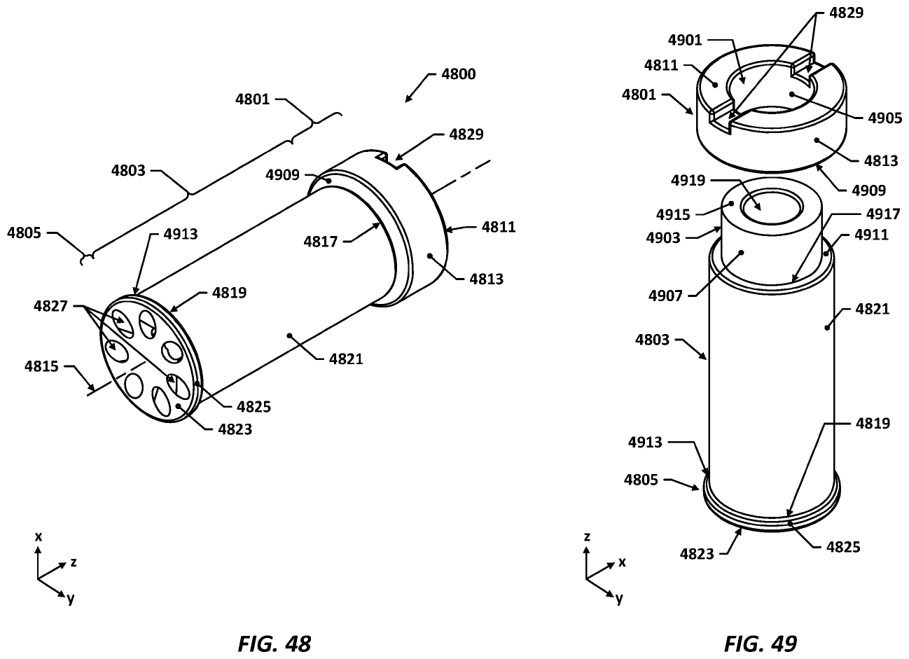

According to some embodiments, the assembly forming insert 4200 may include first part (or body 4201 coupled to (e.g., detachably coupled to) second part (or body) 4203. First part 4201 may include protrusion 4205 extending from (or connected to) head portion 4301 in the axial direction and having first bore 4207 formed therein. Second part 4203 may include main body 4209 extending from (or connected to) flange portion 4305 in a direction opposite the axial direction at or near distal end 4211 of main body 4209 (which may also be referred to, herein, as distal end 4211 of body portion 4303), as well as include coupling protrusion 4213 extending from (or connected to) main body 4209 in the axial direction. In some cases, at least a portion of interior surface 4217 of first bore 4207 and a corresponding portion of exterior surface 4219 of coupling protrusion 4213 may be respectively threaded to enable second part 4203 to be detachably coupled to first part 4201 via a threaded engagement, such as illustrated in at least FIGS. 45-47, but embodiments are not limited thereto. For instance, other engagement methods and/or mechanisms may be implemented. Depending on the extent to which coupling protrusion 4213 is received in first bore 4207 along the axial direction, first gap 4701 may be formed between distal end 4501 of first part 4201 and intermediate surface 4503 of second part 4203, and second gap 4703 along the axial direction may be formed between proximal end 4505 of second part 4203 and intermediate surface 4507 of first part 4203. As will become more apparent below, the extent to which coupling protrusion 4213 is received in first bore 4207 along the axial direction may be variably set to enable mating surface 4307 of flange portion 4305 to abut against second surface 241 of gas distribution body 213 when insert 4200 is at least partially supported in a gas distribution port of gas distribution body 213. In this manner, the overall length of insert 4200 may be adapted to length 261 of second port portion 247 of the gas distribution port of gas distribution body 213. It is also contemplated that, in some implementations, respective lengths of some or all of the various parts, bodies, protrusions, sections, connection points, bores, and/or the like of insert 4200 may be varied such that when first part 4201 and second part 4203 are engaged and at least partially supported in a corresponding gas distribution port (e.g., gas distribution port 207), only a first gap (such as first gap 4701) may be formed, only a second gap (such as second gap 4703) may be formed, both first and second gaps may be formed, or no gap along the axial direction may be formed (such as illustrated in FIGS. 45 and 46) between first and second parts 4201 and 4203. Furthermore, it is contemplated that at least one of first and second parts 4201 and 4203 may be alternatively configured. For instance, first part 4201 may include head portion 4301 having first bore 4207 formed therein, and second part 4203 may include main body 4209 extending from (or connected to) flange portion 4305 in a direction opposite the axial direction at or near distal end 4211 of body portion 4303, as well as include coupling protrusion 4213 extending from (or connected to) main body 4209 in the axial direction and configured to interface with first bore 4207. In this sense, insert 4200 may be configured similar to insert 4800, which will be described later in association with at least FIGS. 48-56.

Head portion 4301 may have length 4309 in the axial direction and maximum dimension (e.g., diameter) 4311 in, for example, a second direction transverse to the axial direction. For example, the second direction may be perpendicular (or substantially perpendicular) to the axial direction, and, as such, may extend in the y-axis direction or within a plane parallel (or substantially parallel) to the xy-plane. Body portion 4303 may have length 4313 in the axial direction and maximum dimension (e.g., diameter) 4315 in the second direction. As previously mentioned, depending on the extent to which coupling protrusion 4213 is received in first bore 4207, length 4313 may be augmented (or otherwise lengthened) by an amount of length 4509 not received in first bore 4207. Length 4509 corresponds to the length of coupling protrusion 4213 in the axial direction. Flange portion 4305 may have length 4317 in the axial direction and maximum dimension (e.g., diameter) 4319 in the second direction. In some embodiments, maximum dimension 4311 may be between about 5.9 mm and about 7.3 mm, maximum dimension 4315 may be between about 4.9 mm and 6.5 mm, and maximum dimension 4319 may be between about 7.5 mm and about 9.5 mm. Further, maximum dimension 4311 may be greater than maximum dimension 4315, such as greater than maximum dimension 4315 by about 15% to about 25%, but embodiments are not limited thereto. Maximum dimension 4319 may be greater than each of maximum dimensions 4311 and 4315. In some cases, maximum dimension 4319 may be greater than maximum dimension 4315 by about 40% to about 60%, but embodiments are not limited thereto. Length 4309 may be between about 1.5 mm and about 3.5 mm and length 4317 may be between about 0.2 mm and about 0.6 mm. In some cases, length 4313 may be varied between about 11 mm and about 18 mm depending on the extent to which coupling protrusion 4213 is received in first bore 4207. Length 4313 may be greater than length 4309, such as greater than length 4309 by about 500% to about 750%, but embodiments are not limited thereto. In this manner, an overall length of insert 4200 may be between about 12 mm and about 22 mm, but embodiments are not limited thereto.

Head portion 4301 may include first surface 4221, intermediate surface 4223 opposing or spaced apart from first surface 4221 in the axial direction, and lateral surface 4225 between intermediate surface 4223 and first surface 4221. In this manner, head portion 4301 may extend along reference axis 4227, which may be a central axis of not only insert 4200, but also of head portion 4301. Protrusion 4205 may be connected to and/or extend from intermediate surface 4223 (or proximal end 4215 of body portion 4303) in the axial direction and terminate at distal end (or surface) 4501 of first part 4201. Lateral surface 4229 of protrusion 4205 may connect distal end 4501 and intermediate surface 4223. In this manner, head portion 4301 and protrusion 4205 may together form first part 4201. Body portion 4303 may include proximal end 4215, distal end 4211 opposing or spaced apart from proximal end 4215 in the axial direction, lateral surface 4229 between proximal end 4215 and distal end 4501 of first part 4201, and lateral surface 4231 between intermediate surface 4503 and distal end 4211 of body portion 4303. As such, proximal end 4215 may extend from, and, thereby, may be adjacent to intermediate surface 4223. Distal end 4211 of body portion 4303 may extend from, and, thereby, may be adjacent to mating surface 4307 of flange portion 4305. Accordingly, body portion 4303 may also extend along reference axis 4227, which may also be a central axis of body portion 4303. Flange portion 4305 may include mating surface 4307, distal surface 4233 opposing or spaced apart from mating surface 4307 in the axial direction, and lateral surface 4235 between distal surface 4233 and mating surface 4307. As with head portion 4301 and body portion 4303, flange portion 4305 may extend along reference axis 4227, which may be a central axis of flange portion 4305.

According to some implementations, first part 4201 may include second bore 4511 extending from first surface 4221 to intermediate surface 4507 of first part 4201 along reference axis 4227, which may be a central axis of second bore 4511. As such, second bore 4511 may form a central bore of insert 4200, but embodiments are not limited thereto. Second bore 4511 may be formed as a void with a generally circular cylinder configuration, but implementations are not limited thereto. For instance, second bore 4511 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, second bore 4511 will be described as having a generally cylindrical configuration, but it should be appreciated that reference to a surface (e.g., interior surface) of such a shape may refer to one or more surfaces of another shape or formation of second bore 4511. In some cases, second bore 4511 may be fluidically connected to first bore 4207, which may extend from intermediate surface 4507 to distal end 4501 along reference axis 4227. Similar to second bore 4511, first bore 4207 may be formed as a void having a generally circular cylinder configuration, but embodiments are not limited thereto. Maximum dimension (e.g., diameter) 4513 of second bore 4511 in the second direction may, in some instances, be smaller than maximum dimension (e.g., diameter) 4515 of second bore 4511 in the second direction. In some implementations, one or more of the bores (e.g., first and second bores 4507 and 4511) of first part 4201 may be stepped or sloped such that the one or more bores may have more than one diameter or varying diameter(s).

Head portion 4301 may, in some cases, include one or more recessed portions 4237 in first part 4201. For convenience, it will be assumed that head portion 4301 includes a plurality of recessed portions 4237, such as two recessed portions 4237 as, for example, shown in FIGS. 44 and 45. Recessed portions 4237 may have depth 4321 in the axial direction and may longitudinally extend in a third direction transverse to the axial direction. For example, the third direction may extend in or along the x-axis direction. In some implementations, recessed portions 4237 may extend radially from second bore 4511 to lateral surface 4225 of head portion 4301 along reference axis 4401, and thereby, may be fluidically connected to second bore 4511 within head portion 4301. Although FIG. 44 illustrates recessed portions 4237 being aligned with one another along reference axis 4401, embodiments are not limited thereto. For instance, one or more of recessed portions 4237 (or at least one other recessed portion) may be aligned with, for instance, reference axis 4403 extending transverse to reference axis 4401. Width 4405 of recessed portions 4237 may extend in, for example, the second direction. In various implementations, depths 4321 and widths 4405 of recessed portions 4237 may be shaped and/or sized to accommodate, for instance, one or more blades of a tool, which may be utilized to couple (e.g., thread) first part 4201 to second part 4203 as part of installing insert 4200 in a gas distribution port, such as gas distribution port 207.

According to various embodiments, insert 4200 (and, thereby, first and second parts 4201 and 4203 of insert 4200) may be formed of any suitable material, as well as formed in any suitable manner. For example, insert 4200 may be formed of (or include) one or more ceramic materials, such as aluminum oxide, aluminum nitride, ruthenium oxide, titanium nitride, titanium aluminum nitride, titanium carbide, etc. In some cases, insert 4200 may be formed of a first material and coated with a second material. For example, insert 4200 may be manufactured from aluminum as the first material and may be coated with aluminum fluoride (AlF₃) as the second material, but embodiments are not limited thereto. It is also contemplated that first part 4201 of insert 4200 may be formed of the same material(s) or at least one different material than second part 4203. In various cases, insert 4200 may be additively manufactured, stamped, injection molded, compression molded, cast, machined, and/or the like.

FIGS. 46 and 47 schematically illustrate partial cross-sectional views of the showerhead of FIG. 2 including the gas distribution port insert of FIGS. 42-45 according to some embodiments. It is noted that FIG. 47 demonstrates an example in which length 261_1 of gas distribution port 207 is greater than length 261 as shown in FIG. 46.

With reference to FIGS. 2 and 42-47, insert 4200 may be at least partially supported in gas distribution port 207 such that intermediate surface 4223 of first part 4201 abuts against resting surface 265 of gas distribution port 207. To this end, first and second parts 4201 and 4203 of insert 4200 may be configured to form clearance fits with gas distribution port 207. For instance, in some cases, maximum dimension 4311 of head portion 4301 of insert 4200 may be about 1% to about 10% smaller than maximum dimension 255 of first port portion 245 of gas distribution port 207 such that lateral surface 4225 of head portion 4301 is spaced apart from inner surface 251 of gas distribution port 207 by distance (or gap) 4601. To this end, maximum dimension 4315 of body portion 4303 of insert 4200 may be about 1% to about 10% smaller than maximum dimension 263 of second port portion 247 of gas distribution port 207 such that lateral surfaces 4229 and 4231 of first and second parts 4201 and 4203 of insert 4200 are spaced apart from inner surface 259 of gas distribution port 207 by distance 4603. In some embodiments, distance 4603 may not be constant and may vary along, for instance, reference axis 257. For example, an outer diameter of lateral surface 4229 of first part 4201 may be different from an outer diameter of lateral surface 4231 of second part 4203, an outer diameter of lateral surface 4229 or lateral surface 4231 may not be constant and, thereby, may vary along reference axis 257, and/or maximum dimension (e.g., an inner diameter) of second port portion 247 may not be constant and, thereby, may vary along reference axis 257. Distance 4603 may be defined to accommodate one or more properties of one or more materials used for various parts described herein and/or for their manufacturability, such as in consideration of coefficients of thermal expansion and mismatches, machinability, manufacturing tolerances, etc. In some cases, distances 4601 and 4603 may be equivalent or substantially equivalent, but embodiments are not limited thereto. The relative spacing between insert 4200 and gas distribution port 207 may, according to some implementations, prevent or at least reduce the likelihood of damage to insert 4200 and/or gas distribution body 213 that might otherwise occur as a result of coefficient of thermal expansion (CTE) mismatches between insert 4200 and gas distribution body 213.

According to various embodiments, an overall length of insert 4200 may be adaptively configured to gas distribution port 207 in a manner that mating surface 4307 of flange portion 4305 abuts against second surface 241 of gas distribution body 213 and intermediate surface 4223 abuts against resting surface 265 of gas distribution port 207 when insert 4200 is at least partially supported in gas distribution port 207. For instance, as seen in FIGS. 46 and 47, second port portion 247 of gas distribution port 207 may have length 261 in one implementation and length 261_1 in another implementation. It is noted that second length 261_1 may be greater than length 261 by distance 4701 in the axial direction. Accordingly, during installation, second part 4203 of insert 4200 may be inserted in opening 205 of gas distribution port 207 until mating surface 4307 abuts against second surface 241. First part 4201 may be threaded onto coupling protrusion 4213 until intermediate surface 4223 abuts against resting surface 265 or 265_1. Depending on the length of second port portion 247, the extent to which coupling protrusion 4213 is received in first bore 4207 in the axial direction as first part 4201 is detachably coupled to second part 4203 may differ, such as can be appreciated from a comparison of the illustrations in FIGS. 46 and 47. Thus, in some cases, proximal end 4505 of second part 4203 may abut against intermediate surface 4507 of first part 4203 and/or intermediate surface 4503 of second part 4203 may abut against distal end 4501 of first part 4201, such as depicted in FIG. 46. In other cases, first gap 4701 may be formed between distal end 4501 of first part 4201 and intermediate surface 4503 of second part 4203, and/or second gap 4703 may be formed between proximal end 4505 of second part 4203 and intermediate surface 4507 of first part 4203, such as shown in FIG. 47. In either case, however, at least mating surface 4307 of flange portion 4305 may be made to abut against second surface 241 of gas distribution body 213. It is contemplated, however, that, in some embodiments, a gap may be formed between mating surface 4307 of flange portion 4305 and second surface 241 of gas distribution body 213. In such instances, the amount of the gap may be small enough to discourage backflow of gas, e.g., process gas, into one or more portions of gas distribution port 207.

In some implementations, distal surface 4233 of insert 4200 may extend beyond second surface 241 of showerhead 107 into gap region 4705 between showerhead 107 and wafer 105 by distance 4707 in the axial direction. Distance 4707 may be determined to accommodate the thickness of wafer 105 (including any structures or films formed or deposited thereon) and a bow or curvature of wafer 105 caused, at least in part, by tensile and/or compressive stress(es) of, for instance, films formed on wafer 105. For example, distance 4707 may be between about 0.2 mm and about 0.8 mm, such as about 0.5 mm. Thus, although gap region 4705 may have height 211 in the axial direction, the protruding nature of distal surface 4233 may reduce the distance between distal surface 4233 and a facing surface of wafer 105 to height 4709. Height 4709 may, in some instances, be between about 0.2 mm and about 0.8 mm. This may further discourage process gas(es) from region 131 from flowing into, and plasma formation or distribution in, gap region 4709 between showerhead 107 and frontside 203 of wafer 105. Also, head portion 4301 may serve as a centering mechanism when insert 4200 is installed at least partially in gas distribution port 207 so as to enable a central axis (e.g., reference axis 4227) of insert 4200 to be coincident (or substantially coincident) with central axis 257 of gas distribution port 207. For instance, first part 4201 (and, thereby, head portion 4301) may be at least partially supported in at least first port portion 245 of gas distribution port 207 before second part 4203 is at least partially supported in second port portion 247 of gas distribution port 207. In some cases, head portion 4301 may be sized larger than body portion 4303 such that distance 4601 between lateral surface 4225 of head portion 4301 and inner surface 251 of gas distribution port 207 is smaller than distance 4603 between lateral surfaces 4229 and 4231 of first and second parts 4201 and 4203 of insert 4200 and inner surface 259 of gas distribution port 207. As such, when second part 4203 is inserted into second port portion 247 and coupled to first part 4201, second part 4203 (and, thereby, body portion 4303) may be more easily centered in second port portion 247 at least because first part 4201 (and, thereby, head portion 4301) may already be centered in first port portion 245. Moreover, distance 4601 between lateral surface 4225 of head portion 4301 and inner surface 251 of gas distribution port 207 may be relatively small such that the likelihood of body portion 4303 becoming uncentred from second port portion 247 may be reduced. This is also true with respect to, for instance, thermally induced movement (or other displacement) of insert 4200 relative to gas distribution port 207. For instance, because distance 4601 may be relatively smaller than distance 4603 the ability for body portion 4303 to become uncentered from second port portion 247 may be reduced as the movement of body portion 4303 may be constrained by the amount of movement made available to head portion 4301.

Similar to inserts 300, 700, 1100, 1500, 2000, 2500, 3000, and 3600, the existence of the above-noted clearance fits may increase the distance between lateral surfaces 4225, 4229, and 4231 of insert 3600 and corresponding inner surfaces 251 and 259 of gas distribution port 207. This may reduce the potential for abrasion between insert 4200 and gas distribution port 207 that might otherwise occur as a result of thermally induced movement or expansion of insert 4200 relative to gas distribution port 207 that may be caused, at least in part, by temperature changes and/or fluctuations association with a semiconductor processing operation being performed via system 100. Although motion of insert 4200 has been described as being caused in association with thermal effects, it is also contemplated that the motion of insert 4200 may be additionally or alternatively caused by other factors, such as, for example, pressure differentials, movement of showerhead 107, etc. In any event, reducing the potential for such abrasion may concomitantly reduce the potential for particulate generation and/or shedding in/from gap 4605 between insert 4200 and gas distribution port 207 that might otherwise cause, at least in part, defect causing contaminates being deposited onto frontside 203 of wafer 105 and/or structures formed thereon/therein. Also, the centering effect of head portion 4301 relative to body portion 4303 may also serve to return insert 4200 into concentric (or substantially concentric) alignment with gas distribution port 207 after movement of insert 4200. Given, however, that insert 4200 may be configured to prevent gas flow from and through gas distribution port 207, a flow of gas may not be provided in the area corresponding to gap 4605 that, as described in association with at least inserts 1500, 2000, and 2500, may otherwise prevent or at least reduce the likelihood of back diffusion into gas distribution port 207, and, thereby, into showerhead 107. As such, flange portion 4305 may protrude laterally outwards (e.g., radially outwards) from lateral surface 4231 of body portion 4303 and beyond inner surface 259 of gas distribution port 207 by distance 4607 to effectively cap or otherwise close off a flow path into/out of the area corresponding to gap 4605. In some cases, distance 4607 may be greater than 0 mm and less than or equal to about 2 mm, but embodiments are not limited thereto. For instance, the magnitude of distance 4607 may be set at a valve sufficient enough to discourage gas flow into gap 4605 that may be contingent upon one or more process conditions, such as pressure, temperature, flow rates, etc. Accordingly, flange portion 4305 may be configured to prevent or at least reduce the likelihood of back diffusion into gas distribution port 207, and, thereby, into showerhead 107. To this end, the closing off of the aforementioned flow path relative to gap 4605 may also prevent or at least reduce the likelihood of particulate shedding from gap 4605 in those instances when particulate generation were to occur in the area corresponding to gap 4605.

### Gas Distribution Port Insert—10

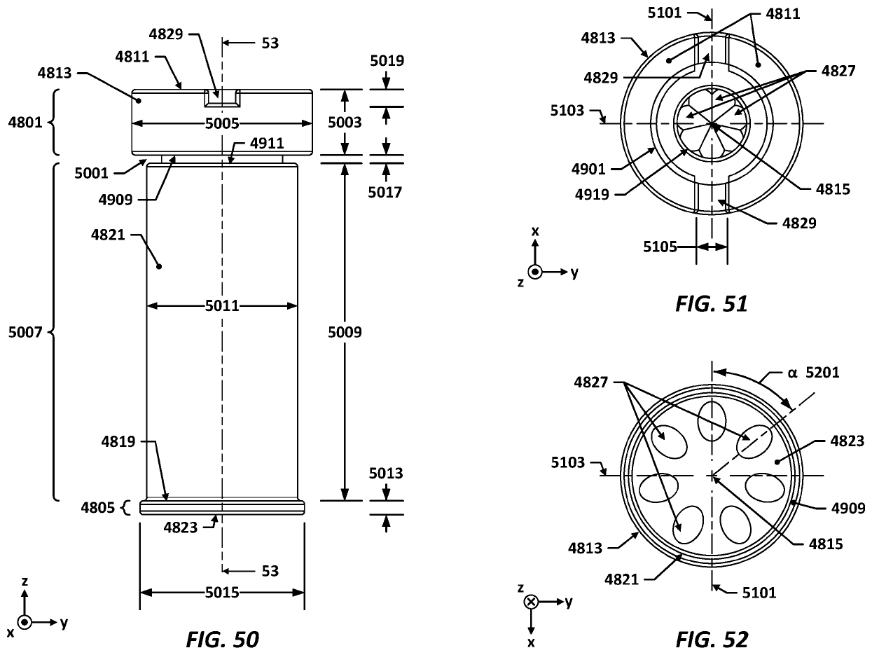

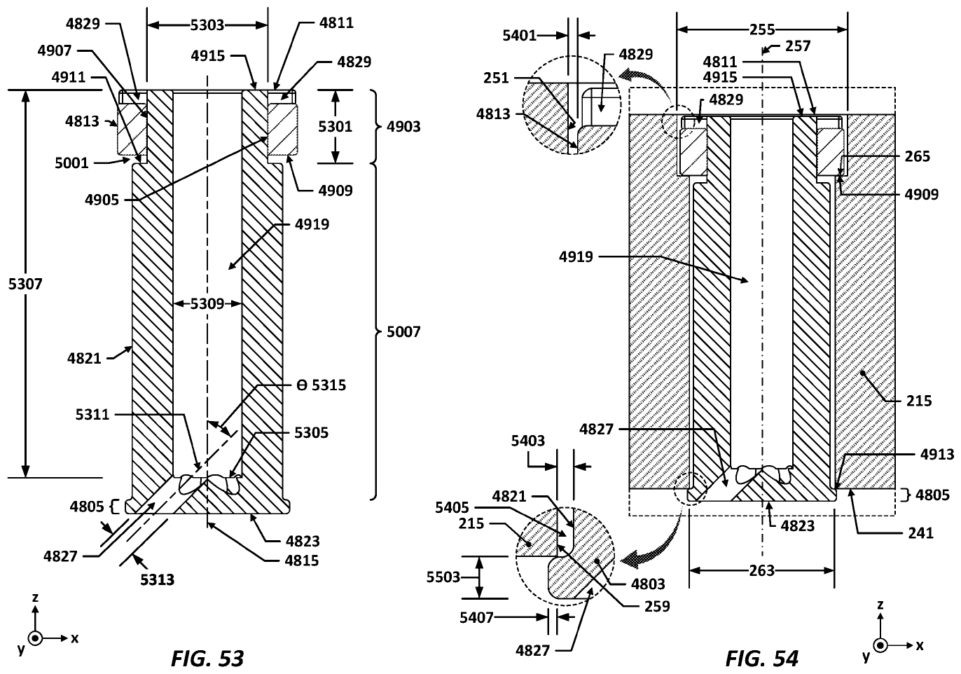

FIGS. 48-53 schematically depict various views of a gas distribution port insert that may be incorporated as part of the showerhead of FIG. 2 according to some embodiments. For example, FIG. 48 depicts a perspective view of insert 4800, FIG. 49 depicts an exploded perspective view of insert 4800, FIG. 50 depicts a side view of insert 4800, FIGS. 51 and 52 respectively depict a top view and a bottom view of insert 4800, and FIG. 53 depicts a cross-sectional view of insert 4800 taken along sectional line 53-53.

With reference to FIGS. 48-53, insert 4800 may be similar to inserts 300, 700, 1100, 1500, 2000, 2500, 3000, and 3600, and as such, may include head portion 4801 and body portion 4803 extending from (or connected to) head portion 4801 in an axial direction. The axial direction may extend in a direction opposite the z-axis direction. Insert 4800, however, may be formed as an assembly of parts or components. For instance, head portion 4801 may be formed as a first part or component coupled (e.g., detachably coupled) to body portion 4803, which may be formed as a second part or component. Moreover, insert 4800 may include flange portion 4805, which may be configured similar to flange portion 4305 of insert 4200. For example, flange portion 4805 may extend from (or be connected to) body portion 4803 in the axial direction and, as will become more apparent below, may be configured to cap or otherwise close off the gas distribution port in which insert 4800 may be at least partially supported. In various implementations, head portion 4801, body portion 4803, and flange portion 4805 may be formed as generally circular cylinders, but embodiments are not limited thereto. For instance, at least one of head portion 4801, body portion 4803, and flange portion 4805 may be formed having any other suitable geometric configuration, such as generally cone shaped bodies, generally triangular shaped prisms, generally quadrilateral shaped prisms, generally pentagonal shaped prisms, generally hexagonal shaped prisms, etc., or frustums of at least one of such formations. For convenience, head portion 4801, body portion 4803, and flange portion 4805 will be described in association with FIGS. 48-53 as having generally cylindrical configurations, but it should be appreciated that reference to a surface of such a shape may refer to one or more surfaces of another shape.

As previously mentioned, the assembly forming insert 4800 may include head portion 4801 coupled (e.g., detachably coupled) to body portion 4803. In some cases, head portion 4801 may include opening 4901, which may be configured to receive and engage with at least a portion of first section (or coupling protrusion) 4903 of body portion 4803. For instance, interior surface 4905 of opening 4901 and lateral surface 4907 of coupling protrusion 4903 may be respectively threaded to enable head portion 4801 to be detachably coupled to body portion 4803 via a threaded engagement, such as illustrated in at least FIGS. 48, 50, and 53, but embodiments are not limited thereto. For instance, any other engagement method and/or mechanism may be implemented. For instance, body portion 4803 may have an opening configured to receive a coupling protrusion extending from head portion 4801. It is also contemplated that any other type of connection between head portion 4801 and body portion 4803 may be utilized, as such as a bayonet-type engagement. As shown, however, the threaded engagement between head portion 4801 and body portion 4803 may allow insert 4800 to be adapted to gas distribution ports of different heights in the axial direction. For example, depending on the extent to which coupling protrusion 4903 is received in opening 4901, gap 5001 of different lengths in the axial direction may be formed between intermediate surface 4909 of head portion 4801 and intermediate surface 4911 of body portion 4803. As will become more apparent below, the extent to which coupling protrusion 4903 is received in opening 4901 may be variably set to enable mating surface 4913 of flange portion 4805 to abut against second surface 241 of gas distribution body 213 when insert 4800 is at least partially supported in a gas distribution port of gas distribution body 213. In this manner, the overall length of insert 4800 may be adapted to length 261 of second port portion 247 of the gas distribution port. It is also contemplated that, in some implementations, respective lengths of some or all of the various parts, bodies, protrusions, sections, and/or the like of insert 4800 may be varied such that when head portion 4801 and body portion 4803 are engaged and at least partially supported in a corresponding gas distribution port (e.g., gas distribution port 207), a gap (such as gap 5001) may or may not be formed. In some cases, at least one other gap between head portion 4801 and body portion 4803 may be formed in addition to or regardless of gap 5001.

According to some embodiments, head portion 4801 may include first surface 4811, intermediate (or second) surface 4909 opposing or spaced apart from first surface 4811 in the axial direction, and at least one lateral surface 4813 between intermediate surface 4909 and first surface 4811. In this manner, head portion 4801 may extend along reference axis 4815, which may be a central axis of not only insert 4800, but also of head portion 4801. Opening 4901 in head portion 4801 may extend from first surface 4811 through intermediate surface 4909 in the axial direction, and in some cases, may be concentrically (or substantially concentrically) aligned with reference axis 4815. Main section 5007 of body portion 4803 may include proximal end 4817, distal end 4819 opposing or spaced apart from proximal end 4817 in the axial direction, and at least one lateral surface 4821 between proximal end 4817 and distal end 4819. In this manner, proximal end 4817 may be arranged adjacent to intermediate surface 4909 of head portion 4801. Coupling protrusion 4903 of body portion 4803 may extend from (or be connected to) intermediate surface 4911 of main section 5007 in the direction opposite the axial direction, and as such, may have proximal end (or surface) 4915, distal end 4917 opposing or spaced apart from proximal end 4915 in the axial direction, and at least one lateral surface 4907 between distal end 4917 to proximal end 4915. In this manner, distal end 4917 of coupling protrusion 4903 may be arranged adjacent to proximal end 4817 of main section 5007. Distal end 4819 of main section 5007 may extend from, and thereby, may be adjacent to mating surface 4913 of flange portion 4805. Accordingly, body portion 4803 may also extend along reference axis 4815, which may also be a central axis of body portion 4803. Flange portion 4805 may include mating surface 4913, distal surface 4823 opposing or spaced apart from mating surface 4913 in the axial direction, and at least one lateral surface 4825 between distal surface 4823 and mating surface 4913. As with head portion 4801 and body portion 4803, flange portion 4805 may extend along reference axis 4815, which may be a central axis of flange portion 4805.

Head portion 4801 may have length 5003 in the axial direction and maximum dimension (e.g., diameter) 4905 in, for example, a second direction transverse to the axial direction. For example, the second direction may be perpendicular (or substantially perpendicular) to the axial direction, and, as such, may extend in the y-axis direction or within a plane parallel (or substantially parallel) to the xy-plane. Main section 5007 of body portion 4903 may have length 5009 in the axial direction and maximum dimension (e.g., diameter) 5011 in the second direction. Coupling protrusion 4903 of body portion 4803 may have length 5301 in the axial direction and maximum dimension (e.g., diameter) 5303 in the second direction. Flange portion 4805 of body portion 4803 may have length 5013 in the axial direction and maximum dimension (e.g., diameter) 5015 in the second direction. Accordingly, depending on the extent to which coupling protrusion 4903 is received in opening 4901 in the axial direction, a length of body portion 4803 abaft of intermediate surface 4909 of head portion 4801 may be augmented (or otherwise lengthened) by an amount (e.g., amount 5017) of length 5301 of coupling protrusion 4903 not received in opening 4901. In some embodiments, maximum dimension 5005 may be between about 5.9 mm and about 7.3 mm, maximum dimension 5011 may be between about 4.9 mm and 6.5 mm, and maximum dimension 5015 may be between about 5.1 mm and about 9.5 mm. In this manner, maximum dimension 5005 may be greater than maximum dimension 5011, such as greater than maximum dimension 5011 by about 15% to about 25%, but embodiments are not limited thereto. Maximum dimension 5019 may be greater than each of maximum dimensions 5005 and 5011. In some cases, maximum dimension 5015 may be greater than maximum dimension 5011 by about 4% to about 60%, but embodiments are not limited thereto. Length 5003 may be between about 1.5 mm and about 3.5 mm and length 5013 may be between about 0.2 mm and about 0.6 mm. In some cases, the length of body portion 4803 abaft of intermediate surface 4909 may be varied between about 11 mm and about 18 mm depending on the extent to which coupling protrusion 4903 is received in opening 4901. In this manner, the length of body portion 4803 abaft of intermediate surface 4909 may be greater than length 5003, such as greater than length 5003 by about 500% to about 750%, but embodiments are not limited thereto. As such, an overall length of insert 4800 may be between about 12 mm and about 22 mm, but embodiments are not limited thereto.

In various implementations, body portion 4803 of insert 4800 may include bore 4919 extending between proximal end 4915 of coupling protrusion 4903 and distal end 4819 of main section 5007 along reference axis 4815, which may be a central axis of bore 4919. As such, bore 4919 may form a central bore of insert 4800, but embodiments are not limited thereto. Bore 4919 may be formed as a void with a generally circular cylinder configuration, but implementations are not limited thereto. For instance, bore 4919 may have a uniform cross-section along the axial direction or may have one or more varying cross-sections (e.g., different shapes and/or different sizes, such as diameters) along the axial direction. Further, bore 4919 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, bore 4919 will be described as having a generally cylindrical configuration, but it should be appreciated that reference to a surface (e.g., interior surface) of such a shape may refer to one or more surfaces of another shape or formation of bore 4919.

As seen in FIG. 53, bore 4919 may terminate at distal surface 5305, which may be offset from distal surface 4823 of flange portion 4805 in a first direction (e.g., the z-axis direction) such that bore 4919 extends through coupling protrusion 4903 and partially through main section 5007 of body portion 4803. In some implementations, bore 4919 extends partially through body portion 4803 and terminates in a transitional region prior to flange portion 4805. As such, bore 4919 may not extend in flange portion 4905, but embodiments are not limited thereto. Accordingly, bore 4919 may have depth 5307 in, for example, the axial direction, and a maximum dimension (e.g., diameter) 5309 in, for instance, the second direction. For example, depth 5307 may be between about 2.2 mm and about 2.7 mm, and maximum dimension 5309 may be between about 12 mm and about 16 mm (and at least smaller than each of dimensions 5005, 5011, and 5303). Depending on the geometric configuration of bore 4919, maximum dimension 5309 may be a width of bore 4919. Body portion 4803 may also include a plurality of gas outlet orifices 4827 fluidically connected to bore 4919 within an interior of insert 4800. Although a total of seven gas outlet orifices 4827 are depicted, insert 4800 may include any suitable number of gas outlet orifices 4827. In some cases, gas outlet orifices 4827 may connect distal surface 4823 and distal surface 5305 so as to enable one or more gases input to bore 4919 at a gas inlet to flow through bore 4919 and gas outlet orifices 4827, and thereby, to be output from distal surface 4823. Depending on the extent to which coupling protrusion 4903 is received in opening 4901 in the axial direction, one or both of first surface 4811 and proximal end 4915 may form a gas inlet or gas inlet surface of insert 4800. In this context, a “gas inlet” or “gas inlet surface” may be considered at least one first opening into or at least one surface of insert 4800 that includes the at least one first opening that is first introduced to gas from a plenum (e.g., plenum 237) of a gas distribution body (e.g., gas distribution body 200) when the gas is flowed through the plenum and to be received in, for example, bore 4919 of insert 4800. For instance, coupling protrusion 4903 may be received in opening 4901 such that first surface 4811 and proximal end 4915 are coplanar with one another, and thereby, both first surface 4811 and proximal end 4915 may form the gas inlet/gas inlet surface of insert 4800. In some cases, coupling protrusion 4903 may be received in opening 4901 such that proximal end 4915 is recessed below first surface 4811, and as such, first surface 4811 may form the gas inlet/gas inlet surface of insert 4800. As another example, coupling protrusion 4903 may be received in opening 4901 such that proximal end 4915 protrudes beyond first surface 4811, and as such, proximal end 4915 may form the gas inlet/gas inlet surface of insert 4800.

Similar to bore 4919, gas outlet orifices 4827 may be formed as voids with generally cylindrical configurations, but embodiments are not limited thereto. For instance, one or more of gas outlet orifices 4827 may be formed as a void having any suitable geometric configuration, such as a generally cone shaped void, a generally triangular shaped prism, a generally quadrilateral shaped prism, a generally pentagonal shaped prism, generally hexagonal shaped prism, etc., or a void having a frustum configuration of at least one of such formations. For convenience, gas outlet orifices 4827 will be described as having generally cylindrical configurations, but it should be appreciated that reference to a surface (e.g., interior surface) of such a shape may refer to one or more surfaces of another shape or formation. Whatever the case, each of gas outlet orifices 4827 may have a corresponding central axis and a respective maximum dimension (e.g., diameter) in a plane perpendicular to its corresponding central axis.

For instance, respective gas outlet orifices 4827 may have corresponding central axes, such as central axis 5311, and respective maximum dimensions (e.g., diameters), such as maximum dimension 5313. The central axes (e.g., central axis 5311) of gas outlet orifices 4827 may extend outwards from reference axis 4815, and thereby, form respective angles of inclination (or angles), such as angle 5315, with reference axis 4815. In some embodiments, angle 5315 may be between about 15° and about 75°, such as between about 30° and about 60°, for instance between about 40° and about 50°, e.g., about 45°. This angling of gas outlet orifices 4827 relative to reference axis 4815 may not only help spread the output of purge gas from insert 4800, but may also discourage process gas(es) from backflowing into insert 4800 and/or showerhead 107 that might otherwise degrade insert 4800 and/or showerhead 107. To this end, the flow of gas from gas outlet orifices 4827 may also prevent or at least reduce the likelihood of material deposition between insert 4800 and inner surface 259 of gas distribution port 207, and/or decrease the likelihood of material shedding and/or particulate formation that may result in defect causing contaminates being deposited onto frontside 203 of wafer 105 or structures formed thereon/therein. In addition, and as will become more apparent below in association with the description accompanying at least FIGS. 62 and 63, the angling of gas outlet orifices 4827 may help minimize or at least reduce a magnitude of a component (e.g., a perpendicular or vertical component) of a mean velocity of gas flow relative to a chamber component facing a gas distribution body including one or more of inserts 4800, such as a pedestal, showerhead pedestal, and/or the like, to help prevent or at least reduce the occurrence of, for example, unwanted defects. Again, a more detailed discussion of these effects will be provided later. In some cases, the angling of gas outlet orifices 4827 relative to reference axis 4815 may seek compromise between the performance of insert 4800 during one or more wafer processing stages and the performance of insert 4800 during one or more cleaning operations. As will also become more apparent below, the configuration of flange portion 4805 may also help with one or more of these effects. It is also noted that gas outlet orifices 4827 may be arranged about reference axis 4815 with angular pitch 5201. Assuming insert 4800 has “n” gas outlet orifices 4827 (where “n” is an integer greater than or equal to two), then angular pitch 5201 may be equivalent (or substantially equivalent) to 360° divided by “n.” For example, insert 4800 is shown including seven gas outlet orifices 1527 such that angular pitch 5201 may be about 51.4°, but embodiments are not limited thereto.

In some implementations, the respective maximum dimensions (e.g., maximum dimension 5313) of corresponding gas outlet orifices 4827 may be between about 0.8 mm and about 1.2 mm, such as between about 0.9 mm and about 1.1 mm, e.g., about 1 mm. Respective lengths (or depths) of gas outlet orifices 4827 may be smaller than depth 5307 of bore 4919. Relative to the dimensional sizing of inserts 300, 700, and 4800, gas outlet orifices 4827 may have respectively shorter lengths within insert 4800 than gas outlet orifices 321 within insert 300 and gas outlet orifices 721 within insert 700. This increase in depth of bore 4919, increase in maximum dimension 5307 of bore 4919, and decrease in length of gas outlet orifices 4827 may cause, at least in part, a smaller pressure drop between a gas inlet surface of insert 4800 (such as proximal end 4915) and distal surface 4823 in association with a flow of gas through insert 4800 under conditions in the slip flow regime. With such an increase in downstream pressure, a throughput (or mean velocity) of the gas through insert 4800 may be smaller than through inserts 300, 700, and 1100. In some cases, assuming a flow of gas in the slip flow regime, a pressure drop through insert 4800 may be less than or equal to about 500×10⁻⁴ Torr, such as less than or equal to about 375×10⁻⁴ Torr, e.g., about 340×10⁻⁴ Torr.

Head portion 4801 may, in some cases, include one or more recessed portions 4829 in first surface 4811. For convenience, it will be assumed that head portion 4801 includes a plurality of recessed portions 4829, such as two recessed portions 4829, as, for example, shown in FIG. 49. Recessed portions 4829 may have depth 5019 in the axial direction and may longitudinally extend in a third direction transverse to the axial direction. For example, the third direction may extend in or along the x-axis direction. In some cases, recessed portions 4829 may extend radially from opening 4901 to lateral surface 4813 of head portion 4801 along reference axis 5101, and thereby, may be fluidically connected to opening 4901 within head portion 4801. Although FIG. 51 illustrates recessed portions 4827 being aligned with one another along reference axis 5101, embodiments are not limited thereto. For instance, one or more of recessed portions 4827 (or at least one other recessed portion) may be aligned with, for instance, reference axis 5103 extending transverse to reference axis 5101. Width 5105 of recessed portions 4827 may extend in, for example, the second direction. In various implementations, depths 5019 and widths 5105 of recessed portions 4827 may be shaped and/or sized to accommodate, for instance, one or more blades of a tool, which may be utilized to couple (e.g., thread) head portion 4801 to body portion 4803 as part of installing insert 4800 in a gas distribution port, e.g., gas distribution port 207.

According to various embodiments, insert 4800 (and, thereby, head and body portions 4801 and 4803 of insert 4800) may be formed of any suitable material, as well as formed in any suitable manner. For example, insert 4800 may be formed of (or include) one or more ceramic materials, such as aluminum oxide, aluminum nitride, ruthenium oxide, titanium nitride, titanium aluminum nitride, titanium carbide, etc. In some cases, insert 4800 may be formed of a first material and coated with a second material. For example, insert 4800 may be manufactured from aluminum as the first material and may be coated with aluminum fluoride (AlF₃) as the second material, but embodiments are not limited thereto. It is also contemplated that head portion 4801 may be formed of the same material(s) or at least one different material than body portion 4803. In various cases, components of insert 4800, e.g., head and body portions 4801 and 4803) may be additively manufactured, stamped, injection molded, compression molded, cast, machined, and/or the like.

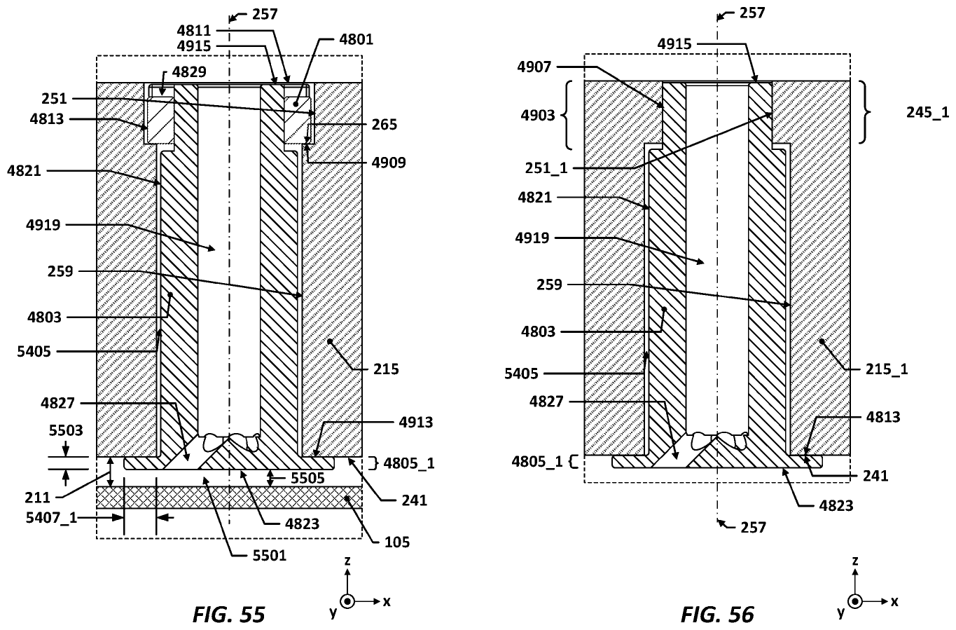

FIG. 54 schematically illustrates a partial cross-sectional view of the showerhead of FIG. 2 including the gas distribution port insert of FIGS. 48-53 according to some embodiments. FIG. 55 schematically illustrates a partial cross-sectional view of the showerhead of FIG. 2 including a modified version of the gas distribution port insert of FIGS. 48-53 according to some embodiments.

With reference to FIGS. 2 and 48-55, insert 4800 may be at least partially supported in gas distribution port 207 such that intermediate surface 4909 of head portion 4801 abuts against resting surface 265 of gas distribution port 207 and mating surface 4913 of flange portion 4805 abuts against second surface 241 of gas distributor 107. To this end, head portion 4801 and body portion 4803 (apart from flange portion 4805) of insert 4800 may be configured such that clearance fits exist with gas distribution port 207. For instance, in some cases, maximum dimension 5005 of head portion 4801 of insert 4800 may be about 1% to about 10% smaller than maximum dimension 255 of first port portion 245 of gas distribution port 207 such that lateral surface 4813 of head portion 4801 is spaced apart from inner surface 251 of gas distribution port 207 by distance (or gap) 5401. To this end, maximum dimension 5011 of main section 5007 of body portion 4803 of insert 4800 may be about 1% to about 10% smaller than maximum dimension 263 of second port portion 247 of gas distribution port 207 such that lateral surface 4821 of main section 5007 is spaced apart from inner surface 259 of gas distribution port 207 by distance 5403. In some embodiments, distance 5403 may not be constant and may vary along, for instance, reference axis 257. For example, an outer diameter of lateral surface 4821 may not be constant and, thereby, may vary along reference axis 257, and/or maximum dimension (e.g., an inner diameter) of second port portion 247 may not be constant and, thereby, may vary along reference axis 257. Distance 5403 may be defined to accommodate one or more properties of one or more materials used for various parts described herein and/or for their manufacturability, such as in consideration of coefficients of thermal expansion and mismatches, machinability, manufacturing tolerances, etc. In some cases, distances 5401 and 5403 may be equivalent or substantially equivalent, but embodiments are not limited thereto. The relative spacing between insert 4800 and gas distribution port 207 may, according to some implementations, prevent or at least reduce the likelihood of damage to insert 4800 and/or gas distribution body 213 that might otherwise occur as a result of, for example, coefficient of thermal expansion (CTE) mismatches between insert 4800 and gas distribution body 213.

According to various embodiments and similar to insert 4200, an overall length of insert 4800 may be adaptively configured to gas distribution port 207 in a manner that mating surface 4913 of flange portion 4805 abuts against second surface 241 of gas distribution body 213 and intermediate surface 4909 of head portion 4801 abuts against resting surface 265 of gas distribution port 207 when insert 4800 is at least partially supported in gas distribution port 207. Accordingly, during installation, body portion 4803 of insert 4800 may be inserted in opening 205 of gas distribution port 207 until mating surface 4913 abuts against second surface 241. Head portion 4801 may be threaded onto coupling protrusion 4903 of body portion 4803 until intermediate surface 4909 abuts against resting surface 265. Depending on the length of second port portion 247, the extent to which coupling protrusion 4903 is received in opening 4901 in the axial direction as head portion 4801 is detachably coupled to body portion 4803 may differ. This may also affect whether proximal end 4915 of body portion 4803 is made to protrude beyond, be recessed from, or become coplanar with first surface 4811 of head portion 4801. Whatever the case, however, at least mating surface 4913 of flange portion 4805 may be made to abut against second surface 241 of gas distribution body 213. It is contemplated, however, that, in some embodiments, a gap may be formed between mating surface 4913 of flange portion 4805 and second surface 241 of gas distribution body 213. In such instances, the amount of the gap may be small enough to discourage backflow of gas, e.g., process gas, into one or more portions of gas distribution port 207.

In some implementations, distal surface 4823 of insert 4800 may extend beyond second surface 241 of showerhead 107 into gap region 5501 between showerhead 107 and wafer 105 by distance 5503 in the axial direction. Distance 5503 may be between about 0.2 mm and about 0.8 mm, such as about 0.5 mm. Thus, although gap region 5501 may have height 211 in the axial direction, the protruding nature of distal surface 4823 may reduce the distance between distal surface 4823 and a facing surface of wafer 105 to height 5505. Height 5505 may, in some instances, be between about 0.2 mm and about 0.8 mm. This may further discourage process gas(es) from region 131 from flowing into gap region 5501 between showerhead 107 and frontside 203 of wafer 105. Also, head portion 4801 may serve as a centering mechanism when insert 4800 is installed at least partially in gas distribution port 207 so as to enable a central axis (e.g., reference axis 4815) of insert 4800 to be coincident (or substantially coincident) with central axis 257 of gas distribution port 207. For instance, head portion 4801 of insert 4800 may be at least partially supported in first port portion 245 of gas distribution port 207 before body portion 4803 is at least partially supported in second port portion 247 of gas distribution port 207. In some cases, head portion 4801 may be sized larger than body portion 4803 such that distance 5401 between lateral surface 4813 of head portion 4801 and inner surface 251 of gas distribution port 207 is smaller than distance 5403 between lateral surface 4821 of body portion 4803 of insert 4800 and inner surface 259 of gas distribution port 207. As such, when body portion 4803 is inserted into second port portion 247 and coupled to head portion 4801, body portion 4803 may be more easily centered in second port portion 247 at least because head portion 4801 may already be centered in first port portion 245. To this end, distance 5401 between lateral surface 4813 of head portion 4801 and inner surface 251 of gas distribution port 207 may be relatively small such that the likelihood of body portion 4803 becoming uncentred from second port portion 247 may be reduced. This is also true with respect to, for instance, thermally induced movement (or other displacement) of insert 4800 relative to gas distribution port 207. For instance, because distance 5401 may be relatively smaller than distance 5403 the ability for body portion 4803 to become uncentered from second port portion 247 may be reduced as the movement of body portion 4803 may be constrained by the amount of movement made available to head portion 4801.

Similar to inserts 300, 700, 1100, 1500, 2000, 2500, 3000, 3600, and 4200, the existence of the above-noted clearance fits may increase the distance between lateral surfaces 4813 and 4821 of insert 4800 and corresponding inner surfaces 251 and 259 of gas distribution port 207. This may reduce the potential for abrasion between insert 4800 and gas distribution port 207 that might otherwise occur as a result of thermally induced movement or expansion of insert 4800 relative to gas distribution port 207 that may be caused, at least in part, by temperature changes and/or fluctuations association with a semiconductor processing operation being performed via system 100. Although motion of insert 4800 has been described as being caused in association with thermal effects, it is also contemplated that the motion of insert 4800 may be additionally or alternatively caused by other factors, such as, for example, pressure differentials, movement of showerhead 107, etc. In any event, reducing the potential for such abrasion may concomitantly reduce the potential for particulate generation and/or shedding in/from gap 5405 between insert 4800 and gas distribution port 207 that might otherwise cause, at least in part, defect causing contaminates being deposited onto frontside 203 of wafer 105 and/or structures formed thereon/therein. Also, the centering effect of head portion 4801 relative to body portion 4803 may also serve to return insert 4800 into concentric (or substantially concentric) alignment with gas distribution port 207 after movement of insert 4800. Given, however, that gas outlet orifices 4827 may be formed in distal surface 4823 arranged abaft of opening 205 of gas distribution port 207, purge gas may not be flowed from the area corresponding to gap 5405 that, as described in association with at least inserts 1500, 2000, and 2500, may otherwise prevent or at least reduce the likelihood of back diffusion into gas distribution port 207, and, thereby, into showerhead 107. That being said, the capping nature of flange portion 4805 may also close off the gas distribution port in which insert 4800 may be at least partially supported to further discourage or prevent purge gas from flowing into the area corresponding to gap 5405. For instance, flange portion 4805 may protrude laterally outwards (e.g., radially outwards) from lateral surface 4821 of main section 5007 of body portion 4803 and beyond inner surface 259 of gas distribution port 207 by distance 5407 to effectively cap or otherwise close off a flow path into/out of the area corresponding to gap 5405. In some cases, distance 5407 may be greater than 0 mm and less than or equal to about 2 mm, but embodiments are not limited thereto. For instance, the magnitude of distance 5407 may be set at a valve sufficient enough to discourage gas flow into gap 5405 that may be contingent upon one or more process conditions, such as pressure, temperature, flow rates, etc. For instance, as seen in FIG. 55, protruding distance 5407_1 of flange portion 4805_1 may be greater than protruding distance 5407 of flange portion 4805 as depicted in FIG. 54. Whatever the case, flange portion 4805 may be configured to prevent or at least reduce the likelihood of back diffusion into gas distribution port 207, and, thereby, into showerhead 107. To this end, the closing off of the aforementioned flow path relative to gap 5405 may also prevent or at least reduce the likelihood of particulate shedding from gap 5405 in those instances when particulate generation were to occur in the area corresponding to gap 5405.

According to some embodiments, a first port portion of a gas distribution port of a gas distribution body may be modified to engage (e.g., detachably engage) with a body portion of an insert and the head portion of the insert may be omitted. An example of such a configuration will be described in more detail in association with FIG. 56 and insert 4800.

FIG. 56 schematically illustrates a partial cross-sectional view of a modified version of showerhead of FIG. 2 including a modified version of the gas distribution port insert of FIG. 55 according to some embodiments.

Referring to FIG. 56, head portion 4801 of insert 4800 may be omitted and first port portion 245_1 of gas distribution body 215_1 may be configured to engage (e.g., detachably engage) with coupling protrusion 4903 of body portion 4803. For instance, inner surface 251_1 of first port portion 245_1 may be threaded to engage with threads formed on or in lateral surface 4907 of coupling portion 4903. In this manner, body portion 4803 may be threaded into first port portion 245_1 until mating surface 4813 of flange portion 4805_1 abuts against second surface 241 of gas distribution body 215_1. Remainders of showerhead 200 and insert 4800 may be as described in conjunction with FIGS. 2 and 48-55.

### Multi-Station Processing Tool

FIG. 57 schematically illustrates a multi-station processing tool according to some embodiments.

In some implementations, multi-station processing tool 5700 can include an inbound load lock 5703 and an outbound load lock 5705, either or both of which may include a plasma source and/or an ultraviolet (UV) source. Robot 5707, at atmospheric pressure, is configured to move wafers from a cassette loaded through pod 5709 into inbound load lock 5703 via an atmospheric port 5711. Wafer 105 is placed by robot 5707 on pedestal 5713 in inbound load lock 5703, atmospheric port 5711 is closed, and inbound load lock 5703 is pumped down. In instances in which inbound load lock 5703 includes a remote plasma source, wafer 105 may be exposed to a remote plasma treatment in inbound load lock 5703 prior to being introduced into process chamber (or chamber) 5715. Further, wafer 105 may be heated in inbound load lock 5703 to, for example, remove moisture and/or adsorbed gases. Next, chamber transport port 5717 to chamber 5715 is opened, and another robot 5719 places wafer 105 into the reactor on a pedestal of a first station shown in the reactor for processing. While the implementation depicted in FIG. 57 includes load locks, it will be appreciated that, in some implementations, direct entry of wafer 105 into a processing station may be provided.

As seen in FIG. 57, chamber 5715 includes four process stations, numbered 1 to 4. Each station has a temperature-controlled pedestal (such as temperature-controlled pedestal 5721 of station 1), and gas line inlets. It will be appreciated that, in some cases, each process station may have identical, different, or multiple purposes. Each station may be controlled independently of the other stations in the process chamber. For example, all four stations may be used to deposit films on wafers loaded onto the pedestals. All four stations may be used to deposit films on back side of wafers; less than four stations may be used to deposit films on back side of wafers while some stations may be used to deposit films on front side of wafers or remain idle. Even when two or more stations are used for the same purposes, different process parameters (such as temperatures, gas flow rates, distances between the showerhead, wafer, and pedestal, etc.) may be applied to each station. Also, in some embodiments, a process station may be switchable between a chemical vapor deposition (CVD) and PECVD process mode. In another example, deposition operations, e.g., PECVD operations, may be performed in one station, while exposure to UV radiation for UV curing may be performed in another station. In some cases, deposition and UV curing may be performed in the same station. Further, although chamber 5715 shown as including four stations, embodiments are not limited thereto. For example, chamber 5715 may have any suitable number of stations, such as five or more stations, or three or less stations. Furthermore, multi-station processing tool 5700 and chamber 5715 are configured such that the interference between stations within chamber 5715 and/or the effect of the process performed on one station to the other stations is monitored and controlled such that the desired process conditions of each station may be provided during operation.

As previously mentioned, multi-station processing tool 5700 may include a wafer handling system (e.g., robot 5719 including spider forks 5701) for transferring and/or positioning wafers within processing chamber 5715. In some embodiments, the wafer handling system may transfer wafers between various process stations and/or between a process station and a load lock. It is contemplated, however, that any suitable wafer handling system may be employed, such as, for example, wafer carousels, other wafer handling robots, etc. Further, multi-station processing tool 5700 may include (or otherwise be coupled to) a system controller 5723 employed to control process conditions and hardware states of multi-station processing tool 5700. System controller 5723 may include one or more memory devices 5725, one or more mass storage devices 5727, and one or more processors 5729. Each processor 5729 may include a central processing unit (CPU) or computer, analog, and/or digital input/output connections, stepper motor controller boards, etc.

In some embodiments, system controller 5723 controls each of the activities of multi-station processing tool 5700. For instance, system controller 5723 may execute system control software 5731 stored in mass storage device 5727, loaded into memory device 5725, and executed by processor 5729. In some embodiments, system control software 5731 may be provided in the “cloud” and/or in a networked computing environment. As used, herein, the “cloud” refers to an information technology infrastructure in which one or more portions of system control software 5731 is hosted in a public or private network platform, managed in-house, or by a service provider. In this manner, system control software 5731 may be made available in an on-demand fashion in any suitable networking configuration. Alternatively, control logic may be hard coded in system controller 5723. Application specific integrated circuits (ASIC), programmable logic devices (e.g., field-programmable gate arrays (FPGAs)) and/or the like may be used for these purposes. In the following discussion, wherever “software” or “code” is used, functionally comparable hard coded logic may be used in its place. System control software 5731 may include instructions for monitoring and controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by multi-station processing tool 5700. System control software 5731 may be configured in any suitable way. For example, various process tool component subroutines or control objects may be written to control operation of the process tool components used to carry out various process tool processes. System control software 5731 may be coded in any suitable computer readable programming language.

In some embodiments, system control software 5731 may include input/output control (IOC) sequencing instructions for monitoring and controlling the various parameters described above. Other computer software and/or programs stored on mass storage device 5727 and/or memory device 5725 associated with system controller 5723 may be employed in some embodiments. Examples of programs or sections of programs for this purpose include a substrate positioning program, a process gas control program, a pressure control program, a heater control program, a cooler control program, and a plasma control program.

A substrate positioning program may include program code for process tool components that are used to load and orientate wafer 105 on pedestal 5721 and to control the spacing between wafer 105 and other parts of multi-station processing tool 5700. A substrate positioning program may further include program code to monitor the performance of, for example, one or more pedestals, one or more actuators, and/or one or more motors, such as, for example, how fast the actuators respond to at least one instruction to move up or down a pedestal and/or how accurately the pedestal moves to the desired spacing.

A process gas control program may include code for controlling gas composition (e.g., silicon-containing gases, oxygen-containing gases, nitrogen-containing gases, dilution (or inert) gases, etc.) and flow rates, and optionally for flowing gas into one or more process stations prior to deposition to stabilize the pressure in the process station. A pressure control program may include code for controlling the pressure in the process station by regulating, for example, a throttle valve in an exhaust system of the process station, a gas flow into the process station, and/or the like. A pressure control program may further include program code to monitor the performance of, for example, mass flow controllers, for example, that are configured to monitor, and thereby facilitate the control of the flow of gas, e.g., process gas, purge gas, inert gas, etc., into one or more stations of multi-station processing tool 5700.

A heater control program may include code for controlling current to a heating unit used to heat a pedestal (e.g., pedestal 5721) and/or a showerhead (e.g., showerhead 107) of processing chamber 5715, and, thereby, to heat wafer 105. Additionally or alternatively, the heater control program may control delivery of a heat transfer gas (such as helium) to a gas distributor, and, thereby, to wafer 105. In some implementations, a heater control program may include program code to control the temperature of multi-station processing tool 5700 or one or more stations thereof. In some cases, the temperature of at least one station of multi-station processing tool 5700 may be different than at least one other station of multi-station processing tool 5700, and as such, the heater control program may include code to ensure such processing conditions are provided. It is also contemplated that a heater control program may include code for controlling current to a heating unit used to heat a gas distribution body (e.g., showerhead 107) of processing chamber 5715, and, thereby, to heat gas flowing therefrom and/or the gas distribution body itself.

A cooling control program may include code for controlling a flow rate of conductive cooling fluid through a cooling unit used to extract heat from a pedestal (e.g., pedestal 5721) and/or a showerhead (e.g., showerhead 107) of processing chamber 5715, and, thereby, transfer such thermal energy to, for instance, a waste heat capturing, storage, recycling, and/or disposing system. In some implementations, a cooling control program may include program code to control the temperature of multi-station processing tool 5700 or one or more stations thereof. In some cases, the temperature of at least one station of multi-station processing tool 5700 may be different than at least one other station of multi-station processing tool 5700, and as such, the cooling control program may include code to ensure such processing conditions are provided. It is also contemplated that a cooling control program may include code for controlling flow of conductive cooling fluid through a cooling unit used to extract heat from a gas distribution body (e.g., showerhead 107) of processing chamber 5715, and, thereby, to cool gas flowing therefrom and/or the gas distribution body itself.

A plasma control program may include code for setting RF power levels applied to the process electrodes in one or more process stations in accordance with various embodiments. In some cases, a plasma control program may include code for controlling when plasma may be struck within one or more stations of multi-station processing tool 5700 and for how long the plasma is to be maintained and/or extinguished. The plasma control program may further include code for controlling the generation of plasma in association with one or more cleaning operations of multi-station processing tool 5700.

A pressure control program may include code for maintaining pressure in a reaction chamber in accordance with various embodiments. The code of the pressure control program may be configured to regulate maximum and minimum allowable pressures, acceptable levels of pressure variation, etc. In some cases, the pressure control program may include code for operating one or more valves of multi-station processing tool 5700 to increase, decrease, or maintain pressure within one or more stations of multi-station processing tool 5700.

In some embodiments, a user interface may be provided in association with system controller 5723. The user interface may include a display screen, graphical software displays of the apparatus and/or process conditions, and user input devices, such as pointing devices, keyboards, touch screens, microphones, etc.

In some embodiments, parameters adjusted by system controller 5723 may relate to process conditions. Non-limiting examples include process gas composition and flow rates, temperature, pressure, plasma conditions (such as RF bias power levels), pressure, temperature, etc. These parameters may be provided to the user in the form of a recipe, which may be entered utilizing the user interface.

Signals for monitoring the process may be provided by analog and/or digital input connections of system controller 5723 from various process tool sensors. The signals for controlling the process may be output on analog and/or digital output connections of multi-station process tool 5700. Non-limiting examples of process tool sensors that may be monitored include mass flow controllers, pressure sensors (such as manometers), thermocouples, etc. Appropriately programmed feedback and control algorithms may be used with data from the sensors to maintain process conditions.

System controller 5723 may provide program instructions for implementing one or more of the above-described processes. The program instructions may control a variety of process parameters, such as direct current (DC) power level, RF bias power level, pressure, temperature, etc. The instructions may control the parameters to operate deposition of film stacks of a stress compensation layer according to various embodiments.

System controller 5723 will typically include one or more memory devices and one or more processors configured to execute the instructions so that the apparatus will perform a method in accordance with some embodiments. In some instances, machine-readable media containing instructions for controlling process operations in accordance with various embodiments may be coupled to system controller 5723.

In some embodiments, system controller 5723 may be part of a system, which may be part of at least one of the above-described examples. Such systems may include semiconductor processing equipment, including a processing tool or tools, a chamber or chambers, a platform or platforms for processing, and/or specific processing components (e.g., a wafer pedestal, a gas flow system, a thermal management system, etc.). The systems discussed above may be integrated with electronics for controlling their operation before, during, and/or after processing of a semiconductor wafer or substrate. The electronics may be referred to as the “controller,” which may control various components or subparts of the system or systems. For instance, system controller 5723, depending on the processing requirements and/or the type of system, may be programmed to control any of the processes disclosed herein, including the delivery of processing gases, temperature settings (e.g., heating and/or cooling), valve operation, light source control for radiative heating, pressure settings, vacuum settings, power settings, RF generator settings, RF matching circuit settings, frequency settings, flow rate settings, fluid delivery settings, positional and operational settings, wafer transfers into and out of a tool or chamber and other transfer tools and/or load locks connected to or interfaced with a specific system. In this manner, system controller 5723 may be configured to control, among other systems, the various actuators and motors of a backside wafer processing system.

Broadly speaking, system controller 5723 may be defined as electronics having various integrated circuits, logic, memory, and/or software that receive instructions, issue instructions, control operation, enable cleaning operations, enable endpoint measurements, and/or the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to system controller 5723 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon oxide, surfaces, circuits, dies of a wafer, etc.

System controller 5723, in some implementations, may be a part of or coupled to a computer that is integrated with, coupled to the system, otherwise networked to the system, or a combination thereof. For example, system controller 5723 may be in the “cloud” or all or a part of a fab host computer system, which can allow for remote access of wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g., a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It is to be understood that the parameters may be specific to the type of process to be performed and the type of tool that the controller is configured to interface with or control. Thus, as described above, system controller 5723 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and/or any other semiconductor processing system that may be associated or used in the fabrication and/or manufacturing of semiconductor wafers.

As noted above, depending on the process step or steps to be performed by the tool, system controller 5723 might communicate with one or more of other tool circuits or modules, other tool components, cluster tools, other tool interfaces, adjacent tools, neighboring tools, tools located throughout a factory, a main computer, another controller, and/or tools used in material transport that bring containers of wafers to and from tool locations and/or load ports in a semiconductor manufacturing factory.

### Chamber Clean Operations

Various semiconductor processes may generate by-products that adhere to components in a processing chamber, such as one or more of the processing chambers of the multi-station processing tool described in association with FIG. 57. As such, one or more maintenance processes or operations may be performed on the processing chambers to not only increase the longevity of the chambers themselves, but also to prevent or at least reduce the likelihood of process and/or product contamination during semiconductor processing operations. For example, various chamber clean operations may be employed to remove accumulated deposits from interior components of, for example, chemical vapor deposition (CVD), plasma-enhanced chemical vapor deposition (PECVD), physical vapor deposition (PVD), atomic layer deposition (ALD), plasma-enhanced atomic layer deposition (PE-ALD), etc., processing chambers. In some cases, a cleaning gas, such as NF₃, F₂, C₂F₄, SF₆, C₂F₆, CCl₄, C₂Cl₆, and/or the like, may be flowed through the processing chambers to remove deposited material from exposed surfaces of components interior to the processing chambers, such as exposed surfaces of the chamber walls, a support pedestal, a showerhead pedestal, and/or the like. Plasma may or may not be formed in association with the introduction of the cleaning gas. In some implementations, a plasma may be formed remote from the processing chambers and dissociated species from the plasma may be flowed into the processing chambers to react with and remove unwanted deposits on components interior thereto. These operations may be generally referred to as remote plasma clean (RPC) processes, which are typically less harsh on chamber components than conventional in situ cleaning operations as the generated plasma does not typically come into direct contact with the chamber components. Moreover, RPC processes are typically capable of removing unwanted deposits without completely removing protective coatings formed on the chamber components, such as protective coatings formed of (or otherwise including) aluminum fluoride, aluminum nitride, aluminum oxide, aluminum oxynitride, yttrium nitride, yttrium oxide, yttrium oxynitride, and/or the like. When, however, purge gas is flowed from a gas distribution body during or as part of a chamber clean process, a magnitude of a perpendicular (or vertical) component of a mean velocity of the gas flow relative to, for instance, a pedestal facing the gas distribution body may be large enough to cause, at least in part, some of the protective coating on the pedestal to also be disproportionally removed from an area corresponding to a projection of the source of the gas flow onto the pedestal. Variations in the thickness of the protective coating may, in some cases, translate into undesired features being formed on a semiconductor wafer during subsequent semiconductor processing operations. As such, there is a need for an approach that efficiently and effectively prevents or at least reduces the likelihood of purge gas interaction with a protective coating on process chamber components as part of a chamber clean operation, such as an RPC process.

According to one or more embodiments, the likelihood of purge gas interaction with a protective coating on an interior chamber component during or as part of a chamber clean operation, such as an RPC process, may be achieved via utilization of one or more inserts having one or more features such as described herein in combination with a gas distribution body to tailor a flow of one or more purge gases from the gas distribution body in association with the chamber clean operation. As such, one or more embodiments may seek to provide an insert(s) configured to minimize or at least reduce a magnitude of a component (e.g., a perpendicular (or vertical) component) of a mean velocity of the flow of the one or more purge gases relative to a chamber component facing the gas distribution body, such as a pedestal, showerhead pedestal, and/or the like. Although various embodiments will be described in association with a multi-station processing tool implementing an RPC process, embodiments are also applicable to single station processing tools, as well as other chamber clean processes.

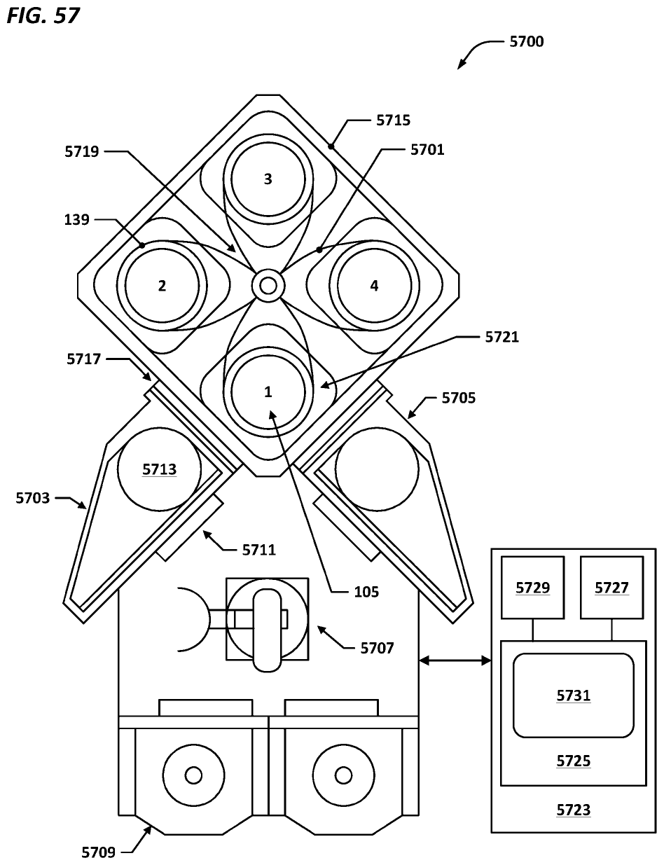

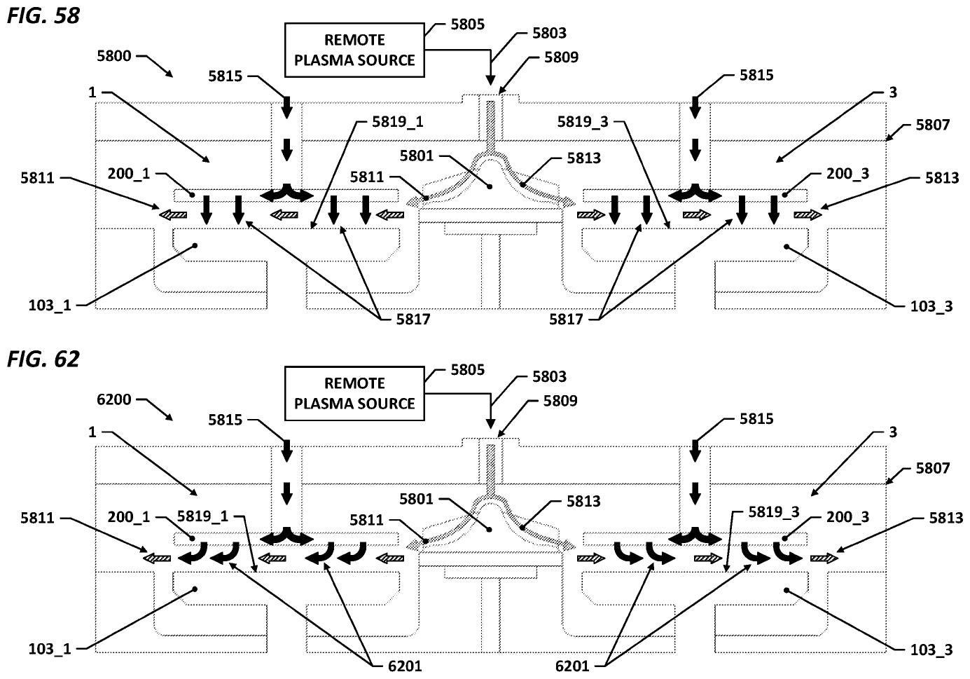

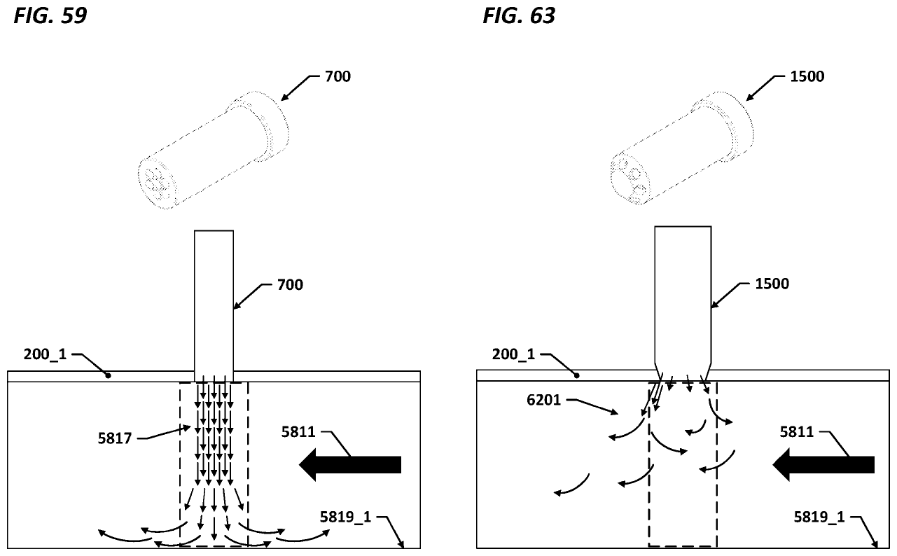

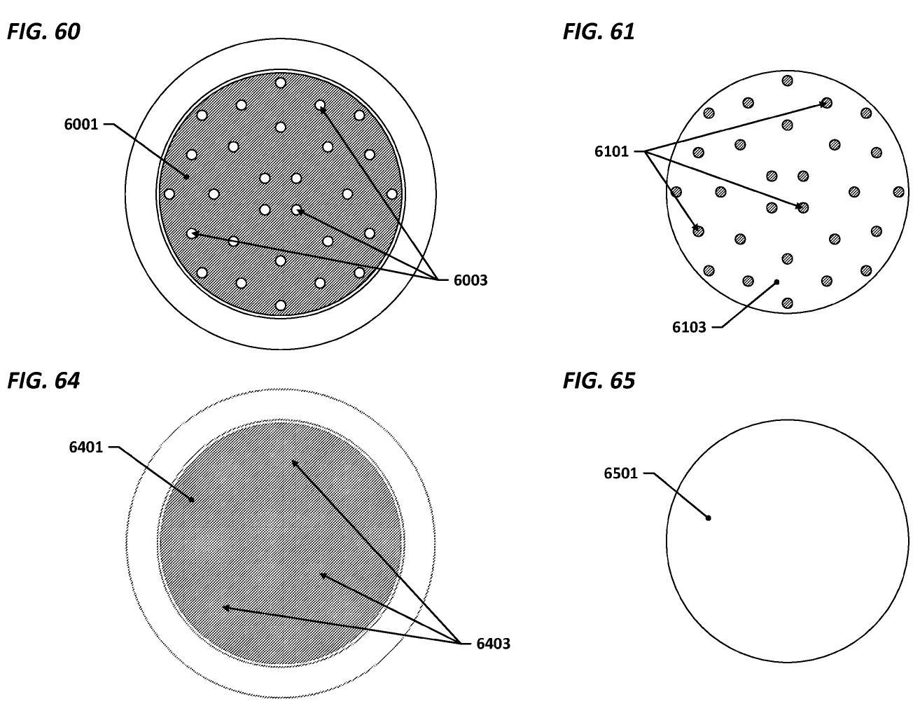

FIG. 58 schematically illustrates a cross-sectional view of the multi-station processing tool of FIG. 57 implementing a remote plasma clean (RPC) process utilizing instances of the gas distributor of FIG. 2 and the gas distribution port insert of FIG. 7 according to some embodiments. FIG. 59 schematically depicts a simulated mean velocity profile of purge gas output from the gas distribution port insert of FIG. 7 in association with the RPC process of FIG. 58 according to some embodiments. FIGS. 60 and 61 schematically illustrate a plan view of a support pedestal after the RPC process of FIG. 58 and a backside view of a semiconductor wafer after being processed using the support pedestal of FIG. 61 according to some embodiments.

Referring to FIG. 58, multi-station processing tool (or tool) 5800 may correspond to tool 5700 described in association with FIG. 57, but may also incorporate directional flow structure 5801 arranged between the various process stations of tool 5800, such as stations 1 and 3 in which instances of gas distributor 200 (e.g., instances 200_1 and 200_3) and pedestal 103 (e.g., instances 103_1 and 103_3) are respectively arranged. For convenience, embodiments will be described relative to the configuration of stations 1 and 3, but may also apply to the configuration of other stations of tool 5800, such as stations 2 and 4. Although directional flow structure 5801 is shown directing one or more cleaning gases 5803 into the areas between gas distributors 200_1 and 200_3 and pedestals 103_1 and 103_3, it is contemplated that cleaning gases 5803 may be directed into one or more other or additional areas within an interior of tool 5800. For example, directional flow structure 5801 may be positioned and/or configured to deliver cleaning gases 5803 above gas distributors 200_1 and 200_3, between gas distributors 200_1 and 200_3 and pedestals 103_1 and 103_3 (as shown), and/or below pedestals 103_1 and 103_3 at different (or similar) time periods during one or more cleaning cycle operations.

One or more disassociated species may be generated by remote plasma source 5805 from various types of cleaning gases, such as one or more of the aforementioned cleaning gas compounds. As such, cleaning gases 5803 may include the dissociated species and may enter processing chamber 5807 of tool 5800 via cleaning gas inlet 5809. Cleaning gas inlet 5809 may be fluidically connected to each of remote plasma source 5805 and an interior region of tool 5800. An initial flow of cleaning gases 5803 introduced to the interior region of processing chamber 5807 may flow in a first direction towards directional flow structure 5801 and may be divided by directional flow structure 5801 into one or more substantially uniform flows (such as flows 5811 and 5813) to the various stations (e.g., stations 1 and 3) of tool 5800. In some cases, the substantially uniform flows may be diverted to corresponding flow paths extending transverse to the first direction, such as perpendicular (or substantially perpendicular) to the first direction. To prevent or at least reduce the potential for cleaning gases 5803 from flowing into gas distributors 200_1 and 200_3, one or more purge gases 5815 may be flowed from the gas distribution port inserts of gas distributors 200_1 and 200_3.

For instance, gas distributors 200_1 and 200_3 may include one or more instances of insert 700 at least partially supported in at least one of its gas distribution ports (e.g., gas distribution port 207). As described in association with FIGS. 7-10, the configuration of bore 909 and gas outlet orifices 721 of insert 700 may cause, at least in part, an increased throughput (or mean velocity) of purge gas through insert 700 relative to insert 300 that may primarily flow in a direction parallel (or substantially parallel) to the direction of extension of central axes 801 and 805 of gas outlet orifices 721. As can be appreciated from FIGS. 10, 58, and 59, purge gas flows 5817 may extend (or substantially extend) in a direction perpendicular (or substantially perpendicular) to the substantially uniform flows of cleaning gases (e.g., flows 5811 and 5813) and corresponding surfaces of gas distributors 200_1 and 200_3 and pedestals 103_1 and 103_3. In some cases, corresponding mean velocities of the substantially uniform flows of cleaning gases (e.g., flows 5811 and 5813) may not be strong enough to sufficiently dissipate (or otherwise disturb) purge gas flows 5817 before purge gas flows 5817 impinge upon and/or form eddies near surfaces facing gas distributors 200_1 and 200_3, such as surfaces 5819_1 and 5819_3 of respective pedestals 103_1 and 103_3. It is noted that phantom lines and arrows are shown in the simulated mean velocity profile depicted in FIG. 59 to emphasize an area of relatively higher mean velocity flow and the eddying of purge gas near, for instance, surface 5819_1 of pedestal 103_1. It is also noted that areas of higher arrow density relate to areas of higher mean velocity. The impingement and/or eddying of purge gas near surfaces 5819_1 and 5819_3 of pedestals 103_1 and 103_3 may cause, at least in part, some of protective coating 6001 formed on pedestals 103_1 and 103_3 being disproportionally removed in areas 6003 as schematically illustrated in FIG. 61. Areas 6003 may correspond to and/or encircle projections of gas outlet orifices 721 onto surfaces 5819_1 and 5819_3 of pedestals 103_1 and 103_3. It has also been observed that the variation in thickness between areas 6003 and a remaining portion of protective coating 6001 on a pedestal may, in some cases, translate into undesired features 6101 being formed on, for instance, backside 6103 of a semiconductor wafer during subsequent semiconductor processing utilizing such a pedestal. Features 6101 may be formed in (or on) areas of the semiconductor wafer corresponding to the locations of areas 6003.

According to some embodiments, the utilization of one or more of the gas distribution inserts described herein may minimize or at least reduce a magnitude of a component (e.g., a perpendicular (or vertical) component) of a mean velocity of the flow of the one or more purge gases relative to a chamber component facing the gas distribution body, such as a pedestal, showerhead pedestal, and/or the like. This may prevent or at least reduce the likelihood of purge gas interaction with the protective coating on the process chamber component during one or more chamber clean operations, such as an RPC process.

FIG. 62 schematically illustrates a cross-sectional view of the multi-station processing tool of FIG. 57 implementing an RPC process utilizing the gas distributor of FIG. 2 and the gas distribution port insert of FIG. 15 according to some embodiments. FIG. 63 schematically depicts a simulated mean velocity profile of purge gas output from the gas distribution port insert of FIG. 15 in association with the RPC process of FIG. 62 according to some embodiments. FIGS. 64 and 65 schematically illustrate a plan view of a support pedestal after the RPC process of FIG. 62 and a backside view of a semiconductor wafer after being processed using the support pedestal of FIG. 64 according to some embodiments. It is noted, however, that multi-station processing tool (or tool) 6200 may correspond to tools 5700 and 5800 described in association with FIGS. 57 and 58, except that the gas distributors (such as gas distributors 200_1 and 200_3) of tool 6200 may include one or more instances of insert 1500 at least partially supported in at least one of its gas distribution ports (e.g., gas distribution port 207) versus insert 700 as in tool 5800. Accordingly, primarily differences between flows 5817 and 6201 of purge gas from gas distributors 103_1 and 103_3 of tools 5800 and 6200 will be described below.

As described in association with FIGS. 15-19, the configuration of bore 1711 and gas outlet orifices 1527 of insert 1500 may cause, at least in part, a decrease in throughput (or mean velocity) of purge gas through insert 1500 relative to at least inserts 300 and 700 that may primarily flow in a direction parallel (or substantially parallel) to the directions of extension of the central axes (e.g., central axis 1801) of gas outlet orifices 1527. It will be recalled that the central axes (e.g., central axis 1801) of gas outlet orifices 1527 may extend outwards from reference axis 1511 of insert 1500 that may extend parallel (or substantially parallel) to a direction perpendicular to surfaces 5819_1 and 5819_3 of pedestals 103_1 and 103_3. Accordingly, as can be appreciated from FIGS. 18, 19, 62, and 63, purge gas flows 6201 from instances of insert 1500 may extend (or substantially extend) in directions transverse to the direction perpendicular to surfaces 5819_1 and 5819_3 of pedestals 103_1 and 103_3, and in some cases, towards the direction of flow of cleaning gases 5803. However, with respect to some of gas outlet orifices 1527, a component (e.g., a horizontal component) of the flow of purge gas may be transverse to or opposite the direction of flow of cleaning gases 5803. As such, one or more of these flow conditions may reduce a magnitude of a component of the mean velocities of purge gas flows 6201 in the direction perpendicular to surfaces 5819_1 and 5819_3. The mean velocities of purge gas flows 6201 may also be reduced by the injection of at least some of purge gases 5815 into the gaps between lateral surfaces 1523 of inserts 1500 and the lower portions of inner surfaces 259 of gas distribution ports 207 near openings 205 in gas distributors 200_1 and 200_3 as can be appreciated from the description accompanying FIGS. 2 and 15-19.

With the reduction in the mean velocities of purge gas flows 6201 and the variability in directional output of the purge gas from gas outlet orifices 1527, the substantially uniform flows of cleaning gases (e.g., flows 5811 and 5813) may also be capable of further dissipating (or otherwise disturbing) the flow of purge gas towards surfaces 5819_1 and 5819_3 of pedestals 103_1 and 103_3. As such, purge gas flows 6201 may be prevented or sufficiently hindered from impinging upon and/or forming eddies near surfaces facing gas distributors 200_1 and 200_3, such as surfaces 5819_1 and 5819_3 of pedestals 103_1 and 103_3. It is noted that phantom lines and arrows are shown in the simulated mean velocity profile depicted in FIG. 63 to emphasize an area of relatively insignificant mean velocity flow of purge gas and the relative absence of purge gas eddying near, for instance, surface 5819_1 of pedestal 103_1. To this end, areas of lower arrow density relate to areas of lower mean velocity. The flow of purge gas in association with insert 1500 may prevent or at least reduce the extent to which protective coating 6401 formed on pedestals 103_1 and 103_3 is disproportionately removed in areas 6403 as schematically illustrated in FIG. 64. Similar to areas 6003, areas 6403 may correspond to and/or encircle projections of gas outlet orifices 1527 onto surfaces 5819_1 and 5819_3 of pedestals 103_1 and 103_3. Accordingly, at least because the uniformity (or substantial uniformity) of the protective coatings on a chamber component (such as a pedestal) may be maintained despite one or more chamber clean operations being performed, subsequent semiconductor processing on a semiconductor wafer utilizing such pedestals may not cause undesired features being formed on, for example, backside 6501 of the semiconductor wafer.

Similar and/or increased effects may also be achieved through the use of at least one of inserts 2000, 2500, 3000, 3600, and 4800 during one or more chamber clean operations at least because inserts 2000, 2500, 3000, 3600, and 4800 may also be configured to minimize or at least reduce a magnitude of a component (e.g., a perpendicular or vertical component) of a mean velocity of the flow of the one or more purge gases relative to a chamber component facing the gas distribution body, such as a pedestal, showerhead pedestal, and/or the like.

### ADDITIONAL AND/OR ALTERNATIVE EMBODIMENTS

Unless otherwise specified, the illustrated embodiments are to be understood as providing example features of varying detail of some embodiments. Thus, unless otherwise specified, the features, components, modules, layers, films, regions, aspects, structures, etc. (hereinafter individually or collectively referred to as an “element” or “elements”), of the various illustrations may be otherwise combined, separated, interchanged, and/or rearranged without departing from the teachings of the disclosure. For instance, it is contemplated that one or more elements of one or more first inserts may be combined, separated, interchanged, and/or rearranged with one or more elements of one or more second inserts without departing from the teachings of the disclosure. For example, the conical frustum configuration of body portion 1103 of insert 1100 may be utilized in place of the generally cylindrical body portion 3603 of insert 3600. As another example, second gas outlet orifices 2521 of insert 2500 may be utilized in association with gas outlet orifices 1527 of insert 1500.

The terminology used herein is for the purpose of describing some embodiments and is not intended to be limiting. As used herein, the singular forms, “a,” “an,” and “the” are intended to include the plural forms as well, unless the context clearly indicates otherwise. It is to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items-it is to be understood that a set or a subset can encompass only one member or multiple members (unless the context indicates otherwise). The terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art. Accordingly, the term “substantially” as used herein, unless otherwise specified, means within 5% of a referenced value. For example, substantially perpendicular means within ±5% of parallel.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. As such, the sizes and relative sizes of the respective elements are not necessarily limited to the sizes and relative sizes shown in the drawings. When an embodiment may be implemented differently, a specific process order may be performed differently from the described order. For example, two consecutively described processes may be performed substantially at the same time or performed in an order opposite to the described order.

When an element, such as a layer, is referred to as being “on,” “connected to,” or “coupled to” another element, it may be directly on, directly connected to, or directly coupled to the other element or at least one intervening element may be present. When, however, an element is referred to as being “directly on,” “directly connected to,” or “directly coupled to” another element, there are no intervening elements present. Other terms and/or phrases if used herein to describe a relationship between elements should be interpreted in a like fashion, such as “between” versus “directly between,” “adjacent” versus “directly adjacent,” “on” versus “directly on,” etc. Further, the term “connected” may refer to physical, electrical, and/or fluid connection. To this end, for the purposes of this disclosure, the phrase “fluidically connected” is used with respect to volumes, plenums, holes, etc., that may be connected to one another, either directly or via one or more intervening components or volumes, to form a fluidic connection, similar to how the phrase “electrically connected” is used with respect to components that are connected to form an electric connection. The phrase “fluidically interposed,” if used, may be used to refer to a component, volume, plenum, hole, etc., that is fluidically connected with at least two other components, volumes, plenums, holes, etc., such that fluid flowing from one of those other components, volumes, plenums, holes etc., to the other or another of those components, volumes, plenums, holes, etc., would first flow through the “fluidically interposed” component before reaching that other or another of those components, volumes, plenums, holes, etc. For example, if a pump is fluidically interposed between a reservoir and an outlet, fluid flowing from the reservoir to the outlet would first flow through the pump before reaching the outlet. The phrase “fluidically adjacent,” if used, refers to placement of a fluidic element relative to another fluidic element such that no potential structures fluidically are interposed between the two elements that might potentially interrupt fluid flow between the two fluidic elements. For example, in a flow path having a first valve, a second valve, and a third valve arranged sequentially therealong, the first valve would be fluidically adjacent to the second valve, the second valve fluidically adjacent to both the first and third valves, and the third valve fluidically adjacent to the second valve.

For the purposes of this disclosure, “at least one of X, Y, . . . , and Z” and “at least one selected from the group consisting of X, Y, . . . , and Z” may be construed as X only, Y only, . . . , Z only, or any combination of two or more of X, Y, . . . , and Z, such as, for instance, XYZ, XYY, YZ, and ZZ. As used herein, the term “and/or” includes any and all combinations of one or more of the associated listed items.

Although the terms “first,” “second,” “third,” etc., may be used herein to describe various elements, these elements should not be limited by these terms. These terms are used to distinguish one element from another element. Thus, a first element discussed below could be termed a second element without departing from the teachings of the disclosure. To this end, use of such identifiers, e.g., “a first element,” should not be read as suggesting, implicitly or inherently, that there is necessarily another instance, e.g., “a second element.” Further, the use, if any, of ordinal indicators, such as (a), (b), (c), . . . , or (1), (2), (3), . . . , or the like, in this disclosure and accompanying claims, is to be understood as not conveying any particular order or sequence, except to the extent that such an order or sequence is explicitly indicated. For example, if there are three steps labeled (i), (ii), and (iii), it is to be understood that these steps may be performed in any order (or even concurrently, if not otherwise contraindicated), unless indicated otherwise. For example, if step (ii) involves the handling of an element that is created in step (i), then step (ii) may be viewed as happening at some point after step (i). In a similar manner, if step (i) involves the handling of an element that is created in step (ii), the reverse is to be understood.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's spatial relationship to at least one other element as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” or “over” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein interpreted accordingly.

The term “between,” as used herein and when used with a range of values, is to be understood, unless otherwise indicated, as being inclusive of the start and end values of that range. For example, between 1 and 5 is to be understood as inclusive of the numbers 1, 2, 3, 4, and 5, not just the numbers 2, 3, and 4.

As used herein, the phrase “operatively connected” is to be understood as referring to a state in which two components and/or systems are connected, either directly or indirectly, such that, for example, at least one component or system can control the other. For instance, a controller may be described as being operatively connected with (or to) a resistive heating unit, which is inclusive of the controller being connected with a sub-controller of the resistive heating unit that is electrically connected with a relay that is configured to controllably connect or disconnect the resistive heating unit with a power source that is capable of providing an amount of power that is able to power the resistive heating unit so as to generate a desired degree of heating. The controller itself likely will not supply such power directly to the resistive heating unit due to the current(s) involved, but it is to be understood that the controller is nonetheless operatively connected with the resistive heating unit.

As used herein, the singular forms, “a,” “an,” and “the” are intended to include the plural forms as well, unless the context clearly indicates otherwise. It is also to be understood that the phrases “for each <item> of the one or more <items>,” “each <item> of the one or more <items>,” and/or the like, if used herein, are inclusive of both a single-item group and multiple-item groups, i.e., the phrase “for . . . each” is used in the sense that it is used in programming languages to refer to each item of whatever population of items is referenced. For example, if the population of items referenced is a single item, then “each” would refer to only that single item (despite dictionary definitions of “each” frequently defining the term to refer to “every one of two or more things”) and would not imply that there must be at least two of those items. Similarly, the term “set” or “subset” should not be viewed, in itself, as necessarily encompassing a plurality of items-it is to be understood that a set or a subset can encompass only one member or multiple members (unless the context indicates otherwise). In addition, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various embodiments are described herein with reference to sectional views, isometric views, perspective views, plan views, and/or exploded illustrations that are schematic depictions of idealized embodiments and/or intermediate structures. As such, variations from the shapes of the illustrations as a result of, for example, manufacturing techniques and/or tolerances, are to be expected. Thus, embodiments disclosed herein should not be construed as limited to the particular illustrated shapes of regions, but are to include deviations in shapes that result from, for instance, manufacturing. To this end, regions illustrated in the drawings may be schematic in nature and shapes of these regions may not reflect the actual shapes of regions of a device, and, as such, are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and are not to be interpreted in an idealized or overly formal sense, unless expressly so defined herein.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the inventive concepts. Further, the blocks, units, and/or modules of some embodiments may be physically combined into more complex blocks, units, and/or modules without departing from the teachings of the disclosure.

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatuses of the disclosed embodiments. Accordingly, embodiments are to be considered as illustrative and not as restrictive, and embodiments are not to be limited to the details given herein.

It is to be further understood that the above disclosure, although focusing on a particular example implementation or implementations, is not limited to only the discussed example, but may also apply to similar variants and mechanisms as well, and such similar variants and mechanisms are also considered to be within the scope of this disclosure. For the avoidance of any doubt, it is also to be understood that the above disclosure is at least directed to the following numbered implementations, as well as to other implementations that are evident from the above disclosure.

Implementation 1: A gas distribution port insert (“insert”) including a head portion, a body portion, a bore, and a plurality of gas outlet orifices. The head portion includes a gas inlet surface, an intermediate surface opposing the gas inlet surface in a first direction, and at least one first lateral surface connecting the gas inlet surface to the intermediate surface. The body portion extends from the head portion. The body portion includes a proximal end adjacent to the intermediate surface; a distal end spaced apart from the proximal end in the first direction, the distal end terminating at a first distal surface; and at least one second lateral surface connecting the distal end to the proximal end. The bore extends along a reference axis from the gas inlet surface through the head portion and partially through the body portion. The bore terminates at a second distal surface interior to the body portion. The plurality of gas outlet orifices is fluidically connected to the bore within the interior of the body portion and is circumferentially arranged about the reference axis. A width of the head portion in a second direction transverse to the first direction is greater than a width of the body portion in the second direction.

Implementation 2: The insert of implementation 1, in which proximal ends of the gas outlet orifices are formed in the second distal surface.

Implementation 3: The insert of either implementation 1 or implementation 2, in which distal ends of the gas outlet orifices are formed in the first distal surface.

Implementation 4: The insert of either implementation 1 or implementation 2, in which: the body portion further includes at least one third lateral surface connecting the first distal surface to the at least one second lateral surface, the at least one third lateral surface being inclined with respect to the first distal surface; and distal ends of the gas outlet orifices are formed in the at least one third lateral surface.

Implementation 5: The insert of implementation 4, in which an angle of inclination of the at least one third lateral surface is greater than 0° and less than 80°.

Implementation 6: The insert of implementation 5, in which the angle of inclination of the at least one third lateral surface is about 45°.

Implementation 7: The insert of any one of implementations 1-6, in which the gas outlet orifices longitudinally extend in the first direction.

Implementation 8: The insert of any one of implementations 1-6, in which respective axes of longitudinal extension of the gas outlet orifices extend outwards from the reference axis and form corresponding angles of inclination with the reference axis.

Implementation 9: The insert of implementations 4 and 8, in which the respective axes of longitudinal extension of the gas outlet orifices extend substantially perpendicular to the at least one third lateral surface.

Implementation 10: The insert of any one of implementations 1-9, further including an additional gas outlet orifice in the first distal end surface. The gas outlet orifices are circumferentially arranged about the additional gas outlet orifice.

Implementation 11: The insert of implementation 10, in which the additional gas outlet orifice longitudinally extends in the first direction.

Implementation 12: The insert of either implementation 10 or implementation 11, in which the reference axis and a central axis of longitudinal extension of the additional gas outlet orifice are substantially coincident.

Implementation 13: The insert of implementation 10, in which an axis of longitudinal extension of the additional gas outlet orifice extends outwards from the reference axis and forms an angle of inclination with the reference axis.

Implementation 14: The insert of any one of implementations 1-13, in which respective lengths of the gas outlet orifices are between about 0.04 mm and about 0.6 mm.

Implementation 15: The insert of any one of implementations 1-13, in which respective lengths of the gas outlet orifices are between about 0.2 mm and about 0.3 mm.

Implementation 16: The insert of any one of implementations 1-15, in which each gas outlet orifice among the gas outlet orifices has a central axis of longitudinal extension, and a maximum dimension in a plane perpendicular to the central axis. The corresponding maximum dimensions of the gas outlet orifices are substantially equivalent, and a diameter of a reference circle that extends through the corresponding central axes of the gas outlet orifices is greater than twice the maximum dimension and less than three times the maximum dimension.

Implementation 17: The insert of implementation 16, in which the diameter of the reference circle is greater than about 0.08 mm and less than about 0.12 mm.

Implementation 18: The insert of any one of implementations 1-15, in which each gas outlet orifice among the gas outlet orifices has a central axis of longitudinal extension, and a diameter of a reference circle that extends through the corresponding central axes of the gas outlet orifices is greater than about 0.1 mm and less than about 0.3 mm.

Implementation 19: The insert of any one of implementations 1-18, in which a total number of the gas outlet orifices is “n,” “n” is an integer greater than or equal to two, and an angular pitch between adjacent gas outlet orifices among the gas outlet orifices is approximately 360o/n.

Implementation 20: The insert of implementation 19, in which “n” is 6.

Implementation 21: A gas distribution port insert (“insert”) including a head portion, a body portion, a bore, and a plurality of gas outlet orifices. The head portion includes a gas inlet surface, an intermediate surface opposing the gas inlet surface in a first direction, and at least one first lateral surface connecting the gas inlet surface to the intermediate surface. The body portion extends from the head portion. The body portion includes: a proximal end adjacent to the intermediate surface; a distal end spaced apart from the proximal end in the first direction, the distal end terminating at a first distal surface; and at least one second lateral surface connecting the distal end to the proximal end. The bore extends along a reference axis from the gas inlet surface through the head portion and partially through the body portion. The bore terminates at a second distal surface interior to the body portion. The plurality of gas outlet orifices is in the at least one second lateral surface and is fluidically connected to the bore within the interior of the body portion. The first gas outlet orifices are circumferentially arranged about the reference axis. A width of the head portion in a second direction transverse to the first direction is greater than a width of the body portion in the second direction.

Implementation 22: The insert of implementation 21, in which the plurality of gas outlet orifices includes a set of first gas outlet orifices and a set of second gas outlet orifices offset from the first gas outlet orifices in the first direction such that the first gas outlet orifices are arranged closer to the proximal end of the body portion than the second gas outlet orifices.

Implementation 23: The insert of either implementation 21 or implementation 22, in which respective axes of longitudinal extension of the gas outlet orifices extend outwards from the reference axis.

Implementation 24: The insert of implementation 23, in which the respective axes of longitudinal extension of the gas outlet orifices extend radially outwards from the reference axis.

Implementation 25: The insert of implementation 23, in which the respective axes of longitudinal extension form corresponding angles of inclination with a first reference plane perpendicular to the reference axis.

Implementation 26: The insert of any one of implementations 21-25, in which the second distal surface is tangent to some of the gas outlet orifices.

Implementation 27: The insert of implementations 22, 24, and 26 or implementations 22, 25, and 26, in which the intermediate surface extends in a second reference plane, the some of the gas outlet orifices tangent to the second distal surface form the set of second gas outlet orifices, and the first gas outlet orifices are spaced apart from the second reference plane in the first direction.

Implementation 28: The insert of any one of implementations 21-26, in which the intermediate surface extends in a second reference plane, and the second reference plane is tangent to some of the gas outlet orifices.

Implementation 29: The insert of implementations 22, 25, 26, and 28, in which the some of the gas outlet orifices tangent to the second distal surface form the set of second gas outlet orifices, and the some of the gas outlet orifices tangent to the second reference plane form the set of first gas outlet orifices.

Implementation 30: The insert of any one of implementations 22-29, in which respective first openings of the set of first gas outlet orifices have corresponding first central axes tangent to the at least one second lateral surface, respective second openings of the set of second gas outlet orifices have corresponding second central axes tangent to the at least one second lateral surface, and the first central axes are circumferentially offset from the second central axes in a manner that the first central axes are incongruent with the second central axes.

Implementation 31: The insert of any one of implementation 30, in which a total number of the gas outlet orifices is “n,” “n” is an integer greater than or equal to four, and an angular pitch between respective ones of the first central axes and correspondingly adjacent ones of the second central axes is approximately 360o/n.

Implementation 32: The insert of implementation 31, in which “n” is 12.

Implementation 33: The insert of implementation 31, in which “n” is 14.

Implementation 34: The insert of any one of implementations 22-29, in which respective openings of the set of first gas outlet orifices have corresponding first central axes tangent to the at least one second lateral surface, respective openings of the set of second gas outlet orifices have corresponding second central axes tangent to the at least one second lateral surface, and the first central axes are substantially aligned with corresponding ones of the second central axes.

Implementation 35: The insert of implementation 34, in which a total number of the first gas outlet orifices is “k,” “k” is an integer greater than or equal to two, and an angular pitch between adjacent first central axes among the first central axes is approximately 360°/k.

Implementation 36: The insert of implementation 35, in which “k” is 6.

Implementation 37: The insert of implementation 35, in which “k” is 7.

Implementation 38: The insert of any one of implementations 22-37, in which a total number of the second gas outlet orifices is equivalent to the total number of first gas outlet orifices.

Implementation 39: The insert of any one of implementations 1-38, in which the second distal surface is a generally conical surface having an apex protruding towards the first gas inlet surface in a direction opposite the first direction.

Implementation 40: The insert of implementation 39, in which a central axis of the bore extends through the apex of the second distal surface.

Implementation 41: The insert of any one of implementations 1-40, in which one or more of the gas outlet orifices have circular cross-sections in planes perpendicular to their axes of longitudinal extension.

Implementation 42: The insert of any one of implementations 1-41, in which the bore and the gas outlet orifices are configured such that, in response to a flow of gas through the insert, a pressure drop between an inlet of the bore and respective outlets of the gas outlet orifices is less than or equal to 850×10⁻⁴ Torr. A Knudsen number of the flow of gas is greater than 0.01 and less than 0.1.

Implementation 43: The insert of implementation 42, in which the pressure drop between the inlet of the bore and the respective outlets of the gas outlet orifices is less than or equal to 500×10⁻⁴ Torr.

Implementation 44: A gas distribution port insert (“insert”) including a head portion, a body portion, a bore, and a gas outlet orifice. The head portion includes a gas inlet surface, an intermediate surface opposing the gas inlet surface in a first direction, and at least one first lateral surface connecting the gas inlet surface to the intermediate surface. The body portion extends from the head portion. The body portion includes: a proximal end adjacent to the intermediate surface; a distal end spaced apart from the proximal end in the first direction, the distal end terminating at a first distal surface; and at least one second lateral surface connecting the distal end to the proximal end. The bore extends along a reference axis from the gas inlet surface through the head portion and partially through the body portion. The bore terminates at a second distal surface interior to the body portion. The gas outlet orifice includes a proximal end opening fluidically connected to the bore within an interior of the body portion, and a distal end opening formed in the at least one second lateral surface. A width of the head portion in a second direction transverse to the first direction is greater than a width of the body portion in the second direction.

Implementation 45: The insert of implementation 44, further including a recessed portion in the gas inlet surface. The recessed portion longitudinally extends from the at least one first lateral surface to the first bore in a third direction. The third direction is transverse to the first direction. A depth of the recessed portion in the first direction is less than a height of the head portion in the first direction.

Implementation 46: The insert of implementation 45, in which a width of the recessed portion in the second direction is between about 0.02 mm and about 0.06 mm, and a height of the recessed portion in the first direction is between about 0.005 mm and about 0.02 mm.

Implementation 47: The insert of any one of implementations 44-46, in which the distal end opening is formed in and spans between the first distal surface and the at least one second lateral surface.

Implementation 48: The insert of any one of implementations 44-47, in which a central axis of longitudinal extension of the gas outlet orifice extends in a fourth direction transverse to the first direction.

Implementation 49: The insert of implementation 48, in which a first reference plane is perpendicular to the first direction, and an angle between the first reference plane and the fourth direction is about 10° to about 30°.

Implementation 50: The insert of either implementation 45 or implementation 46 and either implementation 47 or implementation 48, in which the third direction and the fourth direction are substantially equivalent.

Implementation 51: The insert of any one of implementations 44-50, in which a height of the gas outlet orifice is between about 0.02 mm and about 0.05 mm.

Implementation 52: The insert of any one of implementations 48-50 and implementation 51, in which the height of the gas outlet orifice extends in a fifth direction perpendicular to the fourth direction.

Implementation 53: The insert of any one of implementations 44-52, in which a width of the gas outlet orifice in the second direction is between about 0.1 mm and about 0.2 mm.

Implementation 54: The insert of either implementation 48 or implementation 50, in which the fourth direction is substantially perpendicular to the first direction.

Implementation 55: The insert of implementation 54, in which the gas outlet orifice includes a first sidewall extending in a sixth direction oblique to the central axis of the gas outlet orifice, and a second sidewall extending in a seventh direction oblique to the central axis of the gas outlet orifice, the seventh direction being different from the sixth direction.

Implementation 56: The insert of implementation 55, in which a first angle between the central axis of the gas outlet orifice and the sixth direction is about 45° to about 75°, and a second angle between the central axis of the gas outlet orifice and the seventh direction is about −45° to about −75°.

Implementation 57: The insert of implementation 56, in which magnitudes of the first and second angles are substantially equivalent.

Implementation 58: The insert of any one of implementations 54-57, further including an additional bore extending partially through the body portion and fluidically connecting the bore and the gas outlet orifice.

Implementation 59: The insert of implementation 58, in which the additional bore extends along the reference axis.

Implementation 60: The insert of either implementation 58 or implementation 59, in which a central axis of the additional bore is offset from a central axis of the bore.

Implementation 61: The insert of either implementations 45 and 59 or

implementations 46 and 59, in which the central axis of the additional bore is offset from the central axis of the bore in the third direction.

Implementation 62: The insert of either implementation 60 or implementation 61, in which the offset is between 0.01 mm and 0.03 mm.

Implementation 63: The insert of any one of implementations 58-62, in which a width of the additional bore in the second direction is less than or equal to a minimum width of the gas outlet orifice in the second direction.

Implementation 64: The insert of any one of implementations 58-63, in which a height of the gas outlet orifice in the first direction is smaller than a height of the additional bore in the first direction.

Implementation 65: The insert of any one of implementations 42-64, in which the bore and the gas outlet orifice are configured such that, in response to a flow of gas through the insert, a pressure drop between an inlet of the bore and an outlet of the gas outlet orifice is less than or equal to 850×10⁻⁴ Torr. A Knudsen number of the flow of gas is greater than 0.01 and less than 0.1.

Implementation 66: The insert of implementation 65, in which the pressure drop between the inlet of the bore and the outlet of the gas outlet orifice is less than or equal to 500×10⁻⁴ Torr.

Implementation 67: A gas distribution port insert (“insert”) including a gas inlet, a body portion, a flange portion, a bore, and a plurality of gas outlet orifices. The gas inlet is configured to receive a flow of gas. The body portion includes a proximal end, a distal end spaced apart from the proximal end in a first direction, and a first section including first threads. The first section is disposed between the proximal end and the distal end. The flange portion extends from the distal end of the body portion. The flange portion includes a mating surface adjacent to the distal end, and a first distal surface spaced apart from the mating surface in the first direction. The bore extends along a reference axis from the proximal end towards the distal end. The bore being is fluidically connected to the gas inlet and terminates at a second distal surface interior to the body portion. The plurality of gas outlet orifices is in the first distal surface. The gas outlet orifices are fluidically connected to the bore within the interior of the body portion and circumferentially arranged about the reference axis.

Implementation 68: The insert of implementation 67, further including a head portion. The head portion includes a first surface; a second surface spaced apart from the first surface in the first direction; and an opening extending in the first direction from the first surface through the second surface, the opening including second threads configured to interface with the first threads. The head portion is detachably coupled to the body portion by way of a threaded engagement between the first and second threads that causes, at least in part, a portion of the first section to be received in the opening. An extent of the threaded engagement is configured to change a distance, in the first direction, between the second surface and the mating surface.

Implementation 69: The insert of either implementation 67 or implementation 68, in which the gas inlet is defined by an inlet of the bore at the proximal end of the body portion.

Implementation 70: The insert of either implementation 67 or implementation 68, in which the gas inlet is defined by an inlet of the opening in the first surface of the head portion.

Implementation 71: The insert of any one of implementations 67-70, in which respective axes of longitudinal extension of the gas outlet orifices form corresponding angles of inclination with the reference axis.

Implementation 72: The insert of implementation 71, in which each of the corresponding angles of inclination is about 45°.

Implementation 73: The insert of any one of implementations 67-72, in which a total number of the gas outlet orifices is “n,” “n” is an integer greater than or equal to two, and an angular pitch between respective ones of the axes of longitudinal extension is approximately 360°/n.

Implementation 74: The insert of implementation 73, in which “n” is 7.

Implementation 75: The insert of any one of implementations 67-74, in which the body portion further includes a main section, the first section of the body portion protrudes from the main section in a direction opposite the axial direction, and a width of the head portion in a second direction transverse to the first direction is greater than a width of the main section of the body portion in the second direction.

Implementation 76: The insert of any one of implementations 67-74, in which the body portion further includes a main section, the first section of the body portion protrudes from the main section in a direction opposite the axial direction, and a width of the flange portion in a second direction transverse to the first direction is greater than a width of the main section of the body portion in the second direction.

Implementation 77: The insert of implementation 76, in which a difference between the width of the flange and the width of the main section of the body portion is greater than 0 mm and less than or equal to about 2 mm.

Implementation 78: The insert of any one of implementations 75-77, in which the width of the main section in the second direction is greater than the width of the first section in the second direction, and the width of the flange portion in the second direction is greater than a width of the head portion in the second direction.

Implementation 79: The insert of any one of implementations 67-78, in which: the head portion further includes at least one lateral surface connecting the second surface to the first surface; the first surface includes at least one recessed portion, the at least one recessed portion longitudinally extending from the at least one lateral surface to the opening in a third direction, the third direction being transverse to the first direction; and a depth of the at least one recessed portion in the first direction is less than a height of the head portion in the first direction.

Implementation 80: The insert of any one of implementations 67-79, in which the flange portion forms a generally cylindrical prism.

Implementation 81: The insert of any one of implementations 1-80, in which the reference axis forms a central axis of the insert.

Implementation 82: The insert of any one of implementations 1-81, in which the reference axis extends in the first direction.

Implementation 83: The insert of any one of implementations 1-82, in which respective lengths of the gas outlet orifices are smaller than a length of the bore.

Implementation 84: The insert of any one of implementations 1-69, in which a depth of the bore along the reference axis is between about 0.3 mm and about 0.6 mm.

Implementation 85: The insert of any one of implementations 1-70, in which a width of the bore in the second direction is between about 0.1 mm and about 0.2 mm.

Implementation 86: The insert of any one of implementations 1-71, in which a width of the head portion in the second direction is between about 0.1 mm and about 0.4 mm, and a width of the body portion in the second direction is between about 0.1 mm and about 0.2 mm.

Implementation 87: The insert of any one of implementations 1-72, in which a length of the head portion in the first direction is between about 0.05 mm and about 0.1 mm, and a length of the body portion in the first direction is between about 0.4 mm and about 0.6 mm.

Implementation 88: The insert of any one of implementations 1-73, in which a length of the insert is between about 0.5 mm and about 0.7 mm.

Implementation 89: The insert of any one of implementations 1-88, in which the head portion forms a generally cylindrical prism.

Implementation 90: The insert of any one of implementations 1-89, in which the body portion forms a generally cylindrical prism.

Implementation 91: The insert of any one of implementations 1-76, in which the body portion forms a generally conical frustum decreasing in size with increasing distance from the head portion.

Implementation 92: The insert of any one of implementations 1-77, in which a cavity of the bore forms a generally cylindrical prism in the head portion.

Implementation 93: The insert of any one of implementations 1-78, in which a cavity of the bore forms a generally conical frustum in the head portion.

Implementation 94: The insert of any one of implementations 1-79, in which a cavity of the bore forms a generally cylindrical prism in the body portion.

Implementation 95: The insert of any one of implementations 1-80, in which a cavity of the bore forms a generally conical frustum in the body portion.

Implementation 96: The insert of any one of implementations 1-95, in which the insert includes a metal oxide.

Implementation 97: The insert of any one of implementations 1-96, in which the insert is formed of an aluminum oxide.

Implementation 98: An apparatus including a gas distribution body, which includes one or more plenums formed between a first surface and a second surface opposing the first surface. The second surface includes a plurality of gas distribution ports fluidically connected to at least one of the one or more plenums. One or more of the gas distribution ports includes a gas distribution port insert (“insert”) according to any one of implementations 1-97 at least partially supported therein.

Implementation 99: The apparatus of implementation 98, in which each of the one or more gas distribution ports includes a first port part configured to support the head portion of the insert at least partially therein, and a second port part fluidically connected to the first port part. The second port part is configured to enable the body portion of insert to extend at least partially therethrough.

Implementation 100: The apparatus of implementation 99, in which the first port part is configured to form a clearance fit with the head portion of the insert.

Implementation 101: The apparatus of implementation 100, in which a maximum dimension of the first port part in the second direction is between about 1% and about 5% greater than the width of the head portion of the insert.

Implementation 102: The apparatus of any one of implementations 99-101, in which the second port part has at least one inner side wall adjacent to the at least one second lateral surface of the body portion, and a first gap between the at least one inner side wall and the at least one second lateral surface is greater than 0 and less than or equal to about 1 mm.

Implementation 103: The apparatus of implementation 102, in which the first gap is substantially constant along a length of the second port part.

Implementation 104: The apparatus of either implementation 102 or implementation 103, in which the first gap is greater than 0 and less than or equal to about 0.5 mm.

Implementation 105: The apparatus of implementation 102, in which the first gap increases with increasing distance from the first port part.

Implementation 106: The apparatus of either implementation 102 or implementation 105, in which the first gap is greater than 0 and less than or equal to about 0.8 mm.

Implementation 107: The apparatus of implementation 98, when dependent from any one of implementations 67-83, 89, 90, 96, or 97, in which a gas distribution port of the one or more gas distribution ports includes a first port part including second threads interfacing with the first threads; and a second port part fluidically connected to the first port part, the second port part including at least some of the body portion supported therein.

Implementation 108: The apparatus of implementation 98, when dependent from any one of implementations 67-83, 89, 90, 96, or 97, in which a gas distribution port of the one or more gas distribution ports includes a first port part including the head portion of the insert at least partially supported therein, and a second port part fluidically connected to the first port part, the second port part including at least some of the body portion of the insert at least partially supported therein.

Implementation 109: The apparatus of either implementation 107 or implementation 108, in which the mating surface of the flange portion abuts against the second surface of the gas distribution body.

Implementation 110: The apparatus of implementation 109, when dependent from implementation 108, in which the second surface of the head portion abuts against a support surface in the gas distribution port, and the support surface defines a transition between the first port part and the second port part.

Implementation 111: The apparatus of any one of implementations 98-110, further including a process chamber and a pedestal. The pedestal is configured to support a wafer within the process chamber in relation to the gas distribution body such that a distance, in the first direction, between the second surface and a surface of the wafer facing the second surface is about 1 mm.

Implementation 112: The apparatus of implementation 111, in which the first distal surface extends beyond the second surface of the gas distribution body such that a distance, in the first direction, between the first distal surface and the surface of the wafer is between about 0.10 mm and about 0.5 mm.

Implementation 113: The apparatus of either implementation 111 or implementation 112, in which the gas distribution body forms a portion of a showerhead, and the pedestal is a showerhead pedestal.

Implementation 114: The apparatus of any one of implementations 98-113, in which the gas distribution body further includes one or more thermal control elements thermally coupled thereto. The one or more thermal control elements includes a heating element, a cooling conduit, or both a heating element and a cooling conduit.

Implementation 115: The apparatus of implementation 114, in which one or more portions of the thermal control elements are disposed in a reference plane extending between the first surface and the second surface in a manner that the reference plane is disposed, in the first direction, between the gas inlet or gas inlet surface and the first distal surface.

Implementation 116: The apparatus of any one of implementations 98-110, further including a process chamber, a component, and a directional flow structure. The process chamber includes a cleaning gas inlet. The component includes a third surface facing the second surface of the gas distribution body within an interior of the process chamber. The directional flow structure is supported within the interior of the process chamber. The directional flow structure is configured to direct a portion of a flow of cleaning gas from the cleaning gas inlet to an area between the second surface and the third surface.

Implementation 117: The apparatus of implementation 116, in which the gas distribution body forms a portion of a showerhead, and the component forms a portion of a showerhead pedestal.

Implementation 118: The apparatus of either implementation 116 or implementation 117, further including a remote-plasma clean (“RPC”) source fluidically connected to the cleaning gas inlet. The one or more cleaning gases include dissociated species from plasma generated by the RPC source.

Implementation 119: The apparatus of any one of implementations 116-118, in which the semiconductor processing chamber is a multi-station processing chamber.

Implementation 120: A method including: causing, at least in part, one or more cleaning gases to flow between a first surface of a gas distribution body and a second surface of a component facing the gas distribution body within an interior region of a semiconductor processing chamber, the first surface including a plurality of gas distribution ports configured to support corresponding gas distribution port insets at least partially therein; and causing, at least in part, one or more purge gases to flow from the gas distribution port inserts as the one or more cleaning gases flow between the first surface and the second surface. The one or more cleaning gases are caused, at least in part, to flow in a first general direction. The second surface faces the first surface in a second direction transverse to the first general direction. The gas distribution port inserts include corresponding gas outlet orifices having respective axes of longitudinal extension angled away from the second direction.

Implementation 121: The method of implementation 120, in which the second direction is perpendicular to the first general direction.

Implementation 122: The method of either implementation 120 or implementation 121, in which the gas distribution port inserts are configured according to any one of implementations 1-6 and 8-97.

Implementation 123: The method of either implementation 120 or implementation 121, in which the respective axes of longitudinal extension extend in the first general direction.

Implementation 124: The method of any one of implementations 120-123, in which the gas distribution body forms a portion of a showerhead, and the third surface forms a portion of a showerhead pedestal.

Implementation 125: The method of any one of implementations 120-124, in which the one or more cleaning gases include dissociated species from plasma generated outside the semiconductor processing chamber.

Implementation 126: The method of any one of implementations 120-125, in which the semiconductor processing chamber is a multi-station processing chamber.

1. A gas distribution port insert comprising:
a head portion comprising:
a gas inlet surface;
an intermediate surface opposing the gas inlet surface in a first direction; and
at least one first lateral surface connecting the gas inlet surface to the intermediate surface;
a body portion extending from the head portion, the body portion comprising:
a proximal end adjacent to the intermediate surface;
a distal end spaced apart from the proximal end in the first direction, the distal end terminating at a first distal surface; and
at least one second lateral surface connecting the distal end to the proximal end;
a bore extending along a reference axis from the gas inlet surface through the head portion and partially through the body portion, the bore terminating at a second distal surface interior to the body portion; and
a plurality of gas outlet orifices fluidically connected to the bore within the interior of the body portion and circumferentially arranged about the reference axis,
wherein:
proximal ends of the gas outlet orifices are formed in the second distal surface; and
a width of the head portion in a second direction transverse to the first direction is greater than a width of the body portion in the second direction.

2. The gas distribution port insert of claim 1, wherein:
distal ends of the gas outlet orifices are formed in the first distal surface; and
the gas outlet orifices longitudinally extend in the first direction.

3. The gas distribution port insert of claim 1, wherein:
the body portion further comprises at least one third lateral surface connecting the first distal surface to the at least one second lateral surface, the at least one third lateral surface being inclined with respect to the first distal surface;
distal ends of the gas outlet orifices are formed in the at least one third lateral surface; and
respective axes of longitudinal extension of the gas outlet orifices extend outwards from the reference axis and form corresponding angles of inclination with the reference axis.

4. The gas distribution port insert of claim 3, wherein the respective axes of longitudinal extension of the gas outlet orifices extend substantially perpendicular to the at least one third lateral surface.

5. A gas distribution port insert comprising:
a head portion comprising:
a gas inlet surface;
an intermediate surface opposing the gas inlet surface in a first direction; and
at least one first lateral surface connecting the gas inlet surface to the intermediate surface;
a body portion extending from the head portion, the body portion comprising:
a proximal end adjacent to the intermediate surface;
a distal end spaced apart from the proximal end in the first direction, the distal end terminating at a first distal surface; and
at least one second lateral surface connecting the distal end to the proximal end;
a bore extending along a reference axis from the gas inlet surface through the head portion and partially through the body portion, the bore terminating at a second distal surface interior to the body portion; and
a plurality of gas outlet orifices in the at least one second lateral surface, the gas outlet orifices fluidically connected to the bore within the interior of the body portion, and the gas outlet orifices circumferentially arranged about the reference axis,
wherein a width of the head portion in a second direction transverse to the first direction is greater than a width of the body portion in the second direction.

6. The gas distribution port insert of claim 5, wherein the plurality of gas outlet orifices comprises a set of first gas outlet orifices and a set of second gas outlet orifices offset from the first gas outlet orifices in the first direction such that the first gas outlet orifices are arranged closer to the proximate end of the body portion than the second gas outlet orifices.

7. The gas distribution port insert of claim 6, wherein:
the respective axes of longitudinal extension of the gas outlet orifices extend radially outwards from the reference axis;
the intermediate surface extends in a second reference plane;
some of the gas outlet orifices are tangent to the second distal surface and form the set of second gas outlet orifices; and
some of the gas outlet orifices are spaced apart from the second reference plane in the first direction and form the set of first gas outlet orifices.

8. The gas distribution port insert of claim 6, wherein:
the respective axes of longitudinal extension form corresponding angles of inclination with a first reference plane perpendicular to the reference axis;
the intermediate surface extends in a second reference plane;
some of the gas outlet orifices are tangent to the second reference plane and form the set of first gas outlet orifices; and
some of the gas outlet orifices are tangent to the second distal surface and form the set of second gas outlet orifices.

9. The gas distribution port insert of claim 6,
wherein:
respective first openings of the set of first gas outlet orifices have corresponding first central axes tangent to the at least one second lateral surface;
respective second openings of the set of second gas outlet orifices have corresponding second central axes tangent to the at least one second lateral surface; and
the first central axes are;
(i) circumferentially offset from the second central axes in a manner that the first central axes are incongruent with the second central axes; or
(ii) substantially aligned with corresponding ones of the second central axes.

10. The gas distribution port insert of claim 5, wherein the second distal surface is a generally conical surface having an apex protruding towards the first gas inlet surface in a direction opposite the first direction.

11. A gas distribution port insert comprising:
a head portion comprising:
a gas inlet surface;
an intermediate surface opposing the gas inlet surface in a first direction; and
at least one first lateral surface connecting the gas inlet surface to the intermediate surface;
a body portion extending from the head portion, the body portion comprising:
a proximal end adjacent to the intermediate surface;
a distal end spaced apart from the proximal end in the first direction, the distal end terminating at a first distal surface; and
at least one second lateral surface connecting the distal end to the proximal end;
a bore extending along a reference axis from the gas inlet surface through the head portion and partially through the body portion, the bore terminating at a second distal surface interior to the body portion; and
a gas outlet orifice comprising:
a proximal end opening fluidically connected to the bore within an interior of the body portion; and
a distal end opening formed in the at least one second lateral surface,
wherein a width of the head portion in a second direction transverse to the first direction is greater than a width of the body portion in the second direction.

12. The gas distribution port insert of claim 11, wherein the distal end opening is formed in and spans between the first distal surface and the at least one second lateral surface.

13. The gas distribution port insert of claim 12, wherein:
a central axis of longitudinal extension of the gas outlet orifice extends in a fourth direction transverse to the first direction;
a first reference plane is perpendicular to the first direction; and
an angle between the first reference plane and the fourth direction is about 10 degrees to about 30 degrees

14. The gas distribution port insert of claim 11, wherein:
a central axis of longitudinal extension of the gas outlet orifice extends in a fourth direction perpendicular to the first direction;
the gas outlet orifice comprises:
a first sidewall extending in a sixth direction oblique to the central axis of the gas outlet orifice; and
a second sidewall extending in a seventh direction oblique to the central axis of the gas outlet orifice, wherein the seventh direction is different from the sixth direction.

15. The gas distribution port insert of claim 14, further comprising:
an additional bore extending partially through the body portion along the reference axis and fluidically connecting the bore and the gas outlet orifice,
wherein:
a central axis of the additional bore is offset from a central axis of the bore in a third direction; and
a width of the additional bore in the second direction is less than or equal to a minimum width of the gas outlet orifice in the second direction.

16. A gas distribution port insert comprising:
a gas inlet configured to receive a flow of gas;
a body portion comprising:
a proximal end;
a distal end spaced apart from the proximal end in a first direction; and
a first section comprising first threads, the first section being disposed between the proximal end and the distal end; and
a flange portion extending from the distal end of the body portion, the flange portion comprising:
a mating surface adjacent to the distal end; and
a first distal surface spaced apart from the mating surface in the first direction;
a bore extending along a reference axis from the proximal end towards the distal end, the bore fluidically connected to the gas inlet and terminating at a second distal surface interior to the body portion; and
a plurality of gas outlet orifices in the first distal surface, the gas outlet orifices fluidically connected to the bore within the interior of the body portion and circumferentially arranged about the reference axis.

17. The gas distribution port insert of claim 16, further comprising:
a head portion comprising:
a first surface;
a second surface spaced apart from the first surface in the first direction; and
an opening extending in the first direction from the first surface through the second surface, the opening comprising second threads configured to interface with the first threads,
wherein:
the head portion is detachably coupled to the body portion by way of a threaded engagement between the first and second threads that causes, at least in part, a portion of the first section to be received in the opening; and
an extent of the threaded engagement is configured to change a distance, in the first direction, between the second surface and the mating surface.

18. The gas distribution port insert of claim 17, wherein:
the body portion further comprises a main section;
the first section of the body portion protrudes from the main section in a direction opposite an axial direction; and
a width of the flange portion in a second direction transverse to the first direction is greater than a width of the main section of the body portion in the second direction.

19. The gas distribution port insert of claim 18, wherein:
the width of the main section in the second direction is greater than the width of the first section in the second direction; and
the width of the flange portion in the second direction is greater than a width of the head portion in the second direction.

20. An apparatus comprising:
a gas distribution body comprising one or more plenums formed between a first surface and a second surface opposing the first surface, the second surface comprising a plurality of gas distribution ports fluidically connected to at least one of the one or more plenums,
wherein one or more of the gas distribution ports comprises a gas distribution port insert at least partially supported therein, the gas distribution port insert comprising:
a head portion comprising:
a gas inlet surface;
an intermediate surface opposing the gas inlet surface in a first direction;
and
at least one first lateral surface connecting the gas inlet surface to the intermediate surface;
a body portion extending from the head portion, the body portion comprising:
a proximal end adjacent to the intermediate surface;
a distal end spaced apart from the proximal end in the first direction, the distal end terminating at a first distal surface; and
at least one second lateral surface connecting the distal end to the proximal end;
a bore extending along a reference axis from the gas inlet surface through the head portion and at least partially through the body portion, the bore terminating at a second distal surface interior to the body portion; and
a plurality of gas outlet orifices fluidically connected to the bore within the interior of the body portion and circumferentially arranged about the reference axis,
wherein each of the one or more gas distribution ports comprises:
a first port part configured to support the head portion of the gas distribution port insert at least partially therein; and
a second port part fluidically connected to the first port part, the second port part being configured to enable the body portion of gas distribution port insert to extend at least partially therethrough.

21. The apparatus of claim 20, further comprising:
a process chamber; and
a showerhead pedestal configured to support a wafer within the process chamber in relation to the gas distribution body such that a distance, in the first direction, between the second surface and a surface of the wafer facing the second surface is about 1 mm,
wherein
the gas distribution body forms a portion of a showerhead.

22. The apparatus of claim 20, wherein:
proximal ends of the gas outlet orifices are formed in the second distal surface; and
a width of the head portion in a second direction transverse to the first direction is greater than a width of the body portion in the second direction.
